(19) United States
(12) Patent Application Publication
(10) Pub. No.: US 2026/0223594 A1
(43) Pub. Date: Jul. 30, 2026

(54) Composition For Light-Emitting Device

(71) Applicant: Semiconductor Energy Laboratory Co, Ltd., Kanagawa-ken (JP)

(72) Inventors: Satoshi SEO, Sagamihara (JP); Nobuharu OHSAWA, Zama (JP); Toshiki SASAKI, Isehara (JP); Hiromitsu KIDO, Atsugi (JP)

(73) Assignee: Semiconductor Energy Laboratory Co, Ltd., Kanagawa-ken (JP)

(21) Appl. No.: 19/456,471

(22) Filed: Jan. 22, 2026

Related U.S. Application Data
(63) Continuation of application No. 17/296,659, filed on Nov. 19, 2019, now abandoned.

(30) Foreign Application Priority Data
Nov. 30, 2018 (JP) 2018-225002

(51) Int. Cl. H10K 85/60; C09D 11/037; C09D 11/50; C09D 11/52; C09K 11/06; H10K 50/11; H10K 85/30; H10K 101/10

(52) U.S. Cl. CPC H10K 85/6574; C09D 11/037; C09D 11/50; C09D 11/52; C09K 11/06; H10K 85/342; H10K 85/626; H10K 85/633; H10K 85/636; H10K 85/654; H10K 85/657; H10K 85/6572; C09K 2211/1007; C09K 2211/1029; C09K 2211/1044; C09K 2211/185; H10K 50/11; H10K 85/615; H10K 2101/10

(57) ABSTRACT

Provided is a composition for a light-emitting device, which enables manufacture of a highly productive light-emitting device while device characteristics and reliability of the light-emitting device are maintained. The composition for a light-emitting device is formed by mixing a plurality of organic compounds. A first organic compound having a diazine skeleton (preferably, a benzofurodiazine skeleton, a naphthofurodiazine skeleton, a phenanthrofurodiazine skeleton, a benzothienodiazine skeleton, a naphthothienodiazine skeleton, or a phenanthrothienodiazine skeleton) and a second organic compound that is an aromatic amine compound are mixed to form the composition for a light-emitting device.

This application is a continuation of copending U.S. application Ser. No. 17/296,659, filed on May 25, 2021 which is a 371 of international application PCT/IB2019/059910 filed on Nov. 19, 2019 which are all incorporated herein by reference.

### TECHNICAL FIELD

One embodiment of the present invention relates to a composition for a light-emitting device, a light-emitting device, a light-emitting apparatus, an electronic device, and a lighting device. However, embodiments of the present invention are not limited thereto. That is, one embodiment of the present invention relates to an object, a method, a manufacturing method, or a driving method. Alternatively, one embodiment of the present invention relates to a process, a machine, manufacture, or a composition of matter.

### BACKGROUND ART

A light-emitting device including an EL layer between a pair of electrodes (also referred to as an organic EL device) has characteristics such as thinness, light weight, high-speed response to input signals, and low power consumption; thus, a display including such a light-emitting device has attracted attention as a next-generation flat panel display.

In a light-emitting device, voltage application between a pair of electrodes causes, in an EL layer, recombination of electrons and holes injected from the electrodes, which brings a light-emitting substance (an organic compound) contained in the EL layer into an excited state. Light is emitted when the light-emitting substance returns to the ground state from the excited state. The excited state can be a singlet excited state (S*) and a triplet excited state (T*). Light emission from a singlet excited state is referred to as fluorescence, and light emission from a triplet excited state is referred to as phosphorescence. The statistical generation ratio thereof in the light-emitting device is considered to be S*:T*=1:3. Since the emission spectrum obtained from a light-emitting substance depends on the light-emitting substance, the use of different types of organic compounds as light-emitting substances offers light-emitting devices exhibiting various emission colors.

In order to improve device characteristics and reliability of such a light-emitting device, improvement of a device structure, development of a material, and the like have been actively carried out (see Patent Document 1, for example).

In addition, from the perspective of mass production, it is desired to improve the productivity of light-emitting devices in order to reduce cost in the manufacturing line.

### REFERENCE

### Patent Document

[Patent Document 1] Japanese Published Patent Application No. 2010-182699

### SUMMARY OF THE INVENTION

### Problems to be Solved by the Invention

A material used for an EL layer of a light-emitting device is extremely important for improvement of device characteristics and reliability of the light-emitting device. The EL layer is formed by stacking a plurality of functional layers in many cases, and each functional layer includes a plurality of compounds in some cases. For example, a host material and a guest material are often used in combination in a light-emitting layer, and sometimes used in combination with another material.

When a plurality of layers are stacked or a plurality of materials need to be used in a layer as described above, a reduction in productivity is concerned due to an increase in the number of steps and need for an apparatus that can be used in such a case. However, in order to maintain excellent device characteristics of a light-emitting device to be manufactured, for example, the process cannot be easily simplified. For example, in the case where a light-emitting layer is formed by an evaporation method using a plurality of materials, a light-emitting device with excellent element characteristics cannot be easily obtained when the plurality of materials are put in one evaporation source to be evaporated for simplification of the process.

In view of the above, one embodiment of the present invention provides a composition for a light-emitting device, which enables manufacture of a highly productive light-emitting device while device characteristics and reliability of the light-emitting device are maintained.

Note that the description of these objects does not preclude the existence of other objects. One embodiment of the present invention does not have to achieve all these objects. Other objects are apparent from the description of the specification, the drawings, the claims, and the like, and other objects can be derived from the description of the specification, the drawings, the claims, and the like.

### Means for Solving the Problems

One embodiment of the present invention is a composition for a light-emitting device formed by mixing a plurality of organic compounds. Note that the composition for a light-emitting device can be used as a material for forming an EL layer of a light-emitting device. It is particularly preferable to use the composition for a light-emitting device as a material for forming an EL layer by an evaporation method. The composition for a light-emitting device is preferably used as a material for forming a light-emitting layer included in an EL layer of a light-emitting device by an evaporation method. When a light-emitting layer is formed by an evaporation method, the composition for a light-emitting device including a host material and a plurality of materials, and a guest material can be used.

One embodiment of the present invention is a composition for a light-emitting device formed by mixing a first organic compound having a diazine skeleton (preferably, a benzofurodiazine skeleton, a naphthofurodiazine skeleton, a phenanthrofurodiazine skeleton, a benzothienodiazine skeleton, a naphthothienodiazine skeleton, or a phenanthrothienodiazine skeleton) and a second organic compound that is an aromatic amine compound.

Another embodiment of the present invention is a composition for a light-emitting device formed by mixing a first organic compound having a furodiazine skeleton or a thienodiazine skeleton, which is represented by any one of General Formula (G1), General Formula (G2), and General Formula (G3), and a second organic compound that is an aromatic amine compound.

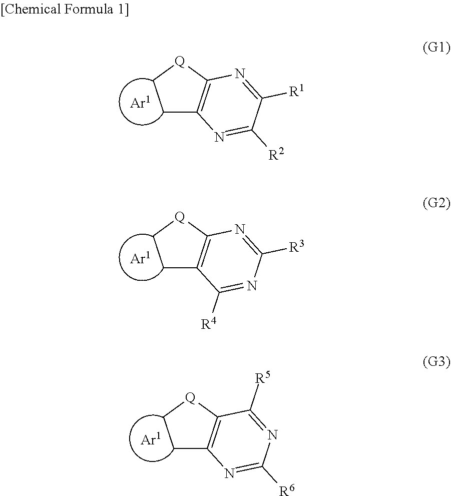

In General Formula (G1), General Formula (G2), and General Formula (G3) above, Q represents oxygen or sulfur. In addition, Ar¹ represents any one of substituted or unsubstituted benzene, substituted or unsubstituted naphthalene, substituted or unsubstituted phenanthrene, and substituted or unsubstituted chrysene. Moreover, each of R¹ to R⁶ independently represents hydrogen or a group having 1 to 100 total carbon atoms, and at least one of R¹ and R², at least one of R³ and R⁴, or at least one of R⁵ and R⁶ is bonded to any one of a pyrrole ring structure, a furan ring structure, and a thiophene ring structure through a substituted or unsubstituted phenylene group or a substituted or unsubstituted biphenylene group.

In any one of General Formula (G1), General Formula (G2), and General Formula (G3) above, Ar¹ is any one of General Formula (t1), General Formula (t2), General Formula (t3), and General Formula (t4) below.

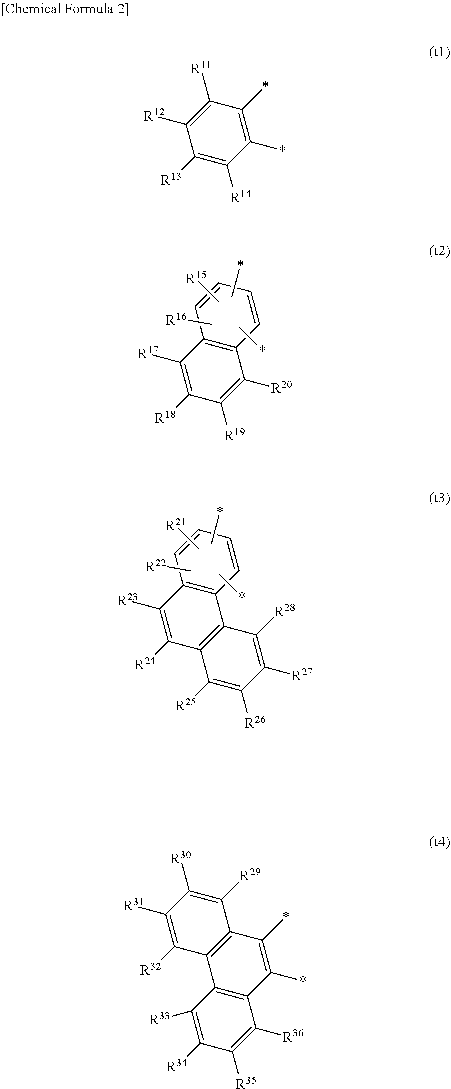

In General Formula (t1), General Formula (t2), General Formula (t3), and General Formula (t4) above, each of R¹¹ to R³⁶ independently represents any one of hydrogen, a substituted or unsubstituted alkyl group having 1 to 6 carbon atoms, a substituted or unsubstituted monocyclic saturated hydrocarbon group having 3 to 7 carbon atoms, a substituted or unsubstituted aromatic hydrocarbon group having 6 to 30 carbon atoms, and a substituted or unsubstituted heteroaromatic hydrocarbon group having 3 to 12 carbon atoms. Note that * represents a bonding portion to a five-membered ring in any one of General Formula (G1) to General Formula (G3).

Another embodiment of the present invention is a composition for a light-emitting device formed by mixing a first organic compound having a benzofurodiazine skeleton, which is represented by any one of General Formula (G1-1), General Formula (G2-1), and General Formula (G3-1), and a second organic compound that is an aromatic amine compound.

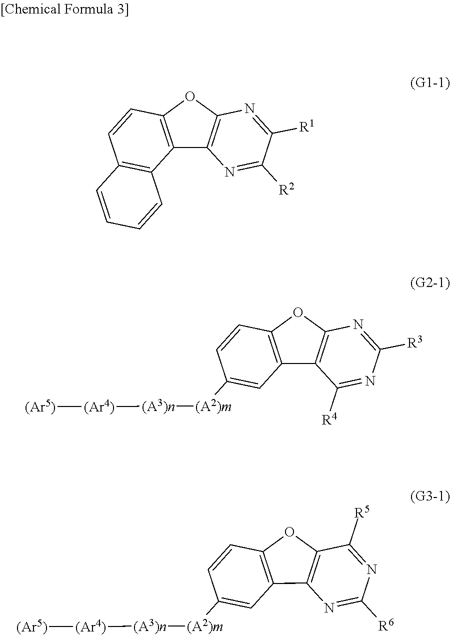

In any one of General Formula (G1-1), General Formula (G2-1), and General Formula (G3-1) above, each of Ar², Ar³, Ar⁴, and Ar⁵ independently represents a substituted or unsubstituted aromatic hydrocarbon ring, a substituent of the aromatic hydrocarbon ring is any one of an alkyl group having 1 to 6 carbon atoms, an alkoxy group having 1 to 6 carbon atoms, a monocyclic saturated hydrocarbon group having 5 to 7 carbon atoms, a polycyclic saturated hydrocarbon group having 7 to 10 carbon atoms, and a cyano group, and the number of carbon atoms included in the aromatic hydrocarbon ring is 6 to 25. In addition, m and n are each 0 or 1. Moreover, each of R¹ to R⁶ independently represents hydrogen or a group having 1 to 100 total carbon atoms, and at least one of R¹ and R², at least one of R³ and R⁴, or at least one of R⁵ and R⁶ is bonded to any one of a pyrrole ring structure, a furan ring structure, and a thiophene ring structure through a substituted or unsubstituted phenylene group or a substituted or unsubstituted biphenylene group.

In any one of General Formula (G1-1), General Formula (G2-1), and General Formula (G3-1) above, each of Ar², Ar³, Ar⁴, and Ar⁵ independently represents a substituted or unsubstituted benzene ring or naphthalene ring.

In any one of General Formula (G1-1), General Formula (G2-1), and General Formula (G3-1) above, Ar², Ar³, Ar⁴, and Ar⁵ are the same.

In any one of General Formula (G1), General Formula (G2), General Formula (G3), General Formula (G1-1), General Formula (G2-1), and General Formula (G3-1) above, each of R¹ to R⁶ independently represents hydrogen or a group having 1 to 100 total carbon atoms, and at least one of R¹ and R², at least one of R³ and R⁴, or at least one of R⁵ and R⁶ is bonded to any one of General Formulae (Ht-1) to (Ht-26) below through a substituted or unsubstituted phenylene group or a substituted or unsubstituted biphenylene group.

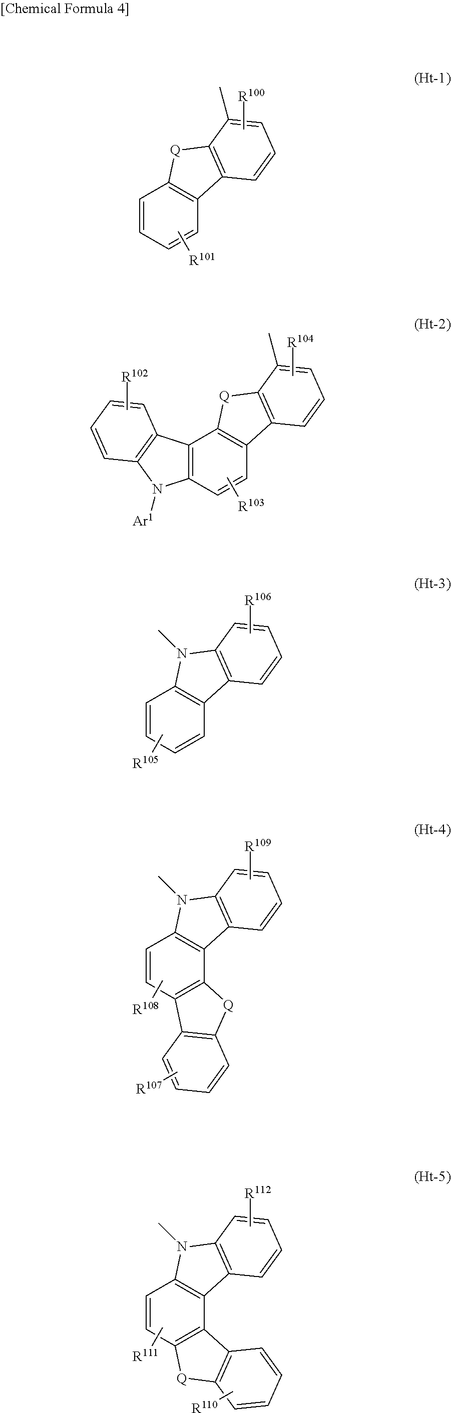

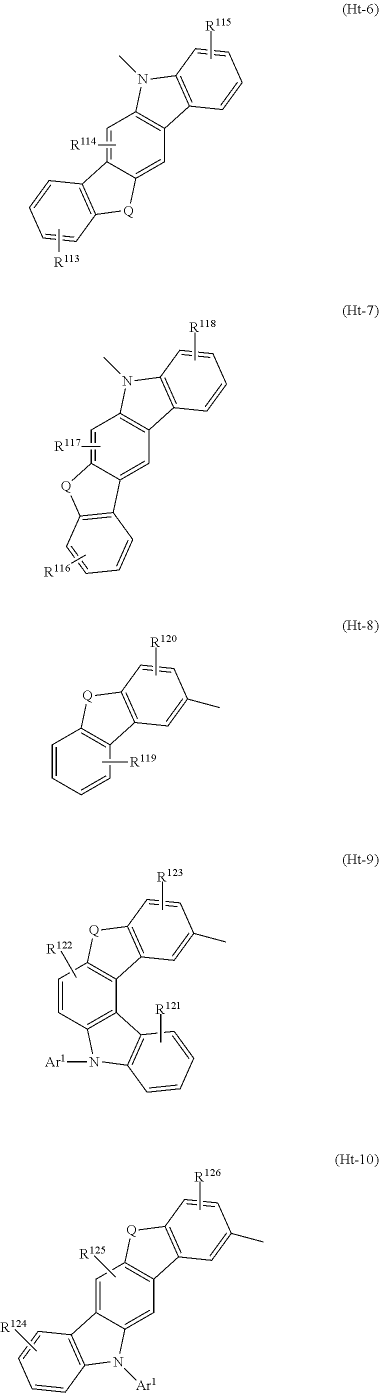

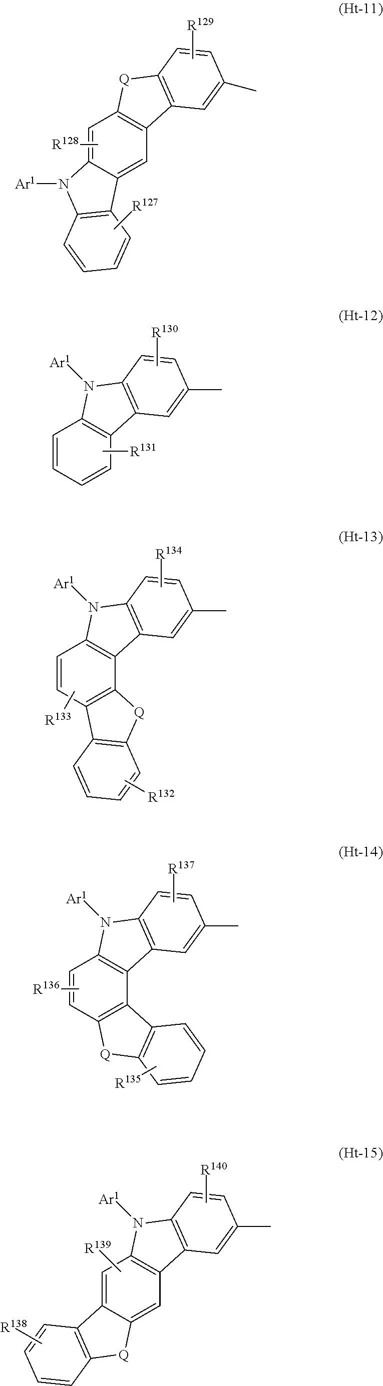

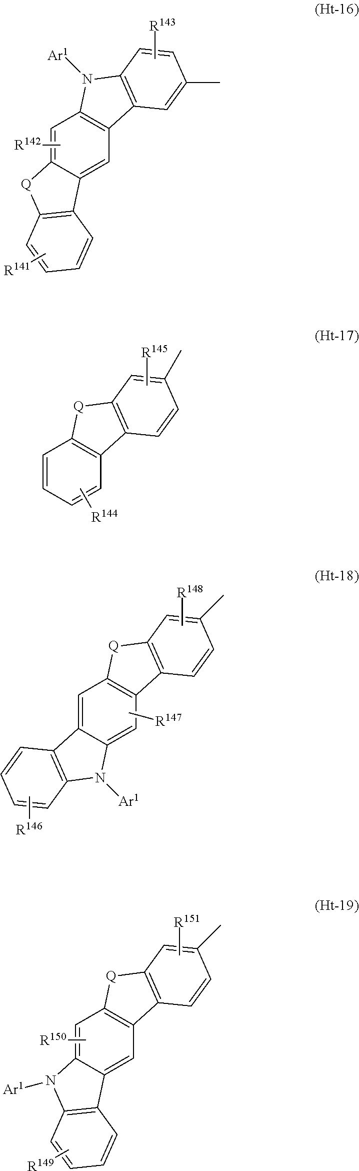

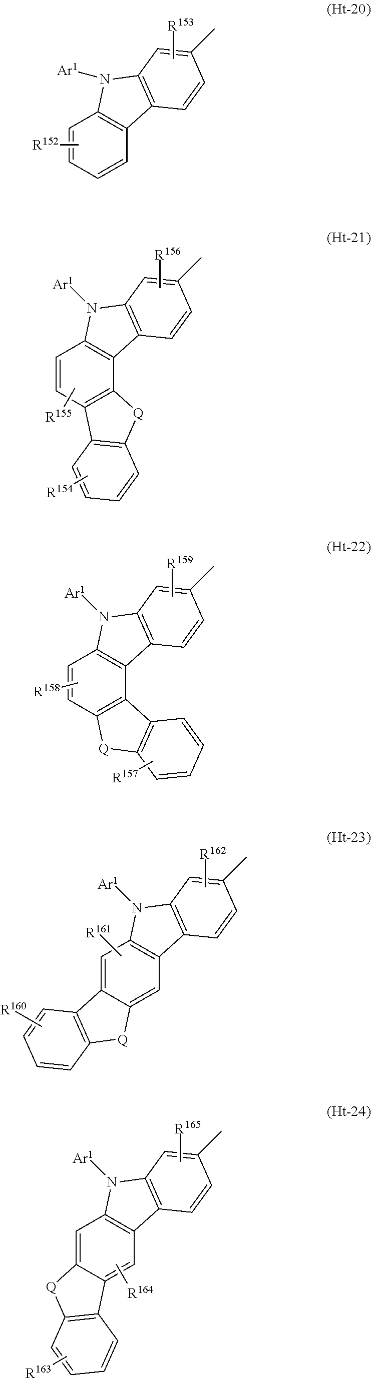

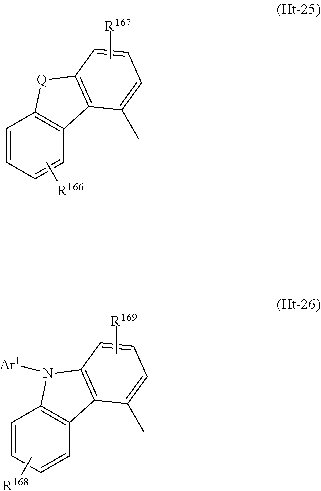

In any one of General Formulae (Ht-1) to (Ht-26) above, Q represents oxygen or sulfur. Furthermore, each of R¹⁰⁰ to R¹⁶⁹ represents 1 to 4 substituents and independently represents any one of hydrogen, an alkyl group having 1 to 6 carbon atoms, and a substituted or unsubstituted aromatic hydrocarbon group having 6 to 13 carbon atoms. Moreover, Ar¹ represents a substituted or unsubstituted benzene ring or naphthalene ring.

Another embodiment of the present invention is the composition for a light-emitting device formed by mixing the first organic compound having a diazine skeleton, which is described in any of the above structures, and the second organic compound that is an aromatic amine compound. As the second organic compound, a compound having a triarylamine skeleton, a carbazole skeleton, or both a triarylamine skeleton and a carbazole skeleton is used.

In the above structure, it is further preferable to use a compound that is a bicarbazole derivative or a 3,3′-bicarbazole derivative as the second organic compound.

Another embodiment of the present invention is the composition for a light-emitting device formed by mixing the first organic compound having a diazine skeleton, which is described in any of the above structures, and the second organic compound that is an aromatic amine compound. A combination of the first organic compound and the second organic compound can form an exciplex.

Another embodiment of the present invention is the composition for a light-emitting device formed by mixing the first organic compound having a diazine skeleton, which is described in any of the above structures, and the second organic compound that is an aromatic amine compound. The first organic compound is mixed in a larger proportion than the second organic compound.

Another embodiment of the present invention is the composition for a light-emitting device formed by mixing the first organic compound having a diazine skeleton, which is described in any of the above structures, and the second organic compound that is an aromatic amine compound. The molecular mass of the first organic compound is smaller than that of the second organic compound, and the difference in molecular mass is less than or equal to 200.

One embodiment of the present invention includes, in its category, in addition to the composition for a light-emitting device, a light-emitting device (also referred to as a light-emitting element) manufactured using the composition for a light-emitting device, a light-emitting apparatus including the light-emitting device, an electronic device including a light-emitting device or a light-emitting apparatus (specifically, an electronic device including a light-emitting device or a light-emitting apparatus, and a connection terminal or an operation key) and a lighting device including a light-emitting device or a light-emitting apparatus (specifically, a lighting device including a light-emitting device or a light-emitting apparatus, and a housing). Accordingly, a light-emitting apparatus in this specification refers to an image display device or a light source (including a lighting device). In addition, a light-emitting apparatus includes a module in which a light-emitting apparatus is connected to a connector such as an FPC (Flexible Printed Circuit) or a TCP (Tape Carrier Package), a module in which a printed wiring board is provided on the tip of a TCP, or a module in which an IC (integrated circuit) is directly mounted on a light-emitting device by a COG (Chip On Glass) method.

### Effect of the Invention

One embodiment of the present invention can provide a composition for a light-emitting device, which enables manufacture of a highly productive light-emitting device while device characteristics and reliability of the light-emitting device are maintained.

Note that the description of the effects does not preclude the existence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like. In addition, a novel light-emitting device whose reliability can be improved can be provided.

### BRIEF DESCRIPTION OF THE DRAWINGS

FIG. 1A and FIG. 1B illustrate light-emitting device structures.

FIG. 2A and FIG. 2B illustrate evaporation methods.

FIG. 3A, FIG. 3B, and FIG. 3C illustrate light-emitting apparatuses.

FIG. 4A and FIG. 4B illustrate a light-emitting apparatus.

FIG. 5A, FIG. 5B, FIG. 5C, FIG. 5D, FIG. 5E, FIG. 5F, and FIG. 5G illustrate electronic devices.

FIG. 6A, FIG. 6B, and FIG. 6C illustrate an electronic device.

FIG. 7A and FIG. 7B illustrate an automobile.

FIG. 8A and FIG. 8B illustrate lighting devices.

FIG. 9 illustrates a light-emitting device.

FIG. 10 is a graph showing current density-luminance characteristics of a light-emitting device 1-1 and a comparative light-emitting device 1-2.

FIG. 11 is a graph showing voltage-luminance characteristics of the light-emitting device 1-1 and the comparative light-emitting device 1-2.

FIG. 12 is a graph showing voltage-current characteristics of the light-emitting device 1-1 and the comparative light-emitting device 1-2.

FIG. 13 is a graph showing emission spectra of the light-emitting device 1-1 and the comparative light-emitting device 1-2.

FIG. 14 is a graph showing reliabilities of the light-emitting device 1-1 and the comparative light-emitting device 1-2.

FIG. 15 is a graph showing luminance-current density characteristics of a light-emitting device 2-1 and a comparative light-emitting device 2-2.

FIG. 16 is a graph showing luminance-voltage characteristics of the light-emitting device 2-1 and the comparative light-emitting device 2-2.

FIG. 17 is a graph showing current-voltage characteristics of the light-emitting device 2-1 and the comparative light-emitting device 2-2.

FIG. 18 is a graph showing emission spectra of the light-emitting device 2-1 and the comparative light-emitting device 2-2.

FIG. 19 is a graph showing reliabilities of the light-emitting device 2-1 and the comparative light-emitting device 2-2.

FIG. 20 is a graph showing luminance-current density characteristics of a light-emitting device 3-1 and a comparative light-emitting device 3-2.

FIG. 21 is a graph showing luminance-voltage characteristics of the light-emitting device 3-1 and the comparative light-emitting device 3-2.

FIG. 22 is a graph showing current-voltage characteristics of the light-emitting device 3-1 and the comparative light-emitting device 3-2.

FIG. 23 is a graph showing emission spectra of the light-emitting device 3-1 and the comparative light-emitting device 3-2.

FIG. 24 is a graph showing reliabilities of the light-emitting device 3-1 and the comparative light-emitting device 3-2.

FIG. 25 is a graph showing luminance-current density characteristics of a light-emitting device 4-1 and a comparative light-emitting device 4-2.

FIG. 26 is a graph showing luminance-voltage characteristics of the light-emitting device 4-1 and the comparative light-emitting device 4-2.

FIG. 27 is a graph showing current-voltage characteristics of the light-emitting device 4-1 and the comparative light-emitting device 4-2.

FIG. 28 is a graph showing emission spectra of the light-emitting device 4-1 and the comparative light-emitting device 4-2.

FIG. 29 is a graph showing reliabilities of the light-emitting device 4-1 and the comparative light-emitting device 4-2.

### MODE FOR CARRYING OUT THE INVENTION

Hereinafter, a composition for a light-emitting device of one embodiment of the present invention is described in detail. Note that the present invention is not limited to the following description, and the modes and details of the present invention can be modified in various ways without departing from the spirit and scope of the present invention. Thus, the present invention should not be construed as being limited to the description in the following embodiments.

Note that the position, size, range, or the like of each component shown in drawings and the like is not accurately represented in some cases for easy understanding. Therefore, the disclosed invention is not necessarily limited to the position, size, range, or the like disclosed in drawings and the like.

Furthermore, in describing structures of the invention with reference to the drawings in this specification and the like, the same components in different drawings are commonly denoted by the same reference numeral.

### Embodiment 1

In this embodiment, a material for a light-emitting device of one embodiment of the present invention is described. Note that a composition for a light-emitting device of one embodiment of the present invention can be used as a material for forming an EL layer of a light-emitting device. In particular, the composition for a light-emitting device can be used as a material for forming an EL layer by an evaporation method. Thus, described is a structure of a composition for a light-emitting device used as a plurality of materials (including a host material) other than a guest material when a light-emitting layer included in an EL layer of a light-emitting device is formed by an evaporation method.

When a light-emitting layer of an EL layer of a light-emitting device is formed by a co-evaporation method, a composition for a light-emitting device that can be used together with a guest material is a mixture of a first organic compound having a diazine skeleton (preferably, a benzofurodiazine skeleton, a naphthofurodiazine skeleton, a phenanthrofurodiazine skeleton, a benzothienodiazine skeleton, a naphthothienodiazine skeleton, or a phenanthrothienodiazine skeleton) and a second organic compound that is an aromatic amine compound.

The composition for a light-emitting device is a mixture of a first organic compound having a furodiazine skeleton or a thienodiazine skeleton, which is represented by any one of General Formula (G1), General Formula (G2), and General Formula (G3), and a second organic compound that is an aromatic amine compound.

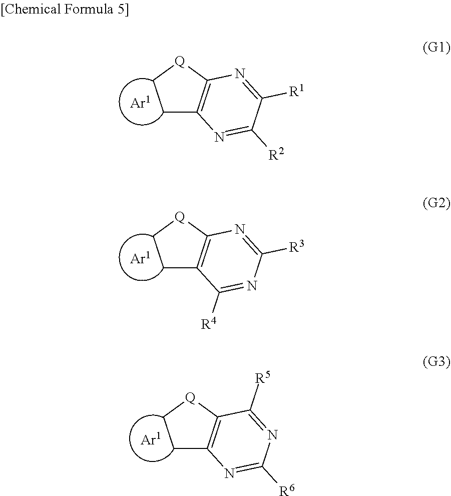

In General Formula (G1), General Formula (G2), and General Formula (G3) above, Q represents oxygen or sulfur. In addition, Ar¹ represents any one of substituted or unsubstituted benzene, substituted or unsubstituted naphthalene, substituted or unsubstituted phenanthrene, and substituted or unsubstituted chrysene. Moreover, each of R¹ to R⁶ independently represents hydrogen or a group having 1 to 100 total carbon atoms, and at least one of R¹ and R², at least one of R³ and R⁴, or at least one of R⁵ and R⁶ is bonded to any one of a pyrrole ring structure, a furan ring structure, and a thiophene ring structure through a substituted or unsubstituted phenylene group or a substituted or unsubstituted biphenylene group.

In any one of General Formula (G1), General Formula (G2), and General Formula (G3) above, Ar¹ is any one of General Formula (t1), General Formula (t2), General Formula (t3), and General Formula (t4) below.

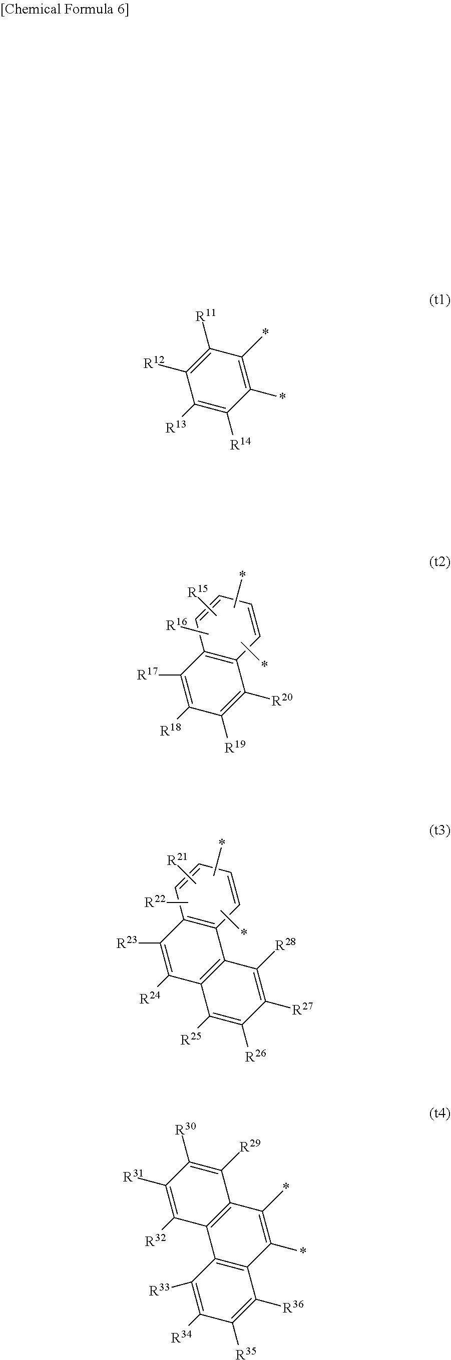

In General Formula (t1), General Formula (t2), General Formula (t3), and General Formula (t4) above, each of R¹¹ to R³⁶ independently represents any one of hydrogen, a substituted or unsubstituted alkyl group having 1 to 6 carbon atoms, a substituted or unsubstituted monocyclic saturated hydrocarbon group having 3 to 7 carbon atoms, a substituted or unsubstituted aromatic hydrocarbon group having 6 to 30 carbon atoms, and a substituted or unsubstituted heteroaromatic hydrocarbon group having 3 to 12 carbon atoms. Note that * represents a bonding portion to a five-membered ring in any one of General Formula (G1) to General Formula (G3).

The composition for a light-emitting device is a mixture of a first organic compound having a benzofurodiazine skeleton, which is represented by any one of General Formula (G1-1), General Formula (G2-1), and General Formula (G3-1), and a second organic compound that is an aromatic amine compound.

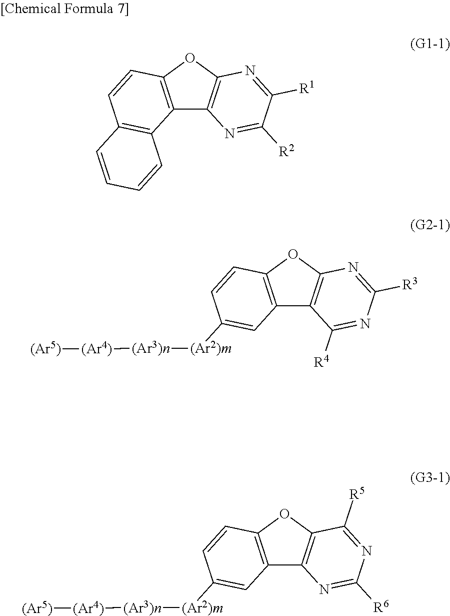

In any one of General Formula (G1-1), General Formula (G2-1), and General Formula (G3-1) above, each of Ar², Ar³, Ar⁴, and Ar⁵ independently represents a substituted or unsubstituted aromatic hydrocarbon ring, a substituent of the aromatic hydrocarbon ring is any one of an alkyl group having 1 to 6 carbon atoms, an alkoxy group having 1 to 6 carbon atoms, a monocyclic saturated hydrocarbon group having 5 to 7 carbon atoms, a polycyclic saturated hydrocarbon group having 7 to 10 carbon atoms, and a cyano group, and the number of carbon atoms included in the aromatic hydrocarbon ring is 6 to 25. In addition, m and n are each 0 or 1. Moreover, each of R¹ to R⁶ independently represents hydrogen or a group having 1 to 100 total carbon atoms, and at least one of R¹ and R², at least one of R³ and R⁴, or at least one of R⁵ and R⁶ is bonded to any one of a pyrrole ring structure, a furan ring structure, and a thiophene ring structure through a substituted or unsubstituted phenylene group or a substituted or unsubstituted biphenylene group.

In any one of General Formula (G1-1), General Formula (G2-1), and General Formula (G3-1) above, each of Ar², Ar³, Ar⁴, and Ar⁵ independently represents a substituted or unsubstituted benzene ring or naphthalene ring.

In any one of General Formula (G1-1), General Formula (G2-1), and General Formula (G3-1), Ar², Ar³, Ar⁴, and Ar⁵ are the same.

In any one of General Formula (G1), General Formula (G2), General Formula (G3), General Formula (G1-1), General Formula (G2-1), and General Formula (G3-1) above, each of R¹ to R⁶ independently represents hydrogen or a group having 1 to 100 total carbon atoms, and at least one of R¹ and R², at least one of R³ and R⁴, or at least one of R⁵ and R⁶ is bonded to any one of General Formulae (Ht-1) to (Ht-26) below through a substituted or unsubstituted phenylene group or a substituted or unsubstituted biphenylene group.

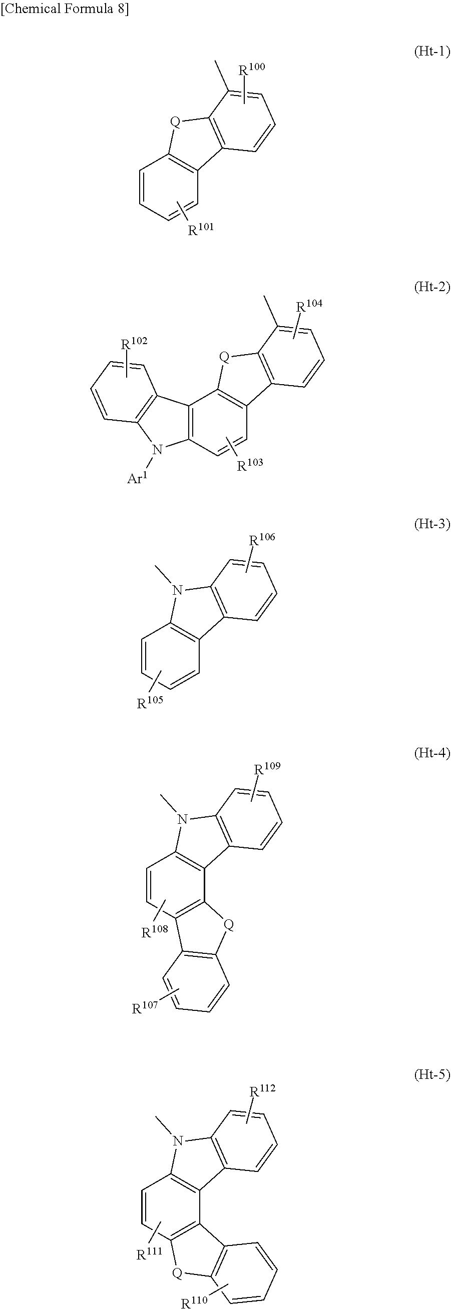

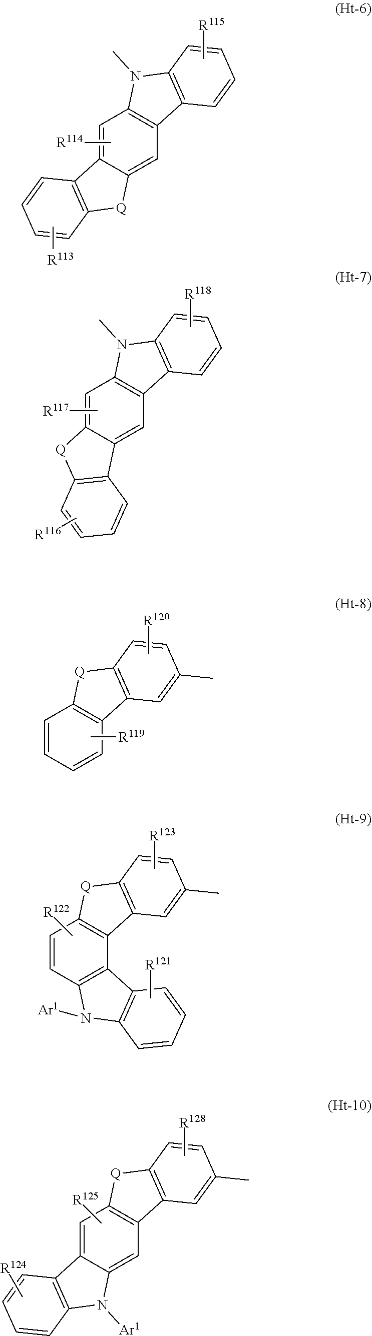

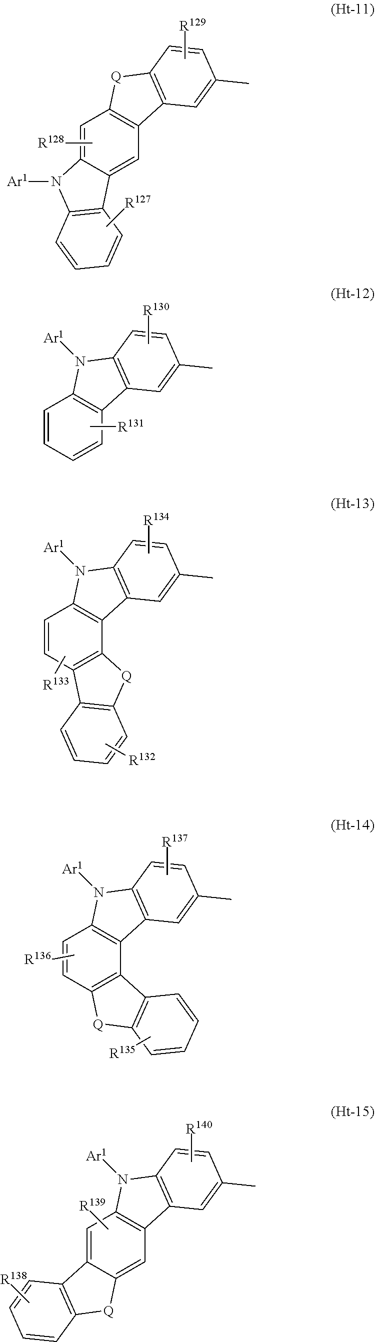

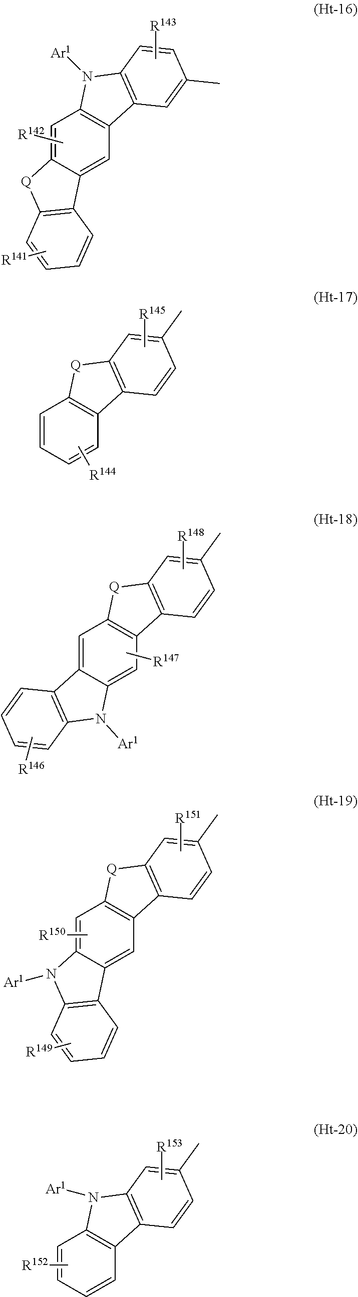

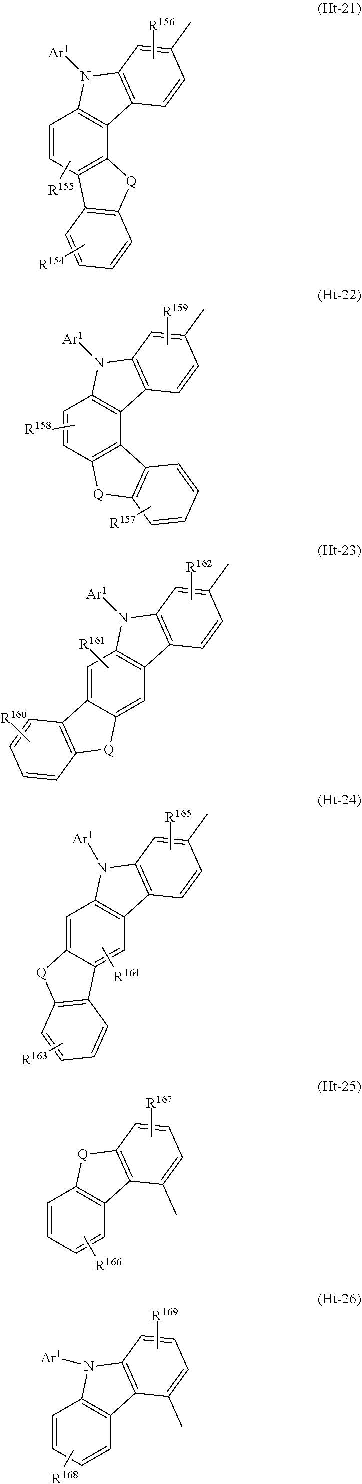

In any one of General Formulae (Ht-1) to (Ht-26) above, Q represents oxygen or sulfur. Furthermore, each of R¹⁰⁰ to R¹⁶⁹ represents 1 to 4 substituents and independently represents any one of hydrogen, an alkyl group having 1 to 6 carbon atoms, and a substituted or unsubstituted aromatic hydrocarbon group having 6 to 13 carbon atoms. Moreover, Ar¹ represents a substituted or unsubstituted benzene ring or naphthalene ring.

Next, specific examples of the first organic compound included in the composition for a light-emitting device of one embodiment of the present invention, which has a diazine skeleton (preferably, a benzofurodiazine skeleton, a naphthofurodiazine skeleton, a phenanthrofurodiazine skeleton, a benzothienodiazine skeleton, a naphthothienodiazine skeleton, or a phenanthrothienodiazine skeleton) or is represented by any one of General Formula (G1), General Formula (G2), General Formula (G3), General Formula (G1-1), General Formula (G2-1), and General Formula (G3-1) above, are shown below.

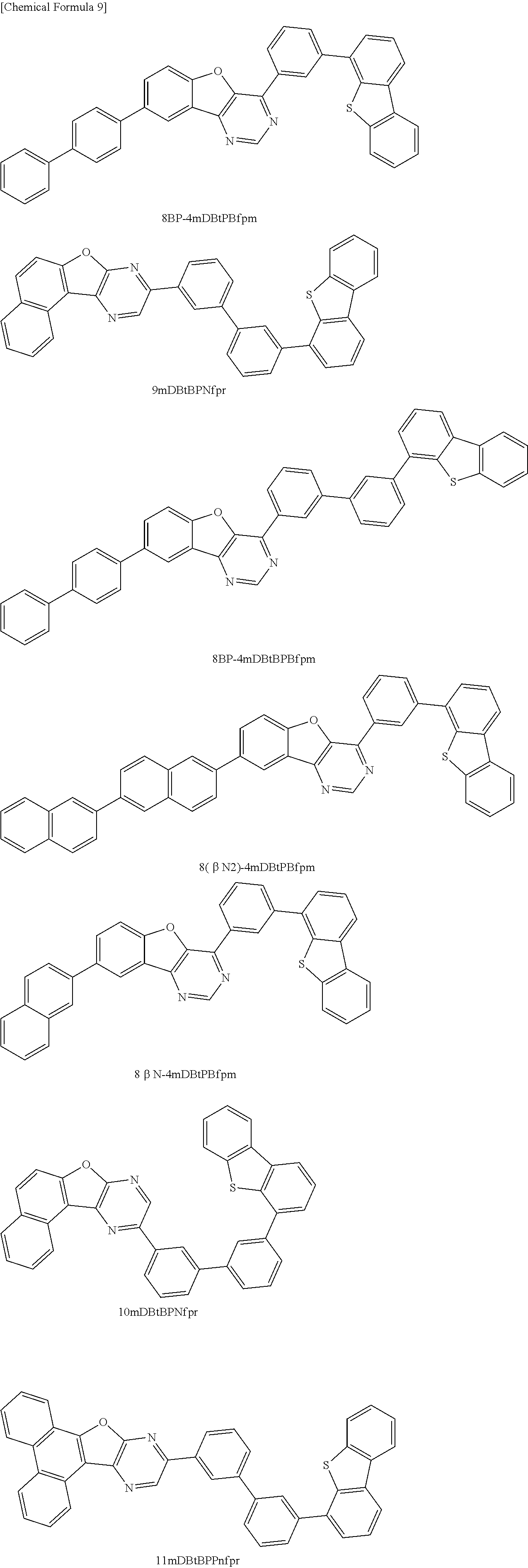

Of the first organic compound and the second organic compound included in the composition for a light-emitting device, it is preferable to use a compound having a triarylamine skeleton, a carbazole skeleton, or both a triarylamine skeleton and a carbazole skeleton as the second organic compound that is an aromatic amine compound.

Of the first organic compound and the second organic compound included in the composition for a light-emitting device, it is preferable to use a compound that is a bicarbazole derivative or a 3,3′-bicarbazole derivative as the second organic compound that is an aromatic amine compound.

Specific examples of the compound having a triarylamine skeleton, a carbazole skeleton, or both a triarylamine skeleton and a carbazole skeleton, which is the second organic compound that is an aromatic amine compound and included in the composition for a light-emitting device, are shown below.

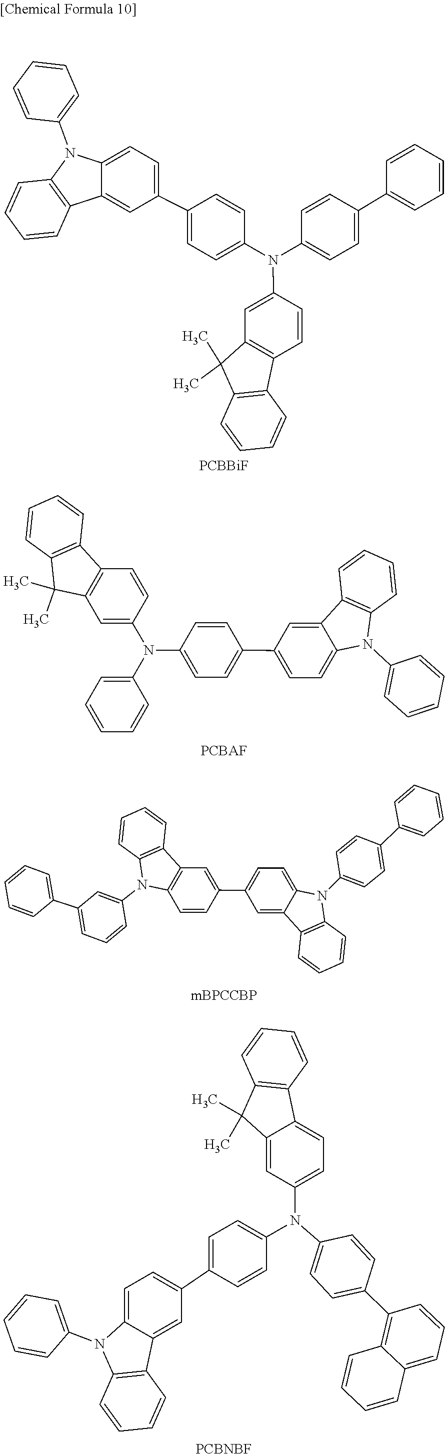

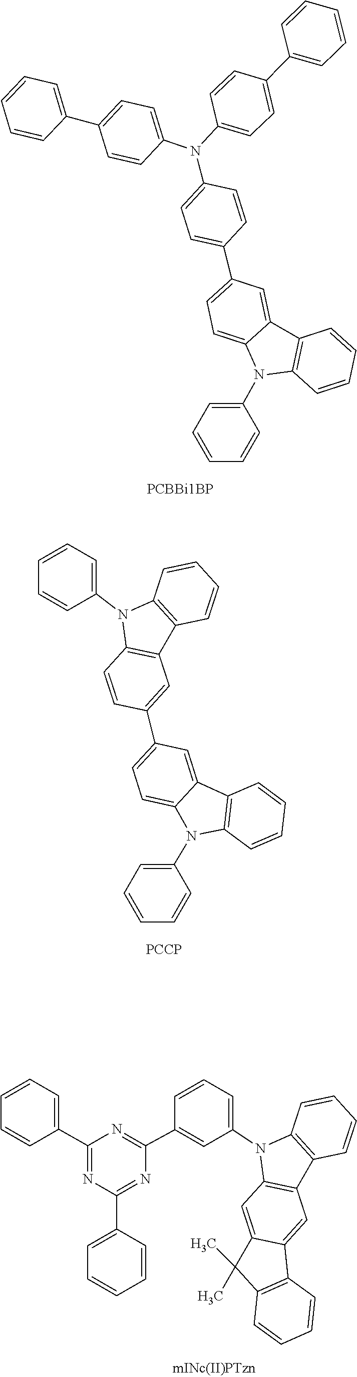

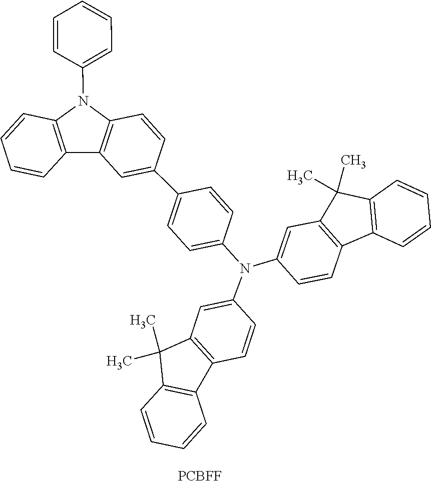

It is preferable that a combination of the first organic compound and the second organic compound included in the composition for a light-emitting device can form an exciplex.

In the composition for a light-emitting device, the first organic compound is preferably mixed in a larger proportion than the second organic compound.

The molecular mass of the first organic compound included in the composition for a light-emitting device is preferably smaller than that of the second organic compound, and the difference in molecular mass is preferably less than or equal to 200.

### Embodiment 2

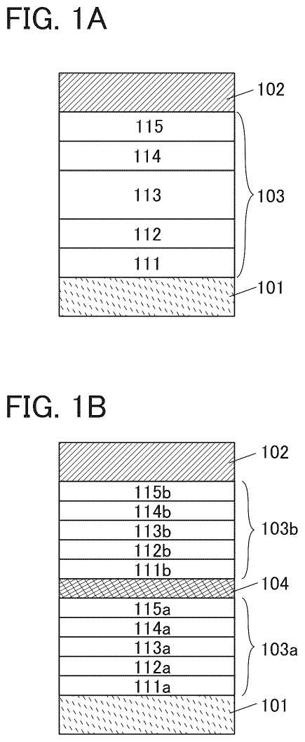

In this embodiment, a light-emitting device in which the composition for a light-emitting device of one embodiment of the present invention can be used is described with reference to FIG. 1.

### <<Structure of Light-Emitting Device>>

FIG. 1 illustrates examples of a light-emitting device including, between a pair of electrodes, an EL layer having a light-emitting layer. Specifically, the light-emitting device has a structure in which an EL layer 103 is sandwiched between a first electrode 101 and a second electrode 102. Note that the EL layer 103 has a structure in which, for example, a hole-injection layer 111, a hole-transport layer 112, a light-emitting layer 113, an electron-transport layer 114, and an electron-injection layer 115 are sequentially stacked as functional layers, in the case where the first electrode 101 serves as an anode. Embodiments of the present invention also include light-emitting devices having other structures: for example, a light-emitting device that can be driven at a low voltage by having a structure (a tandem structure) in which a plurality of EL layers, between which a charge-generation layer is sandwiched, are provided between a pair of electrodes; and a light-emitting device that has improved optical characteristics by having a micro-optical resonator (microcavity) structure between a pair of electrodes. Note that the charge-generation layer has a function of injecting electrons into one of the adjacent EL layers and injecting holes into the other of the EL layers when a voltage is applied to the first electrode 101 and the second electrode 102.

Note that at least one of the first electrode 101 and the second electrode 102 of the above light-emitting device is an electrode having a light-transmitting property (e.g., a transparent electrode or a semi-transmissive and semi-reflective electrode). In the case where the electrode having a light-transmitting property is a transparent electrode, the visible light transmittance of the transparent electrode is 40% or higher. In the case where the electrode having a light-transmitting property is a semi-transmissive and semi-reflective electrode, the visible light reflectance of the semi-transmissive and semi-reflective electrode is higher than or equal to 20% and lower than or equal to 80%, preferably higher than or equal to 40% and lower than or equal to 70%. The resistivity of these electrodes is preferably 1×10⁻² Ωcm or lower.

Furthermore, when one of the first electrode 101 and the second electrode 102 is an electrode having reflectivity (reflective electrode) in the above light-emitting device of one embodiment of the present invention, the visible light reflectance of the electrode having reflectivity is higher than or equal to 40% and lower than or equal to 100%, preferably higher than or equal to 70% and lower than or equal to 100%. The resistivity of this electrode is preferably 1×10⁻² Ωcm or lower.

### <First Electrode and Second Electrode>

As materials for forming the first electrode 101 and the second electrode 102, any of the following materials can be used in an appropriate combination as long as the functions of the electrodes described above can be fulfilled. For example, a metal, an alloy, an electrically conductive compound, a mixture of these, and the like can be used as appropriate. Specifically, an In—Sn oxide (also referred to as ITO), an In—Si—Sn oxide (also referred to as ITSO), an In—Zn oxide, or an In—W—Zn oxide can be given. In addition, it is also possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table, which is not listed above as an example (for example, lithium (Li), cesium (Cs), calcium (Ca), or strontium (Sr)), a rare earth metal such as europium (Eu) or ytterbium (Yb), an alloy containing an appropriate combination of any of these elements, graphene, or the like.

For fabrication of these electrodes, a sputtering method or a vacuum evaporation method can be used.

### <Hole-Injection Layer>

The hole-injection layer 111 is a layer injecting holes from the first electrode 101 that is an anode to the EL layer 103, and is a layer containing an organic acceptor material or a material with a high hole-injection property.

The organic acceptor material is a material that allows holes to be generated in another organic compound whose HOMO level value is close to the LUMO level value of the organic acceptor material when charge separation is caused between the organic acceptor material and the organic compound. Thus, as the organic acceptor material, a compound having an electron-withdrawing group (a halogen group or a cyano group), such as a quinodimethane derivative, a chloranil derivative, or a hexaazatriphenylene derivative, can be used. For example, 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), or 1,3,4,5,7,8-hexafluorotetracyano-naphthoquinodimethane (abbreviation: F6-TCNNQ) can be used. Among organic acceptor materials, HAT-CN, which has a high acceptor property and stable film quality against heat, is particularly favorable. Besides, a [3]radialene derivative has a very high electron-accepting property and thus is preferable; specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneac etonitrile], α,α′,α″-1,2,3-cyclopropanetriylidenetris[2,3,4,5,6-pentafluorobenzeneacetonitrile], or the like can be used.

Examples of the material with a high hole-injection property include transition metal oxides such as molybdenum oxide, vanadium oxide, ruthenium oxide, tungsten oxide, and manganese oxide. Alternatively, it is possible to use a phthalocyanine-based compound such as phthalocyanine (abbreviation: H₂Pc) or copper phthalocyanine (abbreviation: CuPc), or the like.

In addition to the above materials, it is also possible to use an aromatic amine compound, which is a low molecular compound, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), or 3-[N-(1-naphthyl)-N-(9-phenylcarbazol-3-yl)amino]-9-phenylcarbazole (abbreviation: PCzPCN1).

It is also possible to use a high molecular compound (an oligomer, a dendrimer, a polymer, or the like) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), or poly[N,N-bis(4-butylphenyl)-N,N-bis(phenyl)benzidine](abbreviation: Poly-TPD). Alternatively, it is also possible to use a high molecular compound to which acid is added, such as poly(3,4-ethylenedioxythiophene)/poly(styrenesulfonic acid) (abbreviation: PEDOT/PSS) or polyaniline/poly(styrenesulfonic acid) (abbreviation: PAni/PSS).

Alternatively, as the material having a high hole-injection property, a composite material containing a hole-transport material and an acceptor material (electron-accepting material) can be used. In this case, the acceptor material extracts electrons from the hole-transport material, so that holes are generated in the hole-injection layer 111 and the holes are injected into the light-emitting layer 113 through the hole-transport layer 112. Note that the hole-injection layer 111 may be formed to have a single-layer structure of a composite material containing a hole-transport material and an acceptor material (electron-accepting material), or a stacked-layer structure in which a layer containing a hole-transport material and a layer containing an acceptor material (electron-accepting material) are stacked.

As the hole-transport material, a substance having a hole mobility of greater than or equal to 1×10⁻⁶ cm²/Vs is preferable. Note that other substances can be used as long as they have a property of transporting more holes than electrons.

As the hole-transport material, a material having a high hole-transport property, such as a π-electron rich heteroaromatic compound, is preferable. As the second organic compound used for the composition for a light-emitting device of one embodiment of the present invention, a material such as a π-electron rich heteroaromatic compound is preferable among the materials included in the hole-transport material. Note that as the π-electron rich heteroaromatic compound, an aromatic amine compound having an aromatic amine skeleton (having a triarylamine skeleton), a carbazole compound having a carbazole skeleton (not having a triarylamine skeleton), a thiophene compound (a compound having a thiophene skeleton), a furan compound (a compound having a furan skeleton), or the like can be given.

Examples of the above aromatic amine compound include 4,4′-bis[N-(1-naphthyl)-N-phenylamino]biphenyl (abbreviation: NPB or α-NPD), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]-spiro-9,9′-bifluorene (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N′-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), N,N-bis{4-[bis(3-methylphenyl)amino]phenyl}-N,N-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B).

Examples of the aromatic amine compound having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(1,1′-biphenyl-4-yl)-N-[4-(9-phenyl-9H-carbazol-3-yl)phenyl]-9,9dimethyl-9H-fluoren-2-amine (abbreviation: PCBBiF), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N-diphenylbenzene-1,3-diamine (abbreviation: PCA2B), N,N,N-triphenyl-N,N,N′-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-[4-(9-phenyl-9H-carbazol-3-yl)phenyl]-bis(9,9-dimethyl-9H-fluoren-2-yl)amine (abbreviation: PCBFF), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N-[4-(9-phenyl-9H-carbazol-3-yl)phenyl]-9,9-dimethyl-N-[4-(1-naphthyl)phenyl]-9H-fluoren-2-amine (abbreviation: PCBNBF), N-phenyl-N-[4-(9-phenyl-9H-carbazol-3-yl)phenyl]spiro-9,9′-bifluoren-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N-bis[4-(carbazol-9-yl)phenyl]-N,N-diphenyl-9,9-dimethylfluorene-2,7-diamine (abbreviation: YGA2F), and 4,4′,4″-tris(carbazol-9-yl)triphenylamine (abbreviation: TCTA).

Examples of the carbazole compound (not having a triarylamine skeleton) include 3-[4-(9-phenanthryl)-phenyl]-9-phenyl-9H-carbazole (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA). Furthermore, examples of the carbazole compound (not having a triarylamine skeleton) include 3,3′-bis(9-phenyl-9H-carbazole) (abbreviation: PCCP), 9-(1,1′-biphenyl-3-yl)-9′-(1,1′-biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: PNCCP), which are bicarbazole derivatives (e.g., a 3,3′-bicarbazole derivative).

Examples of the thiophene compound (the compound having a thiophene skeleton) include 1,3,5-tri(dibenzothiophen-4-yl)benzene (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Examples of the furan compound (the compound having a furan skeleton) include 4,4′,4″-(benzene-1,3,5-triyl)tri(dibenzofuran) (abbreviation: DBF3P-II), and 4-{3-[3-(9-phenyl-9H-fluoren-9-yl)phenyl]phenyl}dibenzofuran (abbreviation: mmDBFFLBi-II).

In addition, a high molecular compound such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), or poly[N,N-bis(4-butylphenyl)-N,N-bis(phenyl)benzidine](abbreviation: Poly-TPD) can also be used as the hole-transport material.

Note that the hole-transport material is not limited to the above, and one of or a combination of various known materials may be used as the hole-transport material.

As the acceptor material used for the hole-injection layer 111, an oxide of a metal belonging to any of Group 4 to Group 8 of the periodic table can be used. As specific examples, molybdenum oxide, vanadium oxide, niobium oxide, tantalum oxide, chromium oxide, tungsten oxide, manganese oxide, and rhenium oxide can be given. Among these, molybdenum oxide is particularly preferable since it is stable in the air, has a low hygroscopic property, and is easy to handle. It is also possible to use any of the above-described organic acceptor materials.

Note that the hole-injection layer 111 can be formed by any of various known deposition methods, and can be formed by a vacuum evaporation method, for example.

### <Hole-Transport Layer>

The hole-transport layer 112 is a layer transporting holes, which are injected from the first electrode 101 through the hole-injection layer 111, to the light-emitting layer 113. Note that the hole-transport layer 112 is a layer containing a hole-transport material. Thus, for the hole-transport layer 112, a hole-transport material that can be used for the hole-injection layer 111 can be used.

Note that in the light-emitting device of one embodiment of the present invention, the same organic compound as that for the hole-transport layer 112 is preferably used for the light-emitting layer 113. This is because the use of the same organic compounds for the hole-transport layer 112 and the light-emitting layer 113 allows efficient hole transport from the hole-transport layer 112 to the light-emitting layer 113.

### <Light-Emitting Layer>

The light-emitting layer 113 is a layer containing a light-emitting substance (an organic compound). There is no particular limitation on the light-emitting substance that can be used for the light-emitting layer 113, and it is possible to use a light-emitting substance that converts singlet excitation energy into light in the visible light range (e.g., a fluorescent substance) or a light-emitting substance that converts triplet excitation energy into light in the visible light range (e.g., a phosphorescent substance or a TADF material). In addition, a substance that exhibits emission color of blue, purple, bluish purple, green, yellow green, yellow, orange, red, or the like can be appropriately used.

The light-emitting layer 113 includes a light-emitting substance (a guest material) and one or more kinds of organic compounds (e.g., a host material). Note that as the organic compound (e.g., the host material) used here, it is preferable to use a substance whose energy gap is larger than the energy gap of the light-emitting substance (the guest material). Examples of one or more kinds of the organic compounds (e.g., the host material) include organic compounds such as a hole-transport material that can be used for the hole-transport layer 112 described above and an electron-transport material that can be used for the electron-transport layer 114 described later.

In the case where the light-emitting layer 113 includes the first organic compound, the second organic compound, and the light-emitting substance, the composition for a light-emitting device of one embodiment of the present invention, which is formed by mixing the first organic compound and the second organic compound, can be used. In such a case, it is possible to use an electron-transport material as the first organic compound, a hole-transport material as the second organic compound, and a phosphorescent substance, a fluorescent substance, a TADF material, or the like as the light-emitting substance. Furthermore, in such a case, a combination of the first organic compound and the second organic compound preferably forms an exciplex.

The light-emitting layer 113 may have a structure including a plurality of light-emitting layers containing different light-emitting substances to exhibit different emission colors (for example, white light emission obtained by a combination of complementary emission colors). Alternatively, a structure may be employed in which one light-emitting layer contains a plurality of different light-emitting substances.

Examples of the light-emitting substance that can be used for the light-emitting layer 113 are given below.

As an example of the light-emitting substance that converts singlet excitation energy into light, a substance that emits fluorescence (a fluorescent substance) can be given.

Example of the fluorescent substance that is the light-emitting substance that converts singlet excitation energy into light include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N-bis(3-methylphenyl)-N,N-bis[3-(9-phenyl-9H-fluoren-9-yl)phenyl]pyrene-1,6-diamine (abbreviation: 1,6mMemFLPAPrn), (N,N-diphenyl-N,N-bis[4-(9-phenyl-9H-fluoren-9-yl)phenyl]pyrene-1,6-diamine) (abbreviation: 1,6FLPAPrn), N,N-bis(dibenzofuran-2-yl)-N,N-diphenylpyrene-1,6-diamine (abbreviation: 1,6FrAPrn), N,N-bis(dibenzothiophen-2-yl)-N,N-diphenylpyrene-1,6-diamine (abbreviation: 1,6ThAPrn), N,N-(pyrene-1,6-diyl)bis[(N-phenylbenzo[b]naphtho[1,2-d]furan)-6-amine](abbreviation: 1,6BnfAPrn), N,N-(pyrene-1,6-diyl)bis[(N-phenylbenzo[b]naphtho[1,2-d]furan)-8-amine](abbreviation: 1,6BnfAPrn-02), and N,N-(pyrene-1,6-diyl)bis[(6,N-diphenylbenzo[b]naphtho[1,2-d]furan)-8-amine](abbreviation: 1,6BnfAPrn-03).

In addition, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N′-(2-tert-butylanthracene-9,10-diyldi-4,1-phenylene)bis[N,N,N-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), or the like.

Note that as the light-emitting substance that converts singlet excitation energy into light (the fluorescent substance), which can be used for the light-emitting layer 113, a fluorescent substance that exhibits emission color (an emission peak) in part of the near-infrared light range (e.g., a material that emits red light and has a peak at greater than or equal to 800 nm and less than or equal to 950 nm) can also be used without limitation to the above-described fluorescent substance that exhibits emission color (an emission peak) in the visible light range.

Next, as an example of the light-emitting substance that converts triplet excitation energy into light, a substance that emits phosphorescence (a phosphorescent substance) and a thermally activated delayed fluorescence (TADF) material that exhibits thermally activated delayed fluorescence can be given.

First, examples of the phosphorescent substance that is the light-emitting substance that converts triplet excitation energy into light include an organometallic complex, a metal complex (a platinum complex), and a rare earth metal complex. These substances exhibit different emission colors (emission peaks), and thus are used through appropriate selection as needed. Note that, of the phosphorescent substances, the following materials can be given as the material that exhibits emission color (an emission peak) in the visible light range.

The following substances can be given as examples of a phosphorescent substance which emits blue or green light and whose emission spectrum has a peak wavelength at greater than or equal to 450 nm and less than or equal to 570 nm (for example, preferably at greater than or equal to 450 nm and less than or equal to 495 nm in the case of blue light and at greater than or equal to 495 nm and less than or equal to 570 nm in the case of green light).

For example, organometallic complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organometallic complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptzl-Me)₃]); organometallic complexes having an imidazole skeleton, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); organometallic complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)); and the like can be given.

The following substances can be given as examples of a phosphorescent substance which emits green, yellow green, or yellow light and whose emission spectrum has a peak wavelength at greater than or equal to 495 nm and less than or equal to 590 nm. (For example, a peak wavelength at greater than or equal to 495 nm and less than or equal to 570 nm is preferable in the case of green light, a peak wavelength at greater than or equal to 530 nm and less than or equal to 570 nm is preferable in the case of yellow green light, and a peak wavelength at greater than or equal to 570 nm and less than or equal to 590 nm is preferable in the case of yellow light.)

The examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C2′)iridium(III) acetylacetonate (abbreviation: [Ir(pq)₂(acac)]), bis[2-(2-pyridinyl-κN)phenyl-κC][2-(4-phenyl-2-pyridinyl-κN)phenyl-κC]iridium(III) (abbreviation: [Ir(ppy)₂(4dppy)]), and [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]); organometallic complexes such as bis(2,4-diphenyl-1,3-oxazolato-N,C2′)iridium(III) acetylacetonate (abbreviation: [Ir(dpo)₂(acac)]), bis{2-[4′-(perfluorophenyl)phenyl]pyridinato-N,C^{2′}}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and rare earth metal complexes such as tris(acetylacetonato) (monophenanthroline)terbium(III) (abbreviation: [Tb(acac)₃(Phen)]).

The following substances can be given as examples of a phosphorescent substance which emits yellow, orange, or red light and whose emission spectrum has a peak wavelength at greater than or equal to 570 nm and less than or equal to 750 nm. (For example, a peak wavelength at greater than or equal to 570 nm and less than or equal to 590 nm is preferable in the case of yellow light, a peak wavelength at greater than or equal to 590 nm and less than or equal to 620 nm is preferable in the case of orange light, and a peak wavelength at greater than or equal to 600 nm and less than or equal to 750 nm is preferable in the case of red light.)

For example, organometallic complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(dlnpm)₂(dpm)]); organometallic complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-KN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), bis{4,6-dimethyl-2-[5-(5-cyano-2-methylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-m5CP)₂(dpm)]), (acetylacetonato)bis[2-methyl-3-phenylquinoxalinato-N,C^{2′}]iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), and bis[4,6-dimethyl-2-(2-quinolinyl-κN)phenyl-κC](2,4-pentanedionato-κ²O,O′)iridium(III) (abbreviation: [Ir(dmpqn)₂(acac)]); platinum complexes such as 2,3,7,8,12,13,17,18-octaethyl-21H,23H-porphyrinplatinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]) can be given.

As the material that can be used for the light-emitting layer, a phosphorescent substance that exhibits emission color (an emission peak) in part of the near-infrared light range (e.g., a material that emits red light and has a peak at greater than or equal to 800 nm and less than or equal to 950 nm), such as a phtalocyanine compound (central metal: aluminum, zinc, or the like), a naphthalocyanine compound, a dithiolene compound (central metal: nickel), a quinone-based compound, a diimonium-based compound, or an azo-based compound, can also be used without limitation to the above phosphorescent substance that exhibits emission color (an emission peak) in the visible light range.

The following materials can be used as the TADF material that is a light-emitting substance that converts triplet excitation energy into light. The TADF material is a material that can up-convert a triplet excited state into a singlet excited state (reverse intersystem crossing) using a little thermal energy and efficiently exhibits light emission (fluorescence) from the singlet excited state. The thermally activated delayed fluorescence is efficiently obtained under the condition where the energy difference between the triplet excited level and the singlet excited level is greater than or equal to 0 eV and less than or equal to 0.2 eV, preferably greater than or equal to 0 eV and less than or equal to 0.1 eV. Note that delayed fluorescence by the TADF material refers to light emission having a spectrum similar to that of normal fluorescence and an extremely long lifetime. The lifetime is 1×10⁻⁶ seconds or longer, preferably 1×10³ seconds or longer.

Specific examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

Alternatively, a heterocyclic compound having one or both of a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA), can also be used.

Note that a substance in which a π-electron rich heteroaromatic ring is directly bonded to a π-electron deficient heteroaromatic ring is particularly preferable because both the donor property of the π-electron rich heteroaromatic ring and the acceptor property of the π-electron deficient heteroaromatic ring are improved and the energy difference between the singlet excited state and the triplet excited state becomes small.

In the case where the above-described light-emitting substance (the light-emitting substance that converts singlet excitation energy into light in the visible light range (e.g., the fluorescent substance) or the light-emitting substance that converts triplet excitation energy into light in the visible light range (e.g., the phosphorescent substance or the TADF material)) is used in the light-emitting layer 113, the following organic compounds (some of them are the same as the above) are preferably used in addition to these light-emitting substances (the organic compounds). Thus, the composition for a light-emitting device of one embodiment of the present invention preferably includes these organic compounds.

First, in the case where the fluorescent substance is used as the light-emitting substance, it is preferable to use an organic compound of a condensed polycyclic aromatic compound or the like, such as an anthracene derivative, a tetracene derivative, a phenanthrene derivative, a pyrene derivative, a chrysene derivative, or a dibenzo[g,p]chrysene derivative, in combination.

Specific examples include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)-phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N,N,N″,N″,N″,N″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)-biphenyl-4′-yl}-anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

Thus, in the case where the fluorescent substance is used as the light-emitting substance and the composition for a light-emitting device of one embodiment of the present invention is used, the above organic compound is preferably included in the composition for a light-emitting device.

Furthermore, in the case where the phosphorescent substance is used as the light-emitting substance, an organic compound having triplet excitation energy (energy difference between a ground state and a triplet excited state) higher than the triplet excitation energy of the light-emitting substance is preferably used in combination. Other than such an organic compound, the organic compound having high hole-transport property (the second organic compound) and the organic compound having high electron-transport property (the first organic compound) may be used in combination.

Furthermore, other than such an organic compound, a plurality of organic compounds that can form an exciplex (e.g., the first organic compound and the second organic compound, a first host material and a second host material, or a host material and an assist material) may be used. Note that in the case where a plurality of organic compound are used to form an exciplex, a combination of a compound that easily accepts holes (a hole-transport material) and a compound that easily accepts electrons (an electron-transport material) can form an exciplex efficiently, which is preferable. In addition, when a phosphorescent substance and an exciplex are included in a light-emitting layer, ExTET (Exciplex-Triplet Energy Transfer), which is energy transfer from an exciplex to a light-emitting substance, can be performed efficiently, increasing emission efficiency. Note that a fluorescent substance and an exciplex may be included in a light-emitting layer.

Accordingly, in the case where the phosphorescent substance (or the fluorescent substance in some cases as described above) is used as the light-emitting substance and the composition for a light-emitting device of one embodiment of the present invention is used, it is preferable that the organic compound(s) (e.g., the organic compound having high triplet excitation energy, the first organic compound and the second organic compound, the first host material and the second host material, or the host material and the assist material) be included in the composition for a light-emitting device.

Any of the above materials may be used in combination with a low-molecular material or a high-molecular material. Specific examples of the high-molecular material include poly(2,5-pyridinediyl) (abbreviation: PPy), poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy). For the deposition, a known method (a vacuum evaporation method, a coating method, a printing method, or the like) can be used as appropriate.

### <Electron-Transport Layer>

The electron-transport layer 114 is a layer transporting electrons, which are injected from the second electrode 102 through the electron-injection layer 115 to be described later, to the light-emitting layer 113. Note that the electron-transport layer 114 is a layer containing an electron-transport material. As the electron-transport material used for the electron-transport layer 114, a substance having an electron mobility of greater than or equal to 1×10⁻⁶ cm²/Vs is preferable. Note that other substances can be used as long as they have a property of transporting more electrons than holes. The electron-transport layers (114, 114a, and 114b) each function even with a single-layer structure, but can improve the device characteristics when having a stacked-layer structure of two or more layers as needed.

A material having high electron-transport property, such as a π-electron deficient heteroaromatic compound, is preferable as the organic compound that can be used for the electron-transport layer 114. Furthermore, as the first organic compound used for the composition for a light-emitting device of one embodiment of the present invention, a material such as a π-electron deficient heteroaromatic compound is preferable among the materials included in the electron-transport materials. Examples of the π-electron deficient heteroaromatic compound include a compound having a benzofurodiazine skeleton in which a benzene ring as an aromatic ring is condensed with a furan ring of a furodiazine skeleton, a compound having a naphtofurodiazine skeleton in which a naphthyl ring as an aromatic ring is condensed with a furan ring of a furodiazine skeleton, a compound having a phenanthrofurodiazine skeleton in which a phenanthro ring as an aromatic ring is condensed with a furan ring of a furodiazine skeleton, a compound having a benzothienodiazine skeleton in which a benzene ring as an aromatic ring is condensed with a thieno ring of a thienodiazine skeleton, a compound having a naphthothienodiazine skeleton in which a naphthyl ring as an aromatic ring is condensed with a thieno ring of a thienodiazine skeleton, and a compound having a phenanthrothienodiazine skeleton in which a phenanthro ring as an aromatic ring is condensed with a thieno ring of a thienodiazine skeleton. Other examples include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a nitrogen-containing heteroaromatic compound.

Note that examples of the electron-transport material include 9-[(3′-dibenzothiophen-4-yl)biphenyl-3-yl]naphtho[1′,2′:4,5]furo[2,3-b]pyrazine (abbreviation: 9mDBtBPNfpr), 9-(9′-phenyl-3,3′-bi-9H-carbazol-9-yl)naphtho[1′,2′:4,5]furo[2,3-b]pyrazine (abbreviation: 9PCCzNfpr), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-[3-(9′-phenyl-2,3′-bi-9H-carbazol-9-yl)phenyl]naphtho[1′,2′:4,5]furo[2,3-b]pyrazine (abbreviation: 9mPCCzPNfpr-02), 10-[(3′-dibenzothiophen-4-yl)biphenyl-3-yl]naphtho[1′,2′:4,5]furo[2,3-b]pyrazine (abbreviation: 10mDBtBPNfpr), 10-(9′-phenyl-3,3′-bi-9H-carbazol-9-yl)naphtho[1′,2′:4,5]furo[2,3-b]pyrazine (abbreviation: 10PCCzNfpr), 12-[(3′-dibenzothiophen-4-yl)biphenyl-3-yl]phenanthro[9′,10′:4,5]furo[2,3-b]pyrazine (abbreviation: 12mDBtBPPnfpr), 9-[4-(9′-phenyl-3,3′-bi-9H-carbazol-9-yl)phenyl]naphtho[1′,2′:4,5]furo[2,3-b]pyrazine (abbreviation: 9pPCCzPNfpr), 9-[4-(9′-phenyl-2,3′-bi-9H-carbazol-9-yl)phenyl]naphtho[1′,2′: 4,5]furo[2,3-b]pyrazine (abbreviation: 9pPCCzPNfpr-02), 9-[3′-(6-phenylbenzo[b]naphtho[1,2-d]furan-8-yl)biphenyl-3-yl]naphtho[1′,2′: 4,5]furo[2,3-b]pyra zine (abbreviation: 9mBnfBPNfpr), 9-[3′-(6-phenyldibenzothiophen-4-yl)biphenyl-3-yl]naphtho[1′,2′: 4,5]furo[2,3-b]pyrazine (abbreviation: 9mDBtBPNfpr-02), 9-{3-[6-(9,9-dimethylfluoren-2-yl)dibenzothiophen-4-yl]phenyl}naphtho[1′,2′: 4,5]furo[2,3-b]pyrazine (abbreviation: 9mFDBtPNfpr), 11-(3-naphtho[1′,2′: 4,5]furo[2,3-b]pyrazin-9-yl-phenyl)-12-phenylindolo[2,3-a]carbazole (abbreviation: 9mIcz(II)PNfpr), 3-naphtho[1′,2′: 4,5]furo[2,3-b]pyrazin-9-yl-N,N-diphenylbenzenamine (abbreviation: 9mTPANfpr), 10-[4-(9′-phenyl-3,3′-bi-9H-carbazol-9-yl)phenyl]naphtho[1′,2′: 4,5]furo[2,3-b]pyrazine (abbreviation: 10mPCCzPNfpr), 11-[(3′-(dibenzothiophen-4-yl)biphenyl-3-yl]phenanthro[9′,10′: 4,5]furo[2,3-b]pyrazine (abbreviation: 11mDBtBPPnfpr), 10-[3-(9′-phenyl-3,3′-bi-9H-carbazol-9-yl)phenyl]naphtho[1′,2′: 4,5]furo[2,3-b]pyrazine (abbreviation: 10pPCCzPNfpr), 9-[3-(7H-dibenzo[c,g]carbazol-7-yl)phenyl]naphtho[1′,2′: 4,5]furo[2,3-b]pyrazine (abbreviation: 9mcgDBCzPNfpr), 9-{3′-[6-(biphenyl-3-yl)dibenzothiophen-4-yl]biphenyl-3-yl}naphtho[1′,2′: 4,5]furo[2,3-b]pyrazin e (abbreviation: 9mDBtBPNfpr-03), 9-{3′-[6-(biphenyl-4-yl)dibenzothiophen-4-yl]biphenyl-3-yl}naphtho[1′,2′: 4,5]furo[2,3-b]pyrazin e (abbreviation: 9mDBtBPNfpr-04), and 11-[3′-(6-phenyldibenzothiophen-4-yl)biphenyl-3-yl]phenanthro[9′,10′: 4,5]furo[2,3-b]pyrazine (abbreviation: 11mDBtBPPnfpr-02).

Alternatively, 4-[3-(dibenzothiophen-4-yl)phenyl]-8-(naphthalen-2-yl)-[1]benzofuro[3,2-d]pyrimidine (abbreviation: 8PN-4mDBtPBfpm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 4,8-bis[3-(dibenzothiophen-4-yl)phenyl]-[1]benzofuro[3,2-d]pyrimidine (abbreviation: 4,8mDBtP2Bfpm), 8-[(2,2′-binaphthalen)-6-yl]-4-[3-(dibenzothiophen-4-yl)phenyl-[1]benzofuro[3,2-d]pyrimidine (abbreviation: 8(PN2)-4mDBtPBfpm), 3,8-bis[3-(dibenzothiophen-4-yl)phenyl]benzofuro[2,3-b]pyrazine (abbreviation: 3,8mDBtP2Bfpr), 8-[3′-(dibenzothiophen-4-yl)(1,1′-biphenyl-3-yl)]naphtho[1′,2′:4,5]furo[3,2-d]pyrimidine (abbreviation: 8mDBtBPNfpm), or the like can be used.

Further alternatively, a metal complex having a quinoline skeleton or a benzoquinoline skeleton, such as tris(8-quinolinolato)aluminum(III) (abbreviation: Alq₃), tris(4-methyl-8-quinolinolato)aluminum (abbreviation: Almq₃), bis(10-hydroxybenzo[h]quinolinato)beryllium (abbreviation: BeBq₂), bis(2-methyl-8-quinolinolato) (4-phenylphenolato)aluminum(III) (abbreviation: BAlq), or bis(8-quinolinolato)zinc(II) (abbreviation: Znq), a metal complex having an oxazole skeleton or a thiazole skeleton, such as bis[2-(2-benzoxazolyl)phenolato]zinc(II) (abbreviation: ZnPBO) or bis[2-(2-benzothiazolyl)phenolato]zinc(II) (abbreviation: ZnBTZ), or the like can be used.

Still further alternatively, any of the following can be used: an oxadiazole derivative such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), or 9-[4-(5-phenyl-1,3,4-oxadiazol-2-yl)phenyl]-9H-carbazole (abbreviation: COl1); a triazole derivative such as 3-(4-biphenylyl)-4-phenyl-5-(4-tert-butylphenyl)-1,2,4-triazole (abbreviation: TAZ) or 3-(4-tert-butylphenyl)-4-(4-ethylphenyl)-5-(4-biphenylyl)-1,2,4-triazole (abbreviation: p-EtTAZ); an imidazole derivative (including a benzimidazole derivative) such as 2,2′,2″-(1,3,5-benzenetriyl)tris(1-phenyl-1H-benzimidazole) (abbreviation: TPBI) or 2-[3-(dibenzothiophen-4-yl)phenyl]-1-phenyl-1H-benzimidazole (abbreviation: mDBTBIm-II); an oxazole derivative such as 4,4′-bis(5-methylbenzoxazol-2-yl)stilbene (abbreviation: BzOs); a phenanthroline derivative such as bathophenanthroline (abbreviation: Bphen), bathocuproine (abbreviation: BCP), or 2,9-bis(naphthalen-2-yl)-4,7-diphenyl-1,10-phenanthroline (abbreviation: NBphen); a quinoxaline derivative or a dibenzoquinoxaline derivative such as 2-[3-(dibenzothiophen-4-yl)phenyl]dibenzo[f;h]quinoxaline (abbreviation: 2mDBTPDBq-II), 2-[3′-(dibenzothiophen-4-yl)biphenyl-3-yl]dibenzo[f;h]quinoxaline (abbreviation: 2mDBTBPDBq-II), 2-[3′-(9H-carbazol-9-yl)biphenyl-3-yl]dibenzo[f;h]quinoxaline (abbreviation: 2mCzBPDBq), 2-[4-(3, 6-diphenyl-9H-carbazol-9-yl)phenyl]dibenzo[f;h]quinoxaline (abbreviation: 2CzPDBq-III), 7-[3-(dibenzothiophen-4-yl)phenyl]dibenzo[f;h]quinoxaline (abbreviation: 7mDBTPDBq-II), or 6-[3-(dibenzothiophen-4-yl)phenyl]dibenzo[f;h]quinoxaline (abbreviation: 6mDBTPDBq-II); a pyridine derivative such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); a pyrimidine derivative such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,6-bis[3-(9H-carbazol-9-yl)phenyl]pyrimidine (abbreviation: 4,6mCzP2Pm); and a triazine derivative such as 2-{4-[3-(N-phenyl-9H-carbazol-3-yl)-9H-carbazol-9-yl]phenyl}-4,6-diphenyl-1,3,5-triazine (abbreviation: PCCzPTzn), mPCCzPTzn-02, 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), or 2-{3-[3-(dibenzothiophen-4-yl)phenyl]phenyl}-4,6-diphenyl-1,3,5-triazine (abbreviation: mDBtBPTzn).

It is also possible to use a high-molecular compound such as PPy, PF-Py, or PF-BPy.

### <Electron-Injection Layer>

The electron-injection layer 115 is a layer for increasing the efficiency of electron injection from the second electrode 102 that is a cathode; thus, the electron-injection layer 115 is preferably formed using a material whose LUMO level value has a small difference (0.5 eV or less) from the work function value of the material of the second electrode 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-(quinolinolato)-lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. A rare earth metal compound like erbium fluoride (ErF₃) can also be used.

When a charge-generation layer 104 is provided between two EL layers (103a and 103b) as in the light-emitting device illustrated in FIG. 1B, a structure in which a plurality of EL layers are stacked between the pair of electrodes (also referred to as a tandem structure) can be employed. Note that in this embodiment, functions and materials of the hole-injection layer (111), the hole-transport layer (112), the light-emitting layer (113), the electron-transport layer (114), and the electron-injection layer (115) that are illustrated in FIG. 1A are the same as those of hole-injection layers (111a and 111b), hole-transport layers (112a and 112b), light-emitting layers (113a and 113b), electron-transport layers (114a and 114b), and electron-injection layers (115a and 115b) that are illustrated in FIG. 1B.

### <Charge-Generation Layer>

In the light-emitting device of FIG. 1B, the charge-generation layer 104 has a function of injecting electrons into the EL layer 103a and injecting holes into the EL layer 103b when voltage is applied between the first electrode (anode) 101 and the second electrode (cathode) 102. Note that the charge-generation layer 104 may have either a structure in which an electron acceptor (acceptor) is added to a hole-transport material or a structure in which an electron donor (donor) is added to an electron-transport material. Alternatively, both of these structures may be stacked. Note that forming the charge-generation layer 104 with the use of any of the above materials can suppress an increase in drive voltage in the case where the EL layers are stacked.

In the case where the charge-generation layer 104 has a structure in which an electron acceptor is added to a hole-transport material, any of the materials described in this embodiment can be used as the hole-transport material. As the electron acceptor, 7,7,8,8-tetracyano-2,3,5,6-tetrafluoroquinodimethane (abbreviation: F₄-TCNQ), chloranil, and the like can be given. Other examples include oxides of metals belonging to Group 4 to Group 8 of the periodic table. Specific examples are vanadium oxide, niobium oxide, tantalum oxide, chromium oxide, molybdenum oxide, tungsten oxide, manganese oxide, and rhenium oxide.

In the case where the charge-generation layer 104 has a structure in which an electron donor is added to an electron-transport material, any of the materials described in this embodiment can be used as the electron-transport material. As the electron donor, it is possible to use an alkali metal, an alkaline earth metal, a rare earth metal, metals belonging to Groups 2 and 13 of the periodic table, or an oxide or carbonate thereof. Specifically, lithium (Li), cesium (Cs), magnesium (Mg), calcium (Ca), ytterbium (Yb), indium (In), lithium oxide, cesium carbonate, or the like is preferably used. An organic compound such as tetrathianaphthacene may be used as the electron donor.

Although FIG. 1B illustrates the structure in which two EL layers 103 are stacked, a structure may be employed in which three or more EL layers are stacked with a charge-generation layer provided between different EL layers. The light-emitting layers 113 (113a and 113b) included in the EL layers (103, 103a, and 103b) each include an appropriate combination of a light-emitting substance and a plurality of substances, so that fluorescence or phosphorescence of a desired emission color can be obtained. In the case where a plurality of light-emitting layers 113 (113a and 113b) are provided, emission colors of the respective light-emitting layers may be different from each other. In that case, light-emitting substances and other substances are different between the stacked light-emitting layers. For example, the light-emitting layer 113a can be blue, and the light-emitting layer 113b can be red, green, or yellow; for another example, the light-emitting layer 113a can be red, and the light-emitting layer 113b can be blue, green, or yellow. Furthermore, in the case where three or more EL layers are stacked, the light-emitting layer (113a) of the first EL layer can be blue, the light-emitting layer (113b) of the second EL layer can be red, green, or yellow, and a light-emitting layer of the third EL layer can be blue. For another example, the light-emitting layer (113a) of the first EL layer can be red, the light-emitting layer (113b) of the second EL layer can be blue, green, or yellow, and the light-emitting layer of the third EL layer can be red. Note that another combination of emission colors can be employed as appropriate in consideration of luminance and characteristics of the plurality of emission colors.

### <Substrate>

The light-emitting device described in this embodiment can be formed over any of a variety of substrates. Note that the type of the substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, and a base material film.

Note that examples of the glass substrate include barium borosilicate glass, aluminoborosilicate glass, and soda lime glass. Examples of the flexible substrate, the attachment film, and the base material film include plastics typified by polyethylene terephthalate (PET), polyethylene naphthalate (PEN), and polyether sulfone (PES); a synthetic resin such as an acrylic resin; polypropylene; polyester; polyvinyl fluoride; polyvinyl chloride; polyamide; polyimide; an aramid resin; an epoxy resin; an inorganic vapor deposition film; and paper.

For fabrication of the light-emitting device in this embodiment, a vacuum process such as an evaporation method or a solution process such as a spin coating method or an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the functional layers (the hole-injection layers (111, 111a, and 111b), the hole-transport layers (112, 112a, and 112b), the light-emitting layers (113, 113a, and 113b), the electron-transport layers (114, 114a, and 114b), the electron-injection layers (115, 115a, and 115b), and the charge-generation layers (104, 104a, and 104b)) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, a micro-contact printing method, or a nanoimprinting method), or the like.

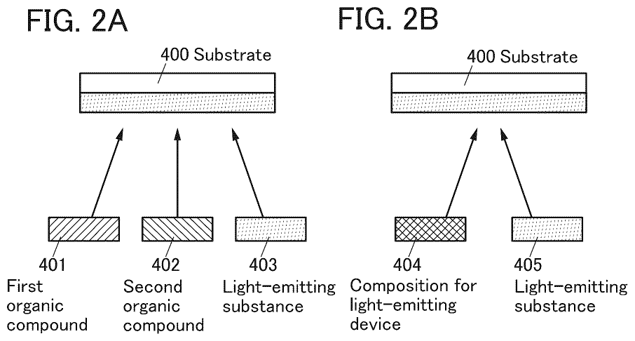

Note that in the case where the functional layer included in the EL layer of the light-emitting device is formed using the composition for a light-emitting device of one embodiment of the present invention, it is particularly preferable to employ an evaporation method. For example, in the case where three kinds of materials (the light-emitting substance, the first organic compound, and the second organic compound) are used for forming the light-emitting layer (113, 113a, or 113b), the same number of evaporation sources (three in this case) as the number of the materials to be evaporated are used as illustrated in FIG. 2A, a first organic compound 401, a second organic compound 402, and a light-emitting substance 403 are put in the respective evaporation sources and co-evaporation is performed; thus, the light-emitting layer (113, 113a, or 113b) that is a mixed film of the three kinds of evaporation materials is formed over a surface of a substrate 400. In the case where the composition for a light-emitting device in which the first organic compound and the second organic compound of the three kinds of materials are mixed is used, two kinds of evaporation sources are used as illustrated in FIG. 2B even though three kinds of materials are used for forming the light-emitting layer (113, 113a, or 113b), a composition 404 for a light-emitting device and a light-emitting substance 405 are put in the respective evaporation sources and co-evaporation is performed; thus, the light-emitting layer (113, 113a, or 113b) that is a mixed film the same as the mixed film formed using three kinds of evaporation sources can be formed.

The composition for a light-emitting device is obtained by mixing compounds having a specific molecular structure as described in Embodiment 1; therefore, even though a plurality of unspecific compounds are mixed to be put in one evaporation source and evaporation is performed, it is difficult to obtain a film with a quality substantially the same as that in the case where the compounds are put in different evaporation sources and co-evaporation is performed. For example, there arise problems in that composition is changed because part of the mixed material is deposited first, a film with desired quality (e.g., composition and film thickness) is not obtained, and the like. In addition, in the mass-producing process, troubles such as complexity of apparatus specifications and increase in effort for maintenance occur.

Thus, with the use of the composition for a light-emitting device of one embodiment of the present invention for part of an EL layer or a light-emitting layer, a highly productive light-emitting device can be manufactured while device characteristics and reliability of the light-emitting device are maintained, which can be said to be preferable.

Note that materials that can be used for the functional layers (the hole-injection layers (111, 111a, and 111b), the hole-transport layers (112, 112a, and 112b), the light-emitting layers (113, 113a, 113b, and 113c), the electron-transport layers (114, 114a, and 114b), the electron-injection layers (115, 115a, and 115b), and the charge-generation layers (104, 104a, and 104b)) included in the EL layers (103, 103a, and 103b) of the light-emitting device described in this embodiment are not limited to the above materials, and other materials can also be used in combination as long as the functions of the layers are fulfilled. For example, a high molecular compound (e.g., an oligomer, a dendrimer, and a polymer), a middle molecular compound (a compound between a low molecular compound and a high molecular compound with a molecular mass of 400 to 4000), or an inorganic compound (e.g., a quantum dot material) can be used. As the quantum dot material, a colloidal quantum dot material, an alloyed quantum dot material, a core-shell quantum dot material, a core quantum dot material, or the like can be used.

The structure described in this embodiment can be used in an appropriate combination with any of the structures described in the other embodiments.

### Embodiment 3

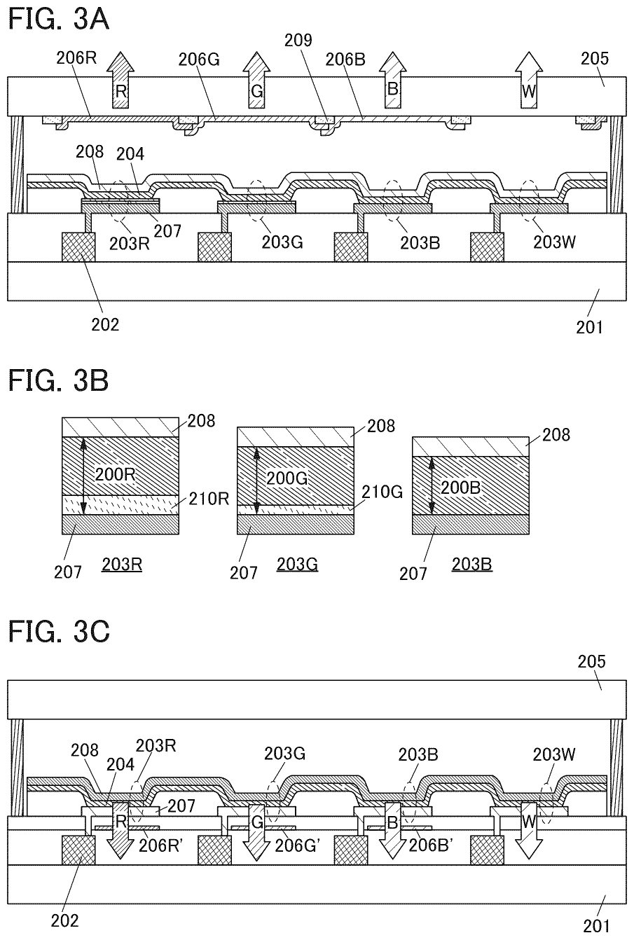

In this embodiment, a light-emitting apparatus of one embodiment of the present invention is described. Note that a light-emitting apparatus shown in FIG. 3A is an active-matrix light-emitting apparatus in which transistors (FETs) 202 over a first substrate 201 are electrically connected to light-emitting devices (203R, 203G, 203B, and 203W); the light-emitting devices (203R, 203G, 203B, and 203W) include a common EL layer 204 and each have a microcavity structure in which the optical path length between electrodes of each light-emitting device is adjusted according to the emission color of the light-emitting device. In addition, the light-emitting apparatus is a top-emission light-emitting apparatus in which light is emitted from the EL layer 204 through color filters (206R, 206G, and 206B) formed on a second substrate 205.

In the light-emitting apparatus shown in FIG. 3A, a first electrode 207 is formed so as to function as a reflective electrode. A second electrode 208 is formed so as to function as a semi-transmissive and semi-reflective electrode. Note that description in any of the other embodiments can be referred to for electrode materials forming the first electrode 207 and the second electrode 208 and appropriate materials can be used.

In the case where the light-emitting device 203R is a red-light-emitting device, the light-emitting device 203G is a green-light-emitting device, the light-emitting device 203B is a blue-light-emitting device, and the light-emitting device 203W is a white-light-emitting device in FIG. 3A, for example, the gap between the first electrode 207 and the second electrode 208 in the light-emitting device 203R is adjusted to have an optical path length 200R, the gap between the first electrode 207 and the second electrode 208 in the light-emitting device 203G is adjusted to have an optical path length 200G, and the gap between the first electrode 207 and the second electrode 208 in the light-emitting device 203B is adjusted to have an optical path length 200B as shown in FIG. 3B. Note that optical adjustment can be performed in such a manner that a conductive layer 210R is stacked over the first electrode 207 in the light-emitting device 203R and a conductive layer 210G is stacked over the first electrode 207 in the light-emitting device 203G as shown in FIG. 3B.

The color filters (206R, 206G, and 206B) are formed on the second substrate 205. Note that the color filters each transmit visible light in a specific wavelength range and block visible light in a specific wavelength range. Thus, as shown in FIG. 3A, the color filter 206R that transmits only light in the red wavelength range is provided in a position overlapping with the light-emitting device 203R, whereby red light emission can be obtained from the light-emitting device 203R. The color filter 206G that transmits only light in the green wavelength range is provided in a position overlapping with the light-emitting device 203G, whereby green light emission can be obtained from the light-emitting device 203G. The color filter 206B that transmits only light in the blue wavelength range is provided in a position overlapping with the light-emitting device 203B, whereby blue light emission can be obtained from the light-emitting device 203B. Note that the light-emitting device 203W can emit white light without a color filter. Note that a black layer (a black matrix) 209 may be provided at an end portion of one type of color filter. The color filters (206R, 206G, and 206B) and the black layer 209 may be covered with an overcoat layer using a transparent material.

Although the light-emitting apparatus shown in FIG. 3A has a structure in which light is extracted from the second substrate 205 side (a top emission structure), the light-emitting apparatus may have a structure in which light is extracted from the first substrate 201 side where the FETs 202 are formed (a bottom emission structure) as shown in FIG. 3C. For a bottom-emission light-emitting apparatus, the first electrode 207 is formed so as to function as a semi-transmissive and semi-reflective electrode and the second electrode 208 is formed so as to function as a reflective electrode. As the first substrate 201, a substrate having at least a light-transmitting property is used. As shown in FIG. 3C, color filters (206R′, 206G′, and 206B′) are provided closer to the first substrate 201 than the light-emitting devices (203R, 203G, and 203B) are.

FIG. 3A shows the case where the light-emitting devices are the red-light-emitting device, the green-light-emitting device, the blue-light-emitting device, and the white-light-emitting device; however, the light-emitting devices of embodiments of the present invention are not limited to the above structures, and a yellow-light-emitting device or an orange-light-emitting device may be included. Note that description in any of the other embodiments can be referred to for materials that are used for the EL layers (a light-emitting layer, a hole-injection layer, a hole-transport layer, an electron-transport layer, an electron-injection layer, a charge-generation layer, and the like) to fabricate each of the light-emitting devices and appropriate materials can be used. In that case, a color filter needs to be appropriately selected according to the emission color of the light-emitting device.

With the above structure, a light-emitting apparatus including light-emitting devices that exhibit a plurality of emission colors can be obtained.

Note that the structures described in this embodiment can be used in an appropriate combination with any of the structures described in the other embodiments.

### Embodiment 4

In this embodiment, a light-emitting apparatus of one embodiment of the present invention is described.

The use of the device structure of the light-emitting device of one embodiment of the present invention allows fabrication of an active-matrix light-emitting apparatus or a passive-matrix light-emitting apparatus. Note that an active-matrix light-emitting apparatus has a structure including a combination of a light-emitting device and a transistor (FET). Thus, each of a passive-matrix light-emitting apparatus and an active-matrix light-emitting apparatus is included in one embodiment of the present invention. Note that any of the light-emitting devices described in the other embodiments can be used in the light-emitting apparatus described in this embodiment.

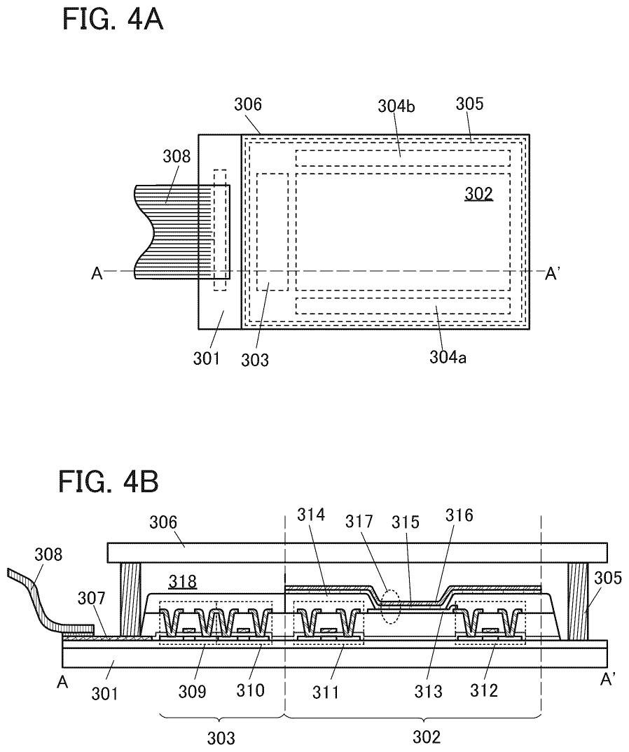

In this embodiment, an active-matrix light-emitting apparatus is described with reference to FIG. 4.

FIG. 4A is a top view showing a light-emitting apparatus, and FIG. 4B is a cross-sectional view taken along a chain line A-A′ in FIG. 4A. The active-matrix light-emitting apparatus includes a pixel portion 302, a driver circuit portion (source line driver circuit) 303, and driver circuit portions (gate line driver circuits) (304a and 304b) that are provided over a first substrate 301. The pixel portion 302 and the driver circuit portions (303, 304a, and 304b) are sealed between the first substrate 301 and a second substrate 306 with a sealant 305.

A lead wiring 307 is provided over the first substrate 301. The lead wiring 307 is electrically connected to an FPC 308 which is an external input terminal. Note that the FPC 308 transmits a signal (e.g., a video signal, a clock signal, a start signal, or a reset signal) or a potential from the outside to the driver circuit portions (303, 304a, and 304b). The FPC 308 may be provided with a printed wiring board (PWB). Note that the light-emitting apparatus provided with an FPC or a PWB is included in the category of a light-emitting apparatus.

Next, the cross-sectional structure is shown in FIG. 4B.

The pixel portion 302 is made up of a plurality of pixels each of which includes an FET (a switching FET) 311, an FET (a current control FET) 312, and a first electrode 313 electrically connected to the FET 312. Note that the number of FETs included in each pixel is not particularly limited and can be set appropriately as needed.

As FETs 309, 310, 311, and 312, for example, a staggered transistor or an inverted staggered transistor can be used without particular limitation. A top-gate transistor, a bottom-gate transistor, or the like may be used.

Note that there is no particular limitation on the crystallinity of a semiconductor that can be used for the FETs 309, 310, 311, and 312, and an amorphous semiconductor or a semiconductor having crystallinity (a microcrystalline semiconductor, a polycrystalline semiconductor, a single crystal semiconductor, or a semiconductor partly including crystal regions) may be used. The use of a semiconductor having crystallinity is preferable because deterioration of the transistor characteristics can be inhibited.

For these semiconductors, a Group 14 element, a compound semiconductor, an oxide semiconductor, an organic semiconductor, or the like can be used, for example. Typically, a semiconductor containing silicon, a semiconductor containing gallium arsenide, an oxide semiconductor containing indium, or the like can be used.

The driver circuit portion 303 includes the FET 309 and the FET 310. The FET 309 and the FET 310 may be formed with a circuit including transistors having the same conductivity type (either n-channel transistors or p-channel transistors) or a CMOS circuit including an n-channel transistor and a p-channel transistor. Furthermore, a structure including a driver circuit outside may be employed.

An end portion of the first electrode 313 is covered with an insulator 314. For the insulator 314, an organic compound such as a negative photosensitive resin or a positive photosensitive resin (an acrylic resin), or an inorganic compound such as silicon oxide, silicon oxynitride, or silicon nitride can be used. An upper end portion or a lower end portion of the insulator 314 preferably has a curved surface with curvature. In that case, favorable coverage with a film formed over the insulator 314 can be obtained.

An EL layer 315 and a second electrode 316 are stacked over the first electrode 313. The EL layer 315 includes a light-emitting layer, a hole-injection layer, a hole-transport layer, an electron-transport layer, an electron-injection layer, a charge-generation layer, and the like.

The structure and materials described in any of the other embodiments can be used for the structure of a light-emitting device 317 described in this embodiment. Although not shown here, the second electrode 316 is electrically connected to the FPC 308 which is an external input terminal.

Although the cross-sectional view in FIG. 4B shows only one light-emitting device 317, a plurality of light-emitting devices are arranged in a matrix in the pixel portion 302. Light-emitting devices from which light of three kinds of colors (R, G, and B) are obtained are selectively formed in the pixel portion 302, whereby a light-emitting apparatus capable of full-color display can be formed. In addition to the light-emitting devices from which light of three kinds of colors (R, G, and B) are obtained, for example, light-emitting devices from which light of white (W), yellow (Y), magenta (M), cyan (C), and the like are obtained may be formed. For example, the light-emitting devices from which light of some of the above colors are obtained are added to the light-emitting devices from which light of three kinds of colors (R, G, and B) are obtained, whereby effects such as an improvement in color purity and a reduction in power consumption can be obtained. Alternatively, a light-emitting apparatus that is capable of full-color display may be fabricated by a combination with color filters. As the kinds of color filters, red (R), green (G), blue (B), cyan (C), magenta (M), and yellow (Y) color filters and the like can be used.

When the second substrate 306 and the first substrate 301 are bonded to each other with the sealant 305, the FETs (309, 310, 311, and 312) and the light-emitting device 317 over the first substrate 301 are provided in a space 318 surrounded by the first substrate 301, the second substrate 306, and the sealant 305. Note that the space 318 may be filled with an inert gas (e.g., nitrogen or argon) or an organic substance (including the sealant 305).

An epoxy resin or glass frit can be used for the sealant 305. It is preferable to use a material that is permeable to as little moisture and oxygen as possible for the sealant 305. For the second substrate 306, a material that can be used for the first substrate 301 can be similarly used. Thus, any of the various substrates described in the other embodiments can be appropriately used. As the substrate, a glass substrate, a quartz substrate, or a plastic substrate made of FRP (Fiber-Reinforced Plastics), PVF (polyvinyl fluoride), polyester, an acrylic resin, or the like can be used. In the case where glass frit is used for the sealant, the first substrate 301 and the second substrate 306 are preferably glass substrates in terms of adhesion.

In the above manner, the active-matrix light-emitting apparatus can be obtained.

In the case where the active-matrix light-emitting apparatus is formed over a flexible substrate, the FETs and the light-emitting device may be directly formed over the flexible substrate; alternatively, the FETs and the light-emitting device may be formed over a substrate provided with a separation layer and then separated at the separation layer by application of heat, force, laser irradiation, or the like to be transferred to a flexible substrate. For the separation layer, a stack of inorganic films such as a tungsten film and a silicon oxide film, or an organic resin film of polyimide or the like can be used, for example. Examples of the flexible substrate include, in addition to a substrate over which a transistor can be formed, a paper substrate, a cellophane substrate, an aramid film substrate, a polyimide film substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, high durability, high heat resistance, a reduction in weight, and a reduction in thickness can be achieved.

The light-emitting device included in the active-matrix light-emitting apparatus may be driven with a structure in which pulsed light (with a frequency of kHz or MHz, for example) emitted from the light-emitting device is used for display. The light-emitting device formed using any of the above organic compounds has excellent frequency characteristics; thus, time for driving the light-emitting device can be shortened, and thus the power consumption can be reduced. Furthermore, a reduction in driving time leads to inhibition of heat generation, so that the degree of deterioration of the light-emitting device can be reduced.

Note that the structures described in this embodiment can be used in an appropriate combination with the structures described in the other embodiments.

### Embodiment 5

In this embodiment, examples of a variety of electronic devices and an automobile completed using the light-emitting device of one embodiment of the present invention or a light-emitting apparatus including the light-emitting device of one embodiment of the present invention are described. Note that the light-emitting apparatus can be used mainly in a display portion of the electronic device described in this embodiment.

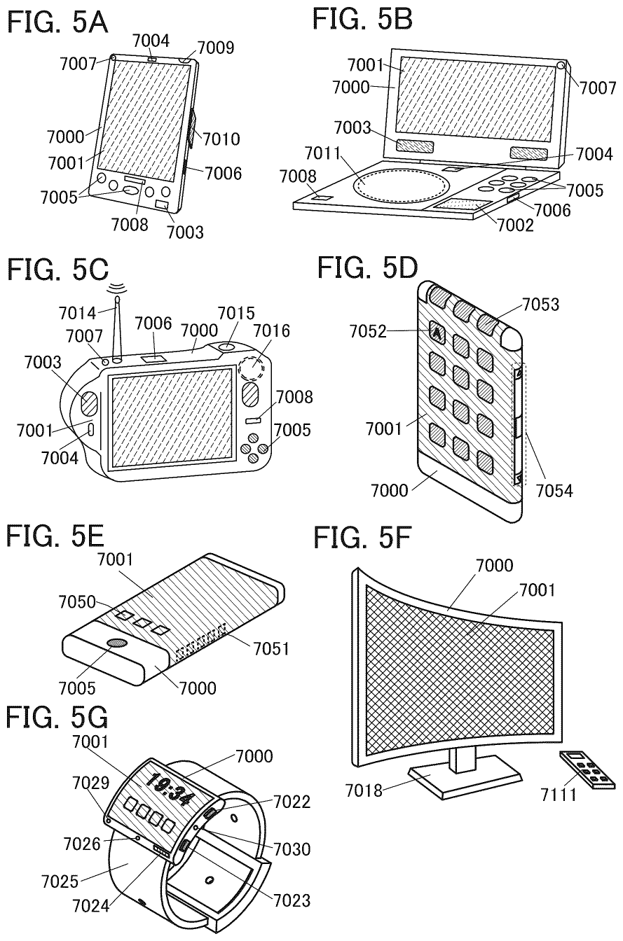

Electronic devices shown in FIG. 5A to FIG. 5E can include a housing 7000, a display portion 7001, a speaker 7003, an LED lamp 7004, operation keys 7005 (including a power switch or an operation switch), a connection terminal 7006, a sensor 7007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 7008, and the like.

FIG. 5A is a mobile computer which can include a switch 7009, an infrared port 7010, and the like in addition to the above components.

FIG. 5B is a portable image reproducing device (e.g., a DVD player) which is provided with a recording medium and can include a second display portion 7002, a recording medium reading portion 7011, and the like in addition to the above components.

FIG. 5C is a digital camera with a television reception function, which can include an antenna 7014, a shutter button 7015, an image receiving portion 7016, and the like in addition to the above components.

FIG. 5D is a portable information terminal. The portable information terminal has a function of displaying information on three or more surfaces of the display portion 7001. Here, an example in which information 7052, information 7053, and information 7054 are displayed on different surfaces is shown. For example, the user can check the information 7053 displayed in a position that can be observed from above the portable information terminal, with the portable information terminal put in a breast pocket of his/her clothes. The user can see the display without taking out the portable information terminal from the pocket and decide whether to answer the call, for example.

FIG. 5E is a portable information terminal (e.g., a smartphone) and can include the display portion 7001, the operation key 7005, and the like in the housing 7000. Note that a speaker, a connection terminal, a sensor, or the like may be provided in the portable information terminal. The portable information terminal can display characters and image information on its plurality of surfaces. Here, an example in which three icons 7050 are displayed is shown. Information 7051 indicated by dashed rectangles can be displayed on another surface of the display portion 7001. Examples of the information 7051 include notification of reception of an e-mail, SNS, or an incoming call, the title and sender of an e-mail, SNS, or the like, the date, the time, remaining battery, and the reception strength of an antenna. Alternatively, the icon 7050 or the like may be displayed in the position where the information 7051 is displayed.

FIG. 5F is a large-size television set (also referred to as TV or a television receiver), which can include the housing 7000, the display portion 7001, and the like. In addition, shown here is a structure where the housing 7000 is supported by a stand 7018. The television set can be operated with a separate remote controller 7111 or the like. Note that the display portion 7001 may include a touch sensor, in which case the television set may be operated by touch on the display portion 7001 with a finger or the like. The remote controller 7111 may be provided with a display portion for displaying information output from the remote controller 7111. With operation keys or a touch panel provided in the remote controller 7111, channels and volume can be operated and images displayed on the display portion 7001 can be operated.

The electronic devices shown in FIG. 5A to FIG. 5F can have a variety of functions. For example, they can have a function of displaying a variety of data (e.g., a still image, a moving image, and a text image) on the display portion, a touch panel function, a function of displaying a calendar, date, time, or the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion. Furthermore, the electronic device including a plurality of display portions can have a function of displaying image data mainly on one display portion while displaying text data mainly on another display portion, a function of displaying a three-dimensional image by displaying images on a plurality of display portions with a parallax taken into account, or the like. Furthermore, the electronic device including an image receiving portion can have a function of taking a still image, a function of taking a moving image, a function of automatically or manually correcting a taken image, a function of storing a taken image in a recording medium (an external recording medium or a recording medium incorporated in the camera), a function of displaying a taken image on the display portion, or the like. Note that functions that the electronic devices shown in FIG. 5A to FIG. 5F can have are not limited to those, and the electronic devices can have a variety of functions.

FIG. 5G is a watch-type portable information terminal, which can be used as a smart watch, for example. The watch-type portable information terminal includes the housing 7000, the display portion 7001, operation buttons 7022 and 7023, a connection terminal 7024, a band 7025, a microphone 7026, a sensor 7029, a speaker 7030, and the like. The display surface of the display portion 7001 is bent, and display can be performed along the bent display surface. Furthermore, mutual communication between the portable information terminal and, for example, a headset capable of wireless communication can be performed, and thus hands-free calling is possible with the portable information terminal. With the connection terminal 7024, the portable information terminal can perform mutual data transmission with another information terminal and charging. Wireless power feeding can also be employed for the charging operation.

The display portion 7001 mounted in the housing 7000 also serving as a bezel includes a non-rectangular display region. The display portion 7001 can display an icon indicating time, another icon, and the like. The display portion 7001 may be a touch panel (input/output device) including a touch sensor (an input device).

Note that the smart watch shown in FIG. 5G can have a variety of functions. For example, the smart watch can have a function of displaying a variety of data (e.g., a still image, a moving image, and a text image) on the display portion, a touch panel function, a function of displaying a calendar, date, time, or the like, a function of controlling processing with a variety of software (programs), a wireless communication function, a function of being connected to a variety of computer networks with a wireless communication function, a function of transmitting and receiving a variety of data with a wireless communication function, and a function of reading out a program or data stored in a recording medium and displaying it on the display portion.

Moreover, a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like can be included inside the housing 7000.

Note that the light-emitting apparatus of one embodiment of the present invention can be used in the display portions of the electronic devices described in this embodiment, enabling the electronic devices to have a long lifetime.

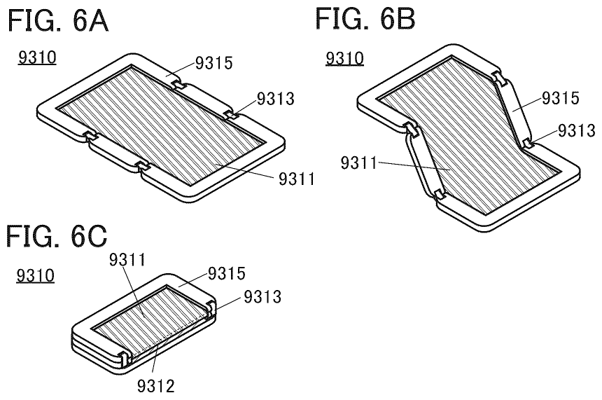

Another electronic device including the light-emitting apparatus is a foldable portable information terminal shown in FIG. 6A to FIG. 6C. FIG. 6A shows a portable information terminal 9310 which is opened. FIG. 6B shows the portable information terminal 9310 in a state in the middle of change from one of an opened state and a folded state to the other. FIG. 6C illustrates the portable information terminal 9310 which is folded. The portable information terminal 9310 is excellent in portability when folded, and is excellent in display browsability when opened because of a seamless large display region.

A display portion 9311 is supported by three housings 9315 joined together by hinges 9313. Note that the display portion 9311 may be a touch panel (an input/output device) including a touch sensor (an input device). By bending the display portion 9311 at a portion between two housings 9315 with the use of the hinges 9313, the portable information terminal 9310 can be reversibly changed in shape from an opened state to a folded state. The light-emitting apparatus of one embodiment of the present invention can be used for the display portion 9311. An electronic device having a long lifetime can be provided. A display region 9312 in the display portion 9311 is a display region that is positioned at a side surface of the portable information terminal 9310 which is folded. On the display region 9312, information icons, file shortcuts of frequently used applications or programs, and the like can be displayed, and confirmation of information and start of an application can be smoothly performed.

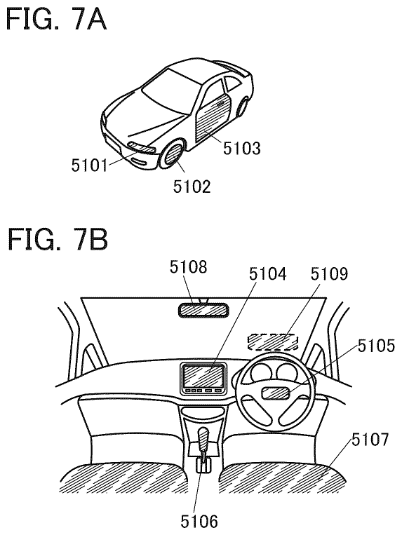

FIG. 7A and FIG. 7B show an automobile including the light-emitting apparatus. In other words, the light-emitting apparatus can be integrated into an automobile. Specifically, the light-emitting apparatus can be applied to lights 5101 (including lights of the rear part of the car), a wheel 5102, a part or the whole of a door 5103, or the like on the outer side of the automobile shown in FIG. 7A. The light-emitting apparatus can also be applied to a display portion 5104, a steering wheel 5105, a shifter 5106, a seat 5107, an inner rearview mirror 5108, a windshield 5109, or the like on the inner side of the automobile shown in FIG. 7B. The light-emitting apparatus may be used for part of any of the other glass windows.

In the above manner, the electronic devices and automobiles in which the light-emitting apparatus of one embodiment of the present invention is used can be obtained. In that case, a long-lifetime electronic device can be obtained. Note that the light-emitting apparatus can be used for electronic devices and automobiles in a variety of fields without being limited to those described in this embodiment.

Note that the structures described in this embodiment can be used in an appropriate combination with any of the structures described in the other embodiments.

### Embodiment 6

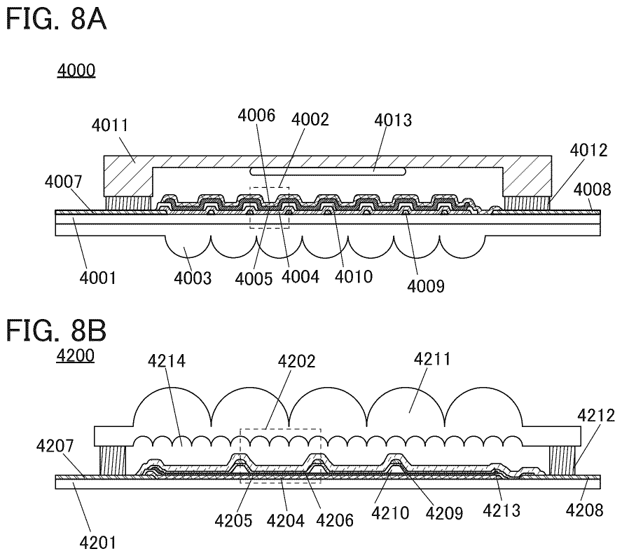

In this embodiment, a structure of a lighting device fabricated using the light-emitting apparatus of one embodiment of the present invention or the light-emitting device which is part of the light-emitting apparatus is described with reference to FIG. 8.

FIG. 8A and FIG. 8B show examples of cross-sectional views of lighting devices. FIG. 8A is a bottom-emission lighting device in which light is extracted from the substrate side, and FIG. 8B is a top-emission lighting device in which light is extracted from the sealing substrate side.

A lighting device 4000 shown in FIG. 8A includes a light-emitting device 4002 over a substrate 4001. In addition, the lighting device 4000 includes a substrate 4003 with unevenness on the outside of the substrate 4001. The light-emitting device 4002 includes a first electrode 4004, an EL layer 4005, and a second electrode 4006.

The first electrode 4004 is electrically connected to an electrode 4007, and the second electrode 4006 is electrically connected to an electrode 4008. In addition, an auxiliary wiring 4009 electrically connected to the first electrode 4004 may be provided. Note that an insulating layer 4010 is formed over the auxiliary wiring 4009.

The substrate 4001 and a sealing substrate 4011 are bonded to each other with a sealant 4012. A desiccant 4013 is preferably provided between the sealing substrate 4011 and the light-emitting device 4002. The substrate 4003 has the unevenness shown in FIG. 8A, whereby the extraction efficiency of light generated in the light-emitting device 4002 can be increased.

A lighting device 4200 shown in FIG. 8B includes a light-emitting device 4202 over a substrate 4201. The light-emitting device 4202 includes a first electrode 4204, an EL layer 4205, and a second electrode 4206.

The first electrode 4204 is electrically connected to an electrode 4207, and the second electrode 4206 is electrically connected to an electrode 4208. An auxiliary wiring 4209 electrically connected to the second electrode 4206 may also be provided. In addition, an insulating layer 4210 may be provided under the auxiliary wiring 4209.

The substrate 4201 and a sealing substrate 4211 with unevenness are bonded to each other with a sealant 4212. A barrier film 4213 and a planarization film 4214 may be provided between the sealing substrate 4211 and the light-emitting device 4202. The sealing substrate 4211 has the unevenness shown in FIG. 8B, whereby the extraction efficiency of light generated in the light-emitting device 4202 can be increased.

Application examples of such lighting devices include a ceiling light for indoor lighting. Examples of the ceiling light include a ceiling direct mount light and a ceiling embedded light. Such a lighting device is fabricated using the light-emitting apparatus and a housing or a cover in combination.

For another example, such lighting devices can be used for a foot light that illuminates a floor so that safety on the floor can be improved. For example, the foot light can be effectively used in a bedroom, on a staircase, or on a passage. In that case, the size or shape of the foot light can be changed depending on the area or structure of a room. The foot light can be a stationary lighting device fabricated using the light-emitting apparatus and a support base in combination.

Such lighting devices can also be used for a sheet-like lighting device (sheet-like lighting). The sheet-like lighting, which is attached to a wall when used, is space-saving and thus can be used for a wide variety of uses. Furthermore, the area of the sheet-like lighting can be easily increased. The sheet-like lighting can also be used on a wall or housing having a curved surface.

Besides the above examples, the light-emitting apparatus of one embodiment of the present invention or the light-emitting device which is part of the light-emitting apparatus can be used as part of furniture in a room, so that a lighting device which has a function of the furniture can be obtained.

As described above, a variety of lighting devices that include the light-emitting apparatus can be obtained. Note that these lighting devices are also embodiments of the present invention.

The structures described in this embodiment can be used in an appropriate combination with the structures described in the other embodiments.

### Example 1

In this example, a plurality of light-emitting devices (a light-emitting device 1, a light-emitting device 2, a light-emitting device 3, and a light-emitting device 4) using the compositions for a light-emitting device (also referred to as premixed materials) of embodiments of the present invention in EL layers 903 and having different stacked structures were fabricated, and the obtained device characteristics are shown. As comparative light-emitting devices, light-emitting devices were fabricated in such a manner that the EL layers 903 were formed by what is called a co-evaporation method in which a plurality of organic compounds included in the compositions for a light-emitting device of embodiments of the present invention, that were the same material structures of those of the light-emitting device 1 to the light-emitting device 4, were not mixed in advance but co-evaporated. Note that in comparison between the light-emitting devices and the comparative light-emitting devices shown in this example, the light-emitting devices fabricated using the compositions for a light-emitting device are a light-emitting device 1-1, a light-emitting device 2-1, a light-emitting device 3-1, and a light-emitting device 4-1, and the comparative light-emitting devices fabricated using no compositions for a light-emitting device are a comparative light-emitting device 1-2, a comparative light-emitting device 2-2, a comparative light-emitting device 3-2, and a comparative light-emitting device 4-2.

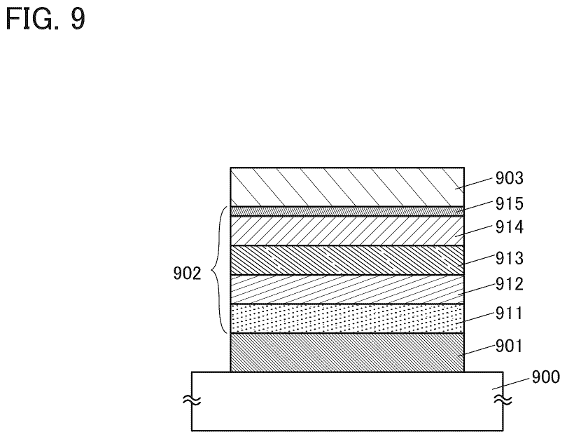

Specific device structures and fabrication methods of the light-emitting devices in this example are described below. Note that FIG. 9 illustrates the device structure of the light-emitting devices described in this example, and Table 1 shows specific compositions. The chemical formulae of the materials used in this example are shown below.

TABLE 1

| | | Hole- | Hole- | Light- | | | Electron- | |
|---|---|---|---|---|---|---|---|---|
| | First | injection | transport | emitting | | | injection | Second |
| | electrode | layer | layer | layer | Electron-transport layer | | layer | electrode |
| Light-emitting | ITSO | DBT3P-II:MoOx | PCBBi1BP | * | 8BP-4mDBtPBfpm | NBphen | LiF | Al |
| device 1 | (70 nm) | (2:1 45 nm) | (20 nm) | | (20 nm) | (10 nm) | (1 nm) | (200 nm) |
| Light-emitting | ITSO | DBT3P-II:MoOx | PCBBiF | ** | 9mDBtBPNfpr | NBphen | LiF | Al |
| device 2 | (70 nm) | (2:1 75 nm) | (20 nm) | | (30 nm) | (15 nm) | (1 nm) | (200 nm) |
| Light-emitting | ITSO | DBT3P-II:MoOx | PCBBiF | *** | 9mDBtBPNfpr | NBphen | LiF | Al |
| device 3 | (70 nm) | (2:1 75 nm) | (20 nm) | | (30 nm) | (15 nm) | (1 nm) | (200 nm) |
| Light-emitting | ITSO | DBT3P-II:MoOx | PCBBi1BP | **** | mPCCzPTzn-02 | NBphen | LiF | Al |
| device 4 | (70 nm) | (2:1 75 nm) | (20 nm) | | (30 nm) | (15 nm) | (1 nm) | (200 nm) |

* 8BP-4mDBtPBfpm:mBPCCBP:[Ir(ppy)₂(mdppy)] (0.5:0.5:0.1 40 nm)
** 9mDBtBPNfpr:PCBFF:[Ir(dmdppr-m5CP)₂(dpm)] (0.8:0.2:0.1 40 nm)
*** 9mDBtBPNfpr:PCBAF:[Ir(dmdppr-m5CP)₂(dpm)] (0.8:0.2:0.1 40 nm)
**** 8(βN2)-4mDBtPBfpm:PCBNBF:[Ir(dmdppr-m5CP)₂(dpm)] (0.7:0.3:0.1 40 nm)

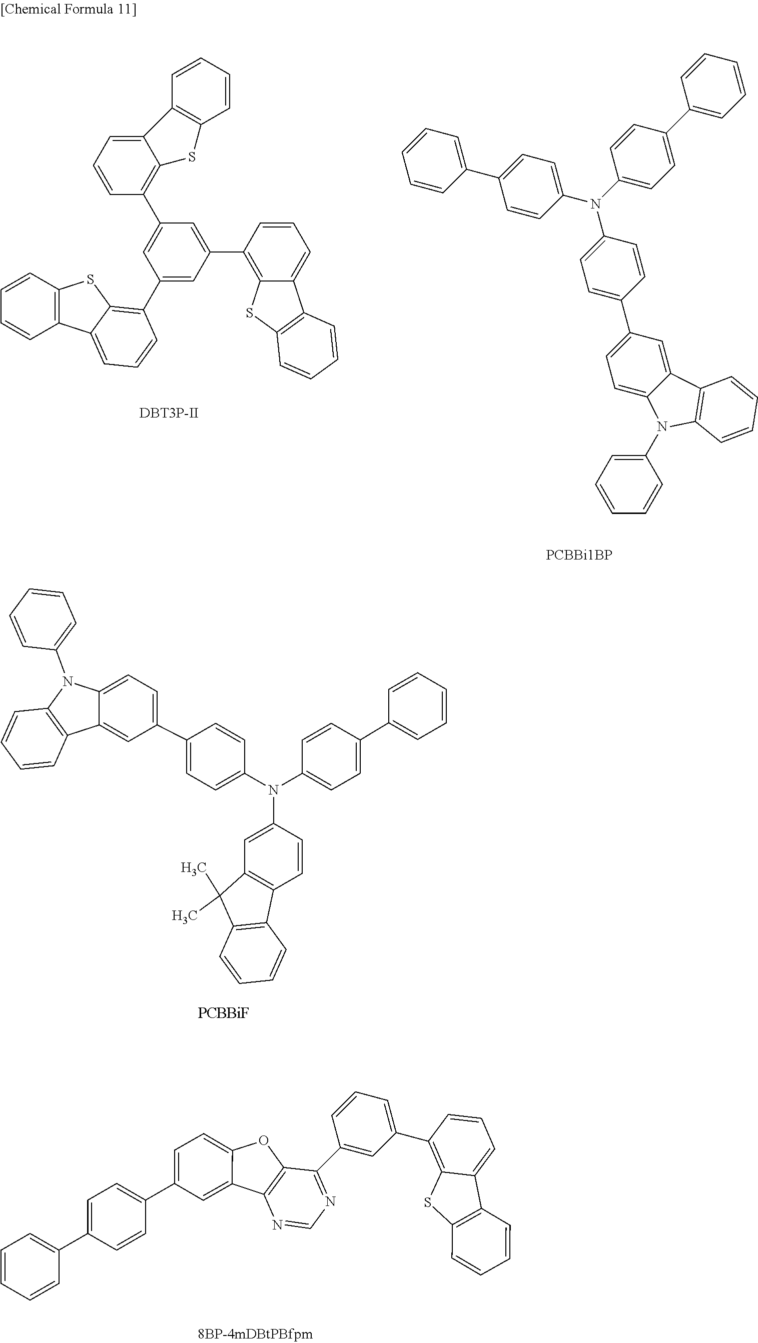

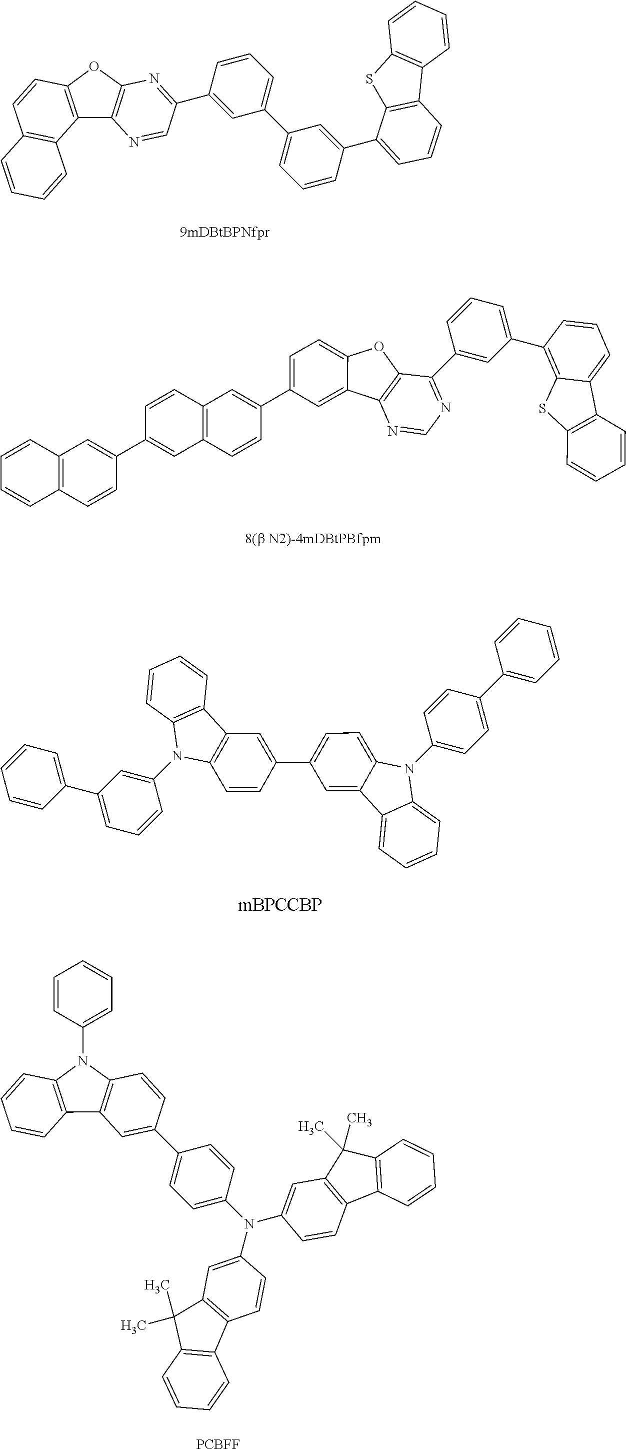

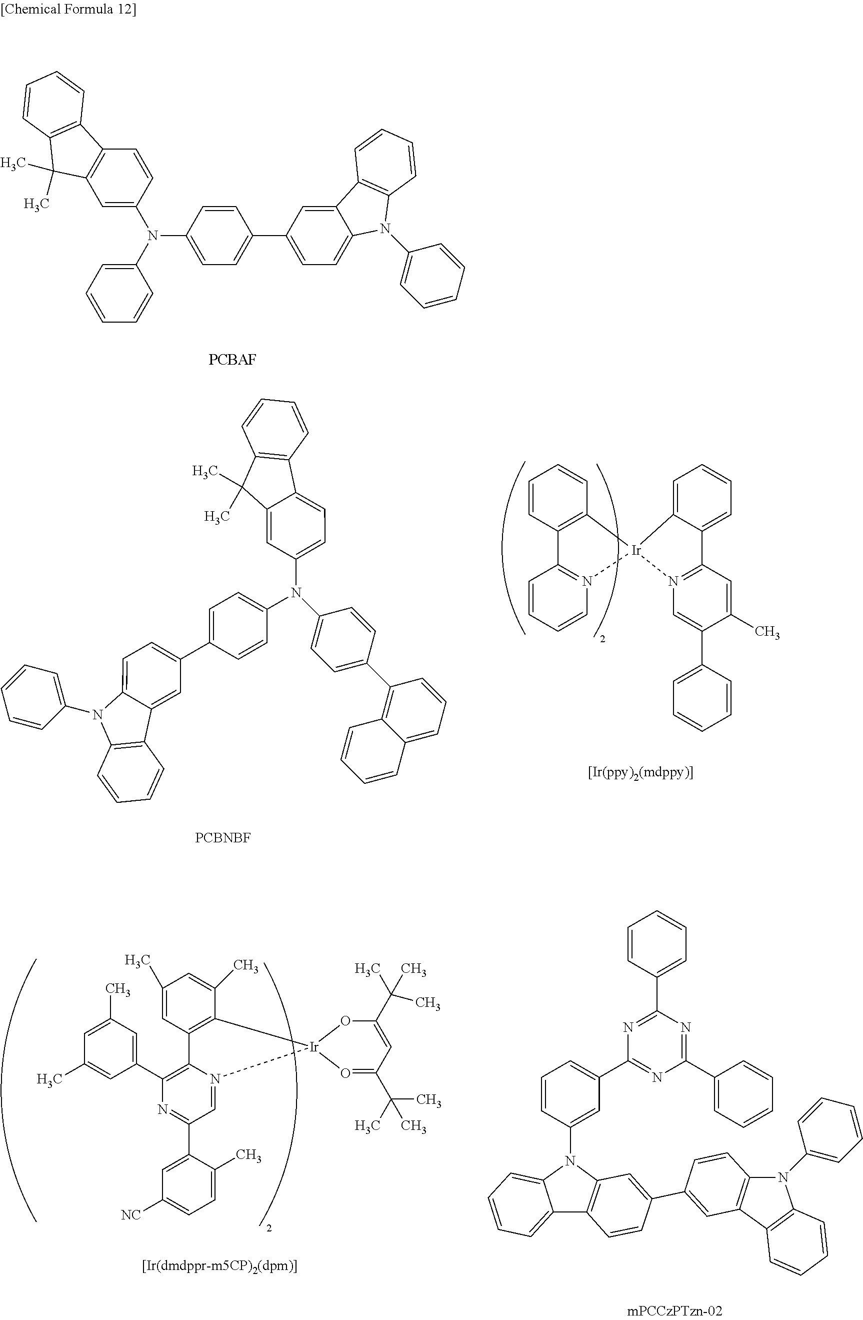

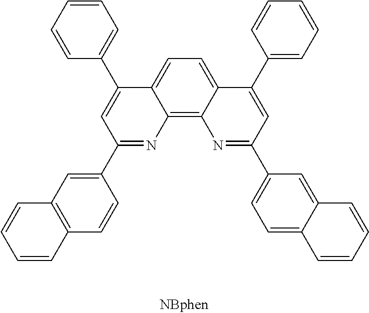 [SMILES: c1ccc(-c2cc(-c3ccc4ccccc4c3)nc3c2ccc2c(-c4ccccc4)cc(-c4ccc5ccccc5c4)nc23)cc1]

### <<Fabrication of Light-Emitting Devices>>

The light-emitting devices described in this example each have a structure shown in FIG. 9, in which a hole-injection layer 911, a hole-transport layer 912, a light-emitting layer 913, an electron-transport layer 914, and an electron-injection layer 915 are stacked in this order over a first electrode 901 formed over a substrate 900, and a second electrode 903 is stacked over the electron-injection layer 915.

First, the first electrode 901 was formed over the substrate 900. The electrode area was set to 4 mm² (2 mm×2 mm). A glass substrate was used as the substrate 900. The first electrode 901 was formed to a thickness of 70 nm using indium tin oxide containing silicon oxide (ITSO) by a sputtering method.

As pretreatment, a surface of the substrate was washed with water, baking was performed at 200° C. for one hour, and then UV ozone treatment was performed for 370 seconds. After that, the substrate was transferred into a vacuum evaporation apparatus in which the pressure was reduced to approximately 1×10⁻⁴ Pa, vacuum baking at 170° C. for 30 minutes was performed in a heating chamber in the vacuum evaporation apparatus, and then the substrate was cooled down for approximately 30 minutes.

Next, the hole-injection layer 911 was formed over the first electrode 901. After the pressure in the vacuum evaporation apparatus was reduced to 1×10⁻⁴ Pa, the hole-injection layer 911 was formed by co-evaporation to have DBT3P-II:molybdenum oxide=2:1 (mass ratio) and a thickness of 45 nm or 75 nm.

Then, the hole-transport layer 912 was formed over the hole-injection layer 911. For the hole-transport layer 912, PCCBBi1BP was used in the light-emitting device 1 and the light-emitting device 4, and PCBBiF was used in the light-emitting device 2 and the light-emitting device 3. Note that the hole-transport layer 912 was formed by evaporation to have a thickness of 20 nm in each case.

Next, the light-emitting layer 913 was formed over the hole-transport layer 912.

In the case of the light-emitting layer 913 of the light-emitting device 1, a composition 1 for a light-emitting device, in which 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm) and 9-(1,1′-biphenyl-3-yl)-9′-(1,1′-biphenyl-4-yl)-9H,9′H-3,3′-bicarbazole (abbreviation: mBPCCBP) were mixed in advance to have a weight ratio of 8BP-4mDtPBfpm:mBPCCBP=0.5:0.5, and [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]) as a guest material (a phosphorescent substance) were used, the composition 1 for a light-emitting device and the guest material were put in separate evaporation sources (also referred to as evaporation boats), and co-evaporation was performed such that the weight ratio was [the composition 1 for a light-emitting device of the mixed material of 8BP-4mDtPBfpm and mBPCCBP]:[Ir(ppy)₂(mdppy)]=1:0.1. Note that the thickness was set to 40 nm. The obtained light-emitting device is the light-emitting device 1-1. The comparative light-emitting device was fabricated in such a manner that 8BP-4mDtPBfpm, mBPCCBP, and [Ir(ppy)₂(mdppy)] were put in separate evaporation sources, and co-evaporation was performed such that the weight ratio was 8BP-4mDtPBfpm:mBPCCBP:[Ir(ppy)₂(mdppy)]=0.5:0.5:0.1 and the thickness was the same as that in the light-emitting device 1-1. The obtained light-emitting device is the comparative light-emitting device 1-2.

In the case of the light-emitting layer 913 of the light-emitting device 2, a composition 2 for a light-emitting device, in which 9-[(3′-dibenzothiophen-4-yl)biphenyl-3-yl]naphtho[1′,2′:4,5]furo[2,3-b]pyrazine (abbreviation: 9mDBtBPNfpr) and N-[4-(9-phenyl-9H-carbazol-3-yl)phenyl]-bis(9,9-dimethyl-9H-fluoren-2-yl)amine (abbreviation: PCBFF) were mixed in advance to have a weight ratio of 9mDBtBPNfpr:PCBFF=0.8:0.2, and bis{4,6-dimethyl-2-[5-(5-cyano-2-methylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-m5CP)₂(dpm)]) as a guest material (a phosphorescent substance) were used, the composition 2 for a light-emitting device and the guest material were put in separate evaporation sources (also referred to as evaporation boats), and co-evaporation was performed such that the weight ratio was [the composition 2 for a light-emitting device of the mixed material of 9mDBtBPNfpr and PCBFF]:[Ir(dmdppr-m5CP)₂(dpm)]=1:0.1. Note that the thickness was set to 40 nm. The obtained light-emitting device is the light-emitting device 2-1. The comparative light-emitting device was fabricated in such a manner that 9mDBtBPNfpr, PCBFF, and [Ir(dmdppr-m5CP)₂(dpm)] were put in separate evaporation sources, and co-evaporation was performed such that the weight ratio was 9mDBtBPNfpr:PCBFF:[Ir(dmdppr-m5CP)₂(dpm)]=0.8:0.2:0.1 and the thickness was the same as that in the light-emitting device 2-1. The obtained light-emitting device is the comparative light-emitting device 2-2.

In the case of the light-emitting layer 913 of the light-emitting device 3, a composition 3 for a light-emitting device, in which 9-[(3′-dibenzothiophen-4-yl)biphenyl-3-yl]naphtho[1′,2′:4,5]furo[2,3-b]pyrazine (abbreviation: 9mDBtBPNfpr) and 9,9-dimethyl-N-phenyl-N-[4-(9-phenyl-9H-carbazol-3-yl)phenyl]fluoren-2-amine (abbreviation: PCBAF) were mixed in advance to have a weight ratio of 9mDBtBPNfpr:PCBAF=0.8:0.2, and [Ir(dmdppr-m5CP)₂(dpm)] as a guest material (a phosphorescent substance) were used, the composition 3 for a light-emitting device and the guest material were put in separate evaporation sources (also referred to as evaporation boats), and co-evaporation was performed such that the weight ratio was [the composition 3 for a light-emitting device of the mixed material of 9mDBtBPNfpr and PCBAF]:[Ir(dmdppr-m5CP)₂(dpm)]=1:0.1. Note that the thickness was set to 40 nm. The obtained light-emitting device is the light-emitting device 3-1. The comparative light-emitting device was fabricated in such a manner that 9mDBtBPNfpr, PCBAF, and [Ir(dmdppr-m5CP)₂(dpm)] were put in separate evaporation sources, and co-evaporation was performed such that the weight ratio was 9mDBtBPNfpr:PCBAF:[Ir(dmdppr-m5CP)₂(dpm)]=0.8:0.2:0.1 and the thickness was the same as that in the light-emitting device 3-1. The obtained light-emitting device is the comparative light-emitting device 3-2.

In the case of the light-emitting layer 913 of the light-emitting device 4, a composition 4 for a light-emitting device, in which 8-[(2,2′-binaphthalen)-6-yl]-4-[3-(dibenzothiophen-4-yl)phenyl-[1]benzofuro[3,2-d]pyrimidine (abbreviation: 8(βN2)-4mDBtPBfpm) and PCBNBF were mixed in advance to have a weight ratio of 8(βN2)-4mDBtPBfpm:PCBNBF=0.7:0.3, and [Ir(dmdppr-m5CP)₂(dpm)] as a guest material (a phosphorescent substance) were used, the composition 4 for a light-emitting device and the guest material were put in separate evaporation sources (also referred to as evaporation boats), and co-evaporation was performed such that the weight ratio was [the composition 4 for a light-emitting device of the mixed material of 8(βN2)-4mDBtPBfpm and PCBNBF]:[Ir(dmdppr-m5CP)₂(dpm)]=1:0.3:0.1. Note that the thickness was set to 40 nm. The obtained light-emitting device is the light-emitting device 4-1. The comparative light-emitting device was fabricated in such a manner that 8(βN2)-4mDBtPBfpm, PCBNBF, and [Ir(dmdppr-m5CP)₂(dpm)] were put in separate evaporation sources, and co-evaporation was performed such that the weight ratio was 8(βN2)-4mDBtPBfpm:PCBNBF:[Ir(dmdppr-m5CP)₂(dpm)]=0.7:0.3:0.1 and the thickness was the same as that in the light-emitting device 4-1. The obtained light-emitting device is the comparative light-emitting device 4-2.

Next, the electron-transport layer 914 was formed over the light-emitting layer 913.

The electron-transport layer 914 in the light-emitting device 1 was formed in the following manner: 8BP-4mDtPBfpm and NBPhen were sequentially deposited by evaporation to a thickness of 20 nm and a thickness of 10 nm, respectively. The electron-transport layer 914 in the light-emitting device 2 was formed in the following manner: 9mDBtBPNfpr and NBphen were sequentially deposited by evaporation to a thickness of 30 nm and a thickness of 15 nm, respectively. The electron-transport layer 914 in the light-emitting device 3 was formed in the following manner: 9mDBtBPNfpr and NBphen were sequentially deposited by evaporation to a thickness of 30 nm and a thickness of 15 nm, respectively. The electron-transport layer 914 in the light-emitting device 4 was formed in the following manner: mPCCzPTzn-02 and NBphen were sequentially deposited by evaporation to a thickness of 30 nm and a thickness of 15 nm, respectively.

Then, the electron-injection layer 915 was formed over the electron-transport layer 914. The electron-injection layer 915 was formed to a thickness of 1 nm by evaporation using lithium fluoride (LiF).

Next, the second electrode 903 was formed over the electron-injection layer 915. The second electrode 903 was formed to a thickness of 200 nm by an evaporation method using aluminum. In this example, the second electrode 903 functions as a cathode.

Through the above steps, the light-emitting devices each in which an EL layer was provided between the pair of electrodes over the substrate 900 were fabricated. The hole-injection layer 911, the hole-transport layer 912, the light-emitting layer 913, the electron-transport layer 914, and the electron-injection layer 915 described in the above steps are functional layers forming the EL layer in one embodiment of the present invention. Furthermore, in all the evaporation steps in the above fabrication method, an evaporation method by a resistance-heating method was used.

The light-emitting device fabricated as described above was sealed using a different substrate (not illustrated). At the time of the sealing using the different substrate (not shown), the different substrate (not shown) coated with a sealant that solidifies by ultraviolet light was fixed onto the substrate 900 in a glove box containing a nitrogen atmosphere, and the substrates were bonded to each other such that the sealant would be attached to the periphery of the light-emitting device formed over the substrate 900. At the time of the sealing, the sealant was irradiated with 365-nm ultraviolet light at 6 J/cm² to be solidified, and the sealant was subjected to heat treatment at 80° C. for one hour to be stabilized.

### <<Operation Characteristics of Light-Emitting Devices>>

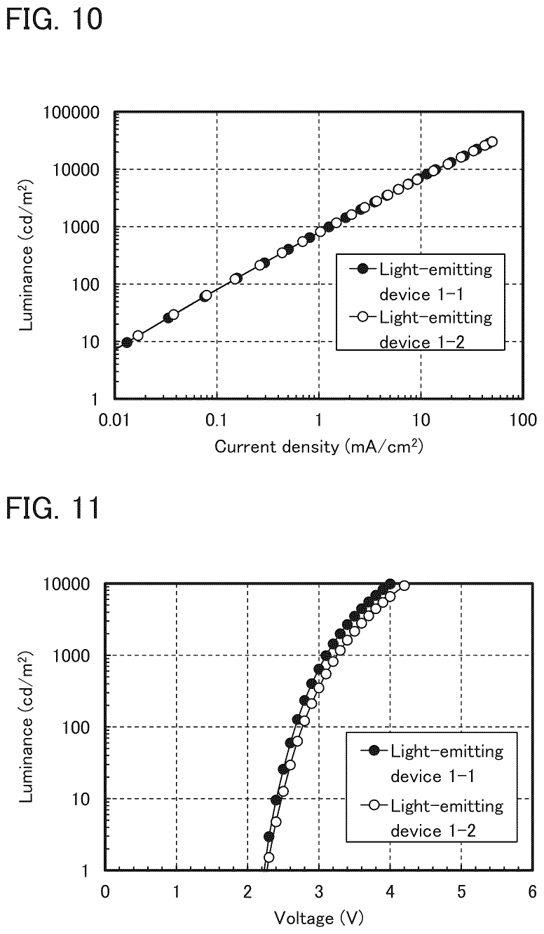

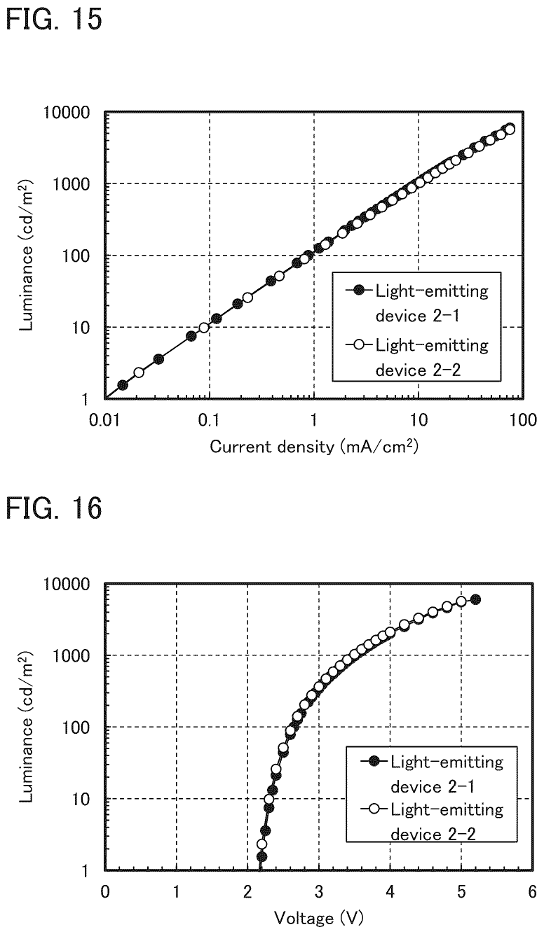

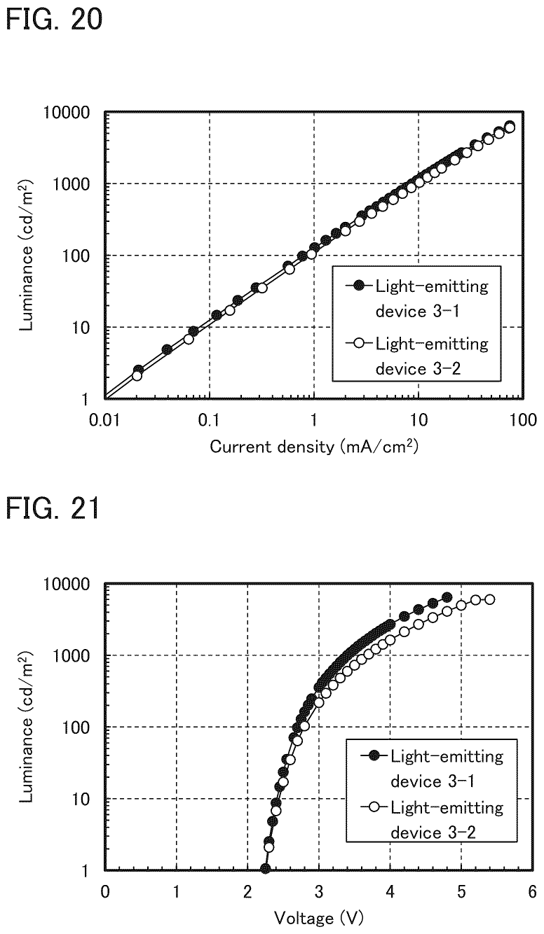

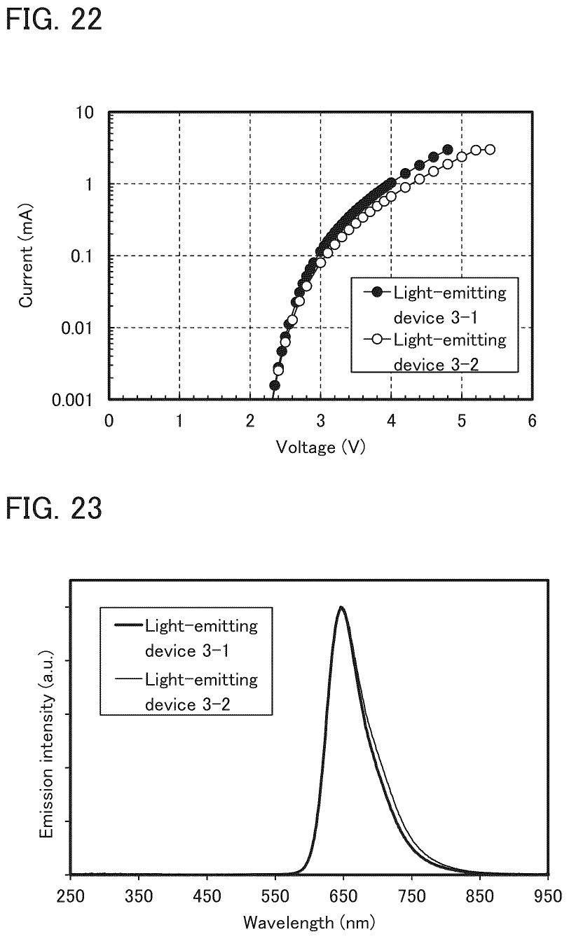

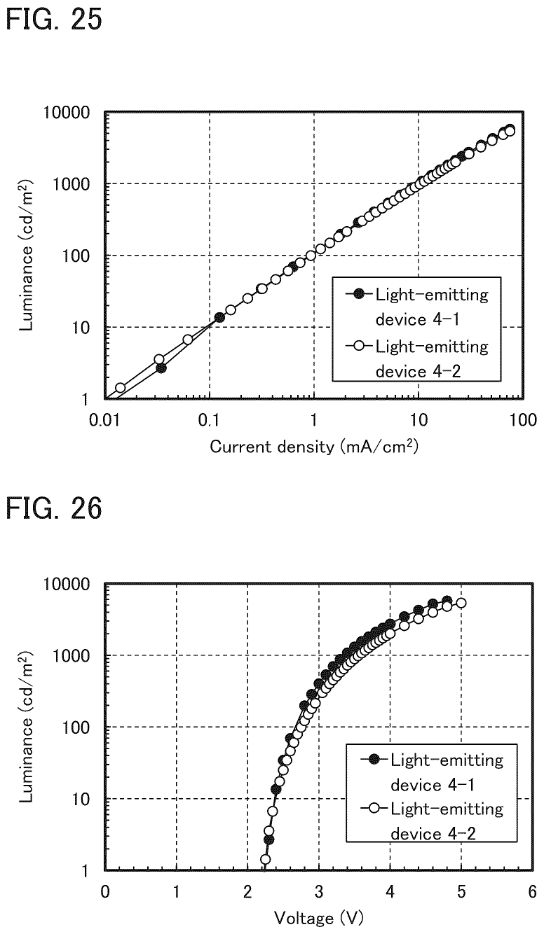

Measurement results of operation characteristics of each of the fabricated light-emitting devices are shown. Note that the measurement was carried out at room temperature (an atmosphere maintained at 25° C.). Luminance and CIE chromaticity were measured with a luminance colorimeter (BM-5A manufactured by TOPCON TECHNOHOUSE CORPORATION), and electroluminescence spectra were measured with a multi-channel spectrometer (PMA-11 manufactured by Hamamatsu Photonics K.K.). As the results of the operation characteristics of the light-emitting device 1-1 and the comparative light-emitting device 1-2, the current density-luminance characteristics are shown in FIG. 10, the voltage-luminance characteristics are shown in FIG. 11, and the voltage-current characteristics are shown in FIG. 12. Similarly, the operation characteristics of the light-emitting device 2-1 and the comparative light-emitting device 2-2 are shown in FIG. 15 to FIG. 17, the operation characteristics ofthe light-emitting device 3-1 and the comparative light-emitting device 3-2 are shown in FIG. 20 to FIG. 22, and the operation characteristics of the light-emitting device 4-1 and the comparative light-emitting device 4-2 are shown in FIG. 25 to FIG. 27.

Table 2 below shows the initial values of the main characteristics of each of the light-emitting devices at around 1000 cd/m².

TABLE 2

| | | | | | | | | | | External |
|---|---|---|---|---|---|---|---|---|---|---|
| | | | | | Current | | | Current | Power | quantum |
| | | Premixed | Voltage | Current | density | Chromaticity | Luminance | efficiency | efficiency | efficiency |
| | No. | or not | (V) | (mA) | (mA/cm²) | (x, y) | (cd/m²) | (cd/A) | (lm/W) | (%) |
| Light-emitting | 1-1 | ∘ | 3.1 | 0.050 | 1.3 | (0.34, 0.63) | 990 | 79 | 80 | 21 |
| device 1 | 1-2 | x | 3.3 | 0.060 | 1.5 | (0.34, 0.63) | 1200 | 79 | 75 | 21 |
| Light-emitting | 2-1 | ∘ | 3.5 | 0.37 | 9.4 | (0.71, 0.29) | 980 | 10 | 9.4 | 25 |
| device 2 | 2-2 | x | 3.5 | 0.41 | 10 | (0.71, 0.29) | 1000 | 10 | 9.0 | 24 |
| Light-emitting | 3-1 | ∘ | 3.4 | 0.35 | 8.6 | (0.71, 0.29) | 1000 | 12 | 11 | 25 |
| device 3 | 3-2 | x | 3.7 | 0.41 | 10 | (0.71, 0.29) | 1000 | 10 | 8.6 | 24 |
| Light-emitting | 4-1 | ∘ | 3.4 | 0.43 | 11 | (0.71, 0.29) | 1100 | 10 | 9.2 | 23 |
| device 4 | 4-2 | x | 3.6 | 0.41 | 10 | (0.71, 0.29) | 980 | 9.5 | 8.4 | 22 |

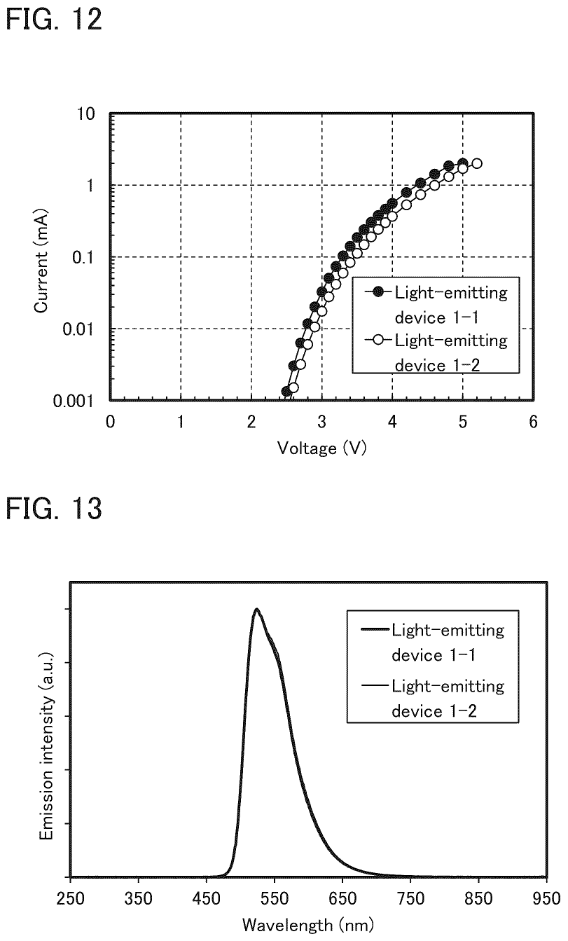

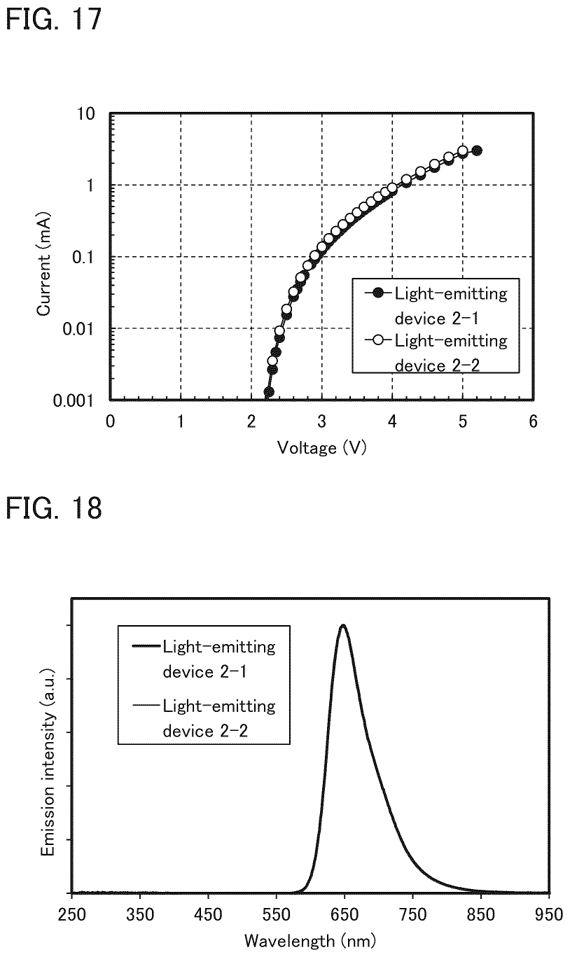

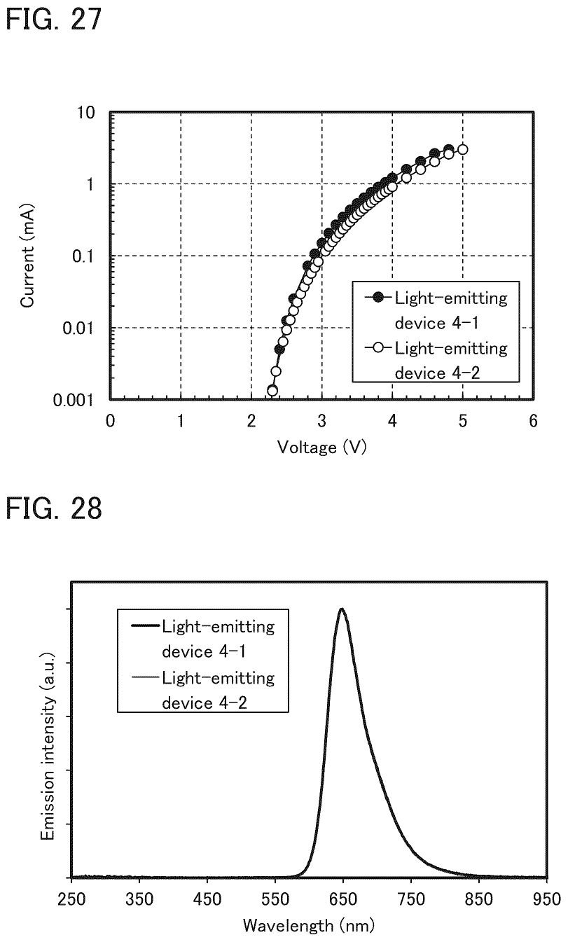

FIG. 13 shows emission spectra of the light-emitting device 1-1 and the comparative light-emitting device 1-2 when a current at a current density of 2.5 mA/cm² is supplied, FIG. 18 shows emission spectra of the light-emitting device 2-1 and the comparative light-emitting device 2-2, FIG. 23 shows emission spectra of the light-emitting device 3-1 and the comparative light-emitting device 3-2, and FIG. 28 shows emission spectra of the light-emitting device 4-1 and the comparative light-emitting device 4-2.

The emission spectra shown in FIG. 13 have peaks at around 523 nm, and it is suggested that the peaks are derived from light emission of [Ir(ppy)₂(mdppy)] contained in the light-emitting layers 913 of the light-emitting device 1-1 and the comparative light-emitting device 1-2.

The emission spectra shown in FIG. 18 have peaks at around 650 nm, and it is suggested that the peaks are derived from light emission of [Ir(dmdppr-m5CP)₂(dpm)] contained in the light-emitting layers 913 of the light-emitting device 2-1 and the comparative light-emitting device 2-2.

The emission spectra shown in FIG. 23 have peaks at around 651 nm, and it is suggested that the peaks are derived from light emission of [Ir(dmdppr-m5CP)₂(dpm)] contained in the light-emitting layers 913 of the light-emitting device 3-1 and the comparative light-emitting device 3-2.

The emission spectra shown in FIG. 28 have peaks at around 647 nm, and it is suggested that the peaks are derived from light emission of [Ir(dmdppr-m5CP)₂(dpm)] contained in the light-emitting layers 913 of the light-emitting device 4-1 and the comparative light-emitting device 4-2.

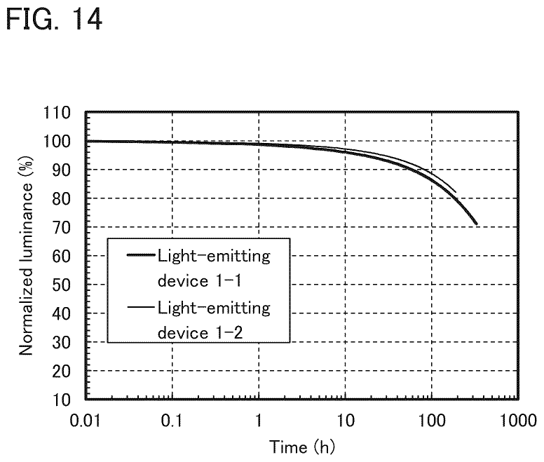

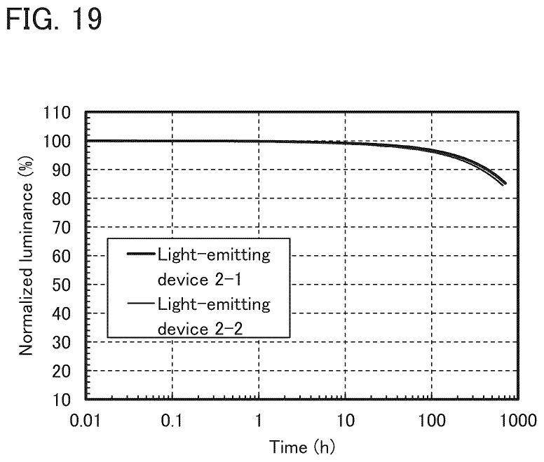

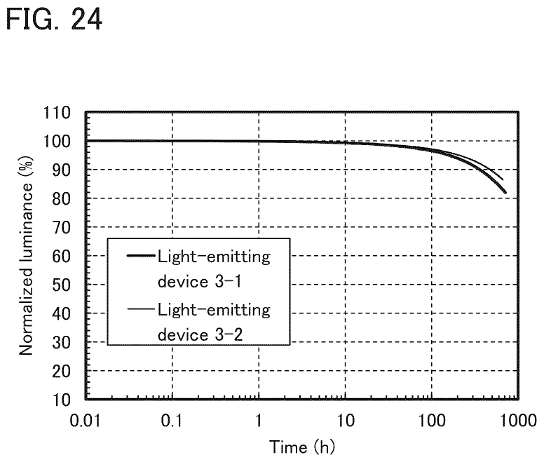

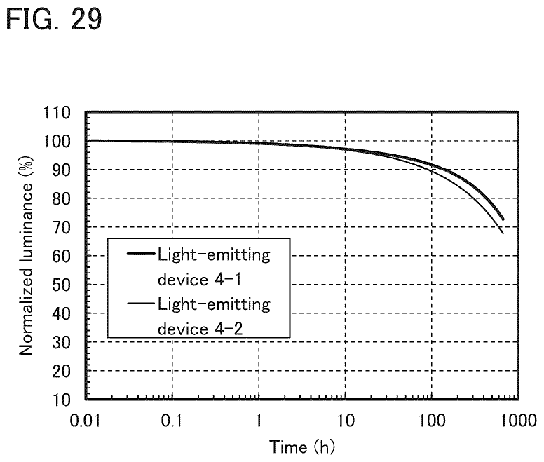

Next, a reliability test was performed on each light-emitting device. FIG. 14 shows the results of the reliability test of the light-emitting device 1-1 and the comparative light-emitting device 1-2, FIG. 19 shows the results of the reliability test of the light-emitting device 2-1 and the comparative light-emitting device 2-2, FIG. 24 shows the results of the reliability test of the light-emitting device 3-1 and the comparative light-emitting device 3-2, and FIG. 29 shows the results of the reliability test of the light-emitting device 4-1 and the comparative light-emitting device 4-2. In these figures showing reliabilities, the vertical axis represents normalized luminance (%) with an initial luminance of 100%, and the horizontal axis represents device driving time (h). As the reliability test, a driving test at a constant current density of 50 mA/cm² was performed on the light-emitting device 1-1 and the comparative light-emitting device 1-2, a driving test at a constant current density of 75 mA/cm² was performed on the light-emitting device 2-1 and the comparative light-emitting device 2-2, a driving test at a constant current density of 75 mA/cm² was performed on the light-emitting device 3-1 and the comparative light-emitting device 3-2, and a driving test at a constant current density of 75 mA/cm² was performed on the light-emitting device 4-1 and the comparative light-emitting device 4-2.

These results show that the light-emitting device 1-1, the light-emitting device 2-1, the light-emitting device 3-1, and the light-emitting device 4-1 each of whose light-emitting layer was formed using the composition for a light-emitting device (the premixed material) of one embodiment of the present invention have substantially the same reliabilities of the corresponding comparative light-emitting device 1-2, comparative light-emitting device 2-2, comparative light-emitting device 3-2, and comparative light-emitting device 4-2 each of whose light-emitting layer was formed by a co-evaporation method in which organic compounds included in the material for a light-emitting device were put in separate evaporation sources.

That is, this example suggests that with the use of the composition for a light-emitting device (the premixed material) of one embodiment of the present invention for a light-emitting layer, a highly productive light-emitting device can be manufactured while the device characteristics and reliability of the light-emitting device are maintained.

### Reference Synthesis Example 1

A synthesis method of 9-[(3′-dibenzothiophen-4-yl)biphenyl-3-yl]naphtho[1′,2′:4,5]furo[2,3-b]pyrazine (abbreviation: 9mDBtBPNfpr), which is the organic compound used in Example 1, is described. The structure of 9mDBtBPNfpr is shown below.

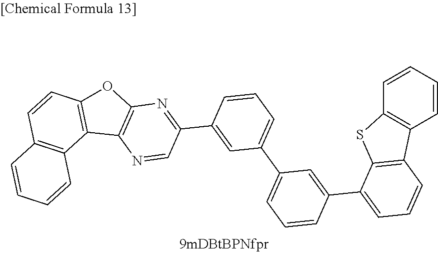 [SMILES: c1cc(-c2cccc(-c3cccc4c3sc3ccccc34)c2)cc(-c2cnc3c(n2)oc2ccc4ccccc4c23)c1]

### Step 1; Synthesis of 6-chloro-3-(2-methoxynaphthalen-1-yl)pyrazin-2-amine

First, into a three-neck flask equipped with a reflux pipe were put 4.37 g of 3-bromo-6-chloropyrazin-2-amine, 4.23 g of 2-methoxynaphthalene-1-boronic acid, 4.14 g of potassium fluoride, and 75 mL of dehydrated tetrahydrofuran, and the air in the flask was replaced with nitrogen. The mixture in the flask was degassed by being stirred under reduced pressure, 0.57 g of tris(dibenzylideneacetone)dipalladium(0) (abbreviation: Pd₂(dba)₃) and 4.5 mL of tri-tert-butylphosphine (abbreviation: P(tBu)₃) were added thereto, and then stirring was performed at 80° C. for 54 hours for reaction.

After a predetermined time elapsed, the obtained mixture was subjected to suction filtration and the filtrate was concentrated. Then, purification by silica gel column chromatography using a developing solvent of toluene:ethyl acetate=9:1 was performed, whereby a target pyrazine derivative was obtained (yellowish white powder, 2.19 g, in a yield of 36%). The synthesis scheme of Step 1 is shown in Formula (a-1) below.

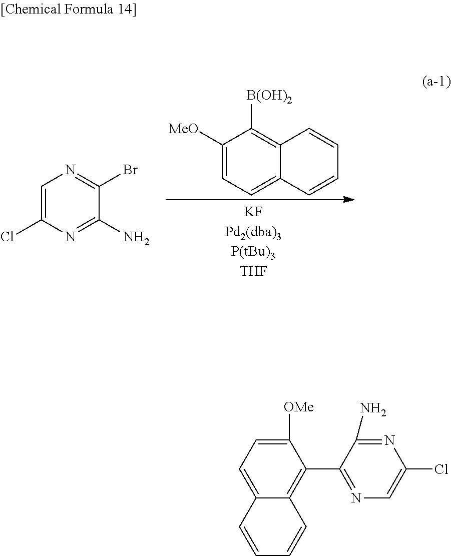 [SMILES: Nc1nc(Cl)cnc1Br ; COc1ccc2ccccc2c1B(O)O ; COc1ccc2ccccc2c1-c1ncc(Cl)nc1N]

### Step 2; Synthesis of 9-chloronaphtho[1′,2′:4,5]furo[2,3-b]pyrazine

Next, into a three-neck flask were put 2.18 g of 6-chloro-3-(2-methoxynaphthalen-1-yl)pyrazin-2-amine obtained in Step 1, 63 mL of dehydrated tetrahydrofuran, and 84 mL of a glacial acetic acid, and the air in the flask was replaced with nitrogen. After the flask was cooled down to −10° C., 2.8 mL of tert-butyl nitrite was dripped, and stirring was performed at −10° C. for 30 minutes and at 0° C. for 3 hours. After a predetermined time elapsed, 250 mL of water was added to the obtained suspension and suction filtration was performed, whereby a target pyrazine derivative was obtained (yellowish white powder, 1.48 g, in a yield of 77%). The synthesis scheme of Step 2 is shown in (a-2) below.

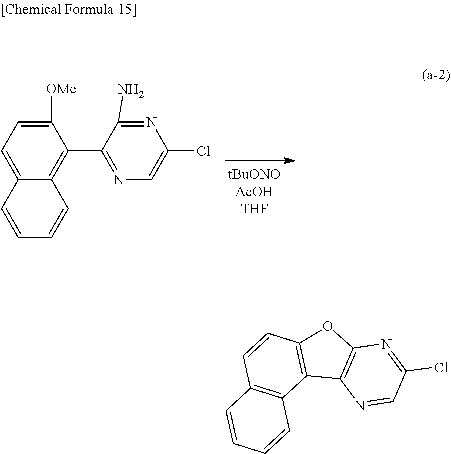 [SMILES: COc1ccc2ccccc2c1-c1ncc(Cl)nc1N ; Clc1cnc2c(n1)oc1ccc3ccccc3c12]

### Step 3; Synthesis of 9-[(3′-dibenzothiophene-4-yl)biphenyl-3-yl]naphtho[1′,2′:4,5]furo[2,3-b]pyrazine (abbreviation: 9mDBtBPNfpr)

Into a three-neck flask were put 1.48 g of 9-chloronaphtho[1′,2′:4,5]furo[2,3-b]pyrazine obtained in Step 2, 3.41 g of 3′-(4-dibenzothiophene)-1,1′-biphenyl-3-boronic acid, 8.8 mL of a 2M aqueous solution of potassium carbonate, 100 mL of toluene, and 10 mL of ethanol, and the air in the flask was replaced with nitrogen. The mixture in the flask was degassed by being stirred under reduced pressure, 0.84 g of bis(triphenylphosphine)palladium(II) dichloride (abbreviation: Pd(PPh₃)₂Cl₂) was added thereto, and then stirring was performed at 80° C. for 18 hours for reaction.

After a predetermined time elapsed, the obtained suspension was subjected to suction filtration, followed by washing with water and ethanol. The obtained solid was dissolved in toluene, and the mixture was filtered through a filter aid in which Celite, alumina, and Celite were stacked in this order and was recrystallized with a mixed solvent of toluene and hexane, whereby a target substance was obtained (a pale yellow solid, 2.66 g, in a yield of 82%).

By a train sublimation method, 2.64 g of the obtained pale yellow solid was purified by sublimation. The conditions of the purification by sublimation were such that the solid was heated under a pressure of 2.6 Pa at 315° C. while the argon gas flowed at a flow rate of 15 mL/min. After the purification by sublimation, 2.34 g of a target pale yellow solid was obtained in a yield of 89%. The synthesis scheme of Step 3 is shown in (a-3) below.

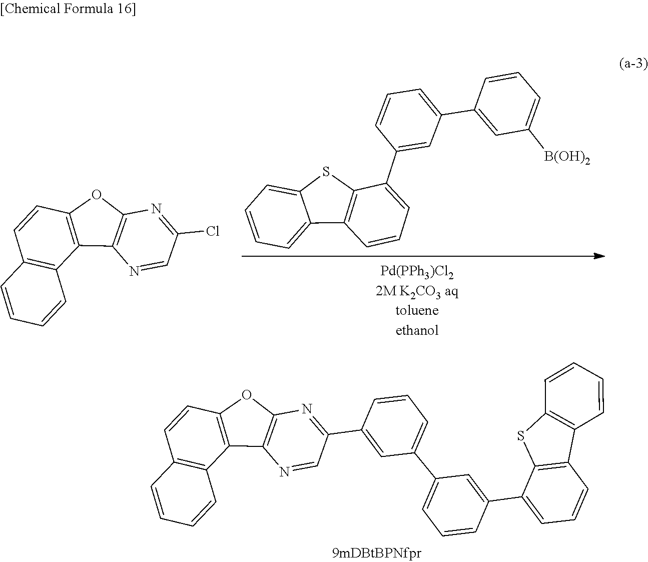

Results of analysis by nuclear magnetic resonance spectroscopy (¹H-NMR) of the pale yellow solid obtained in Step 3 are shown below.

¹H-NMR. δ (CD₂Cl₂): 7.47-7.51 (m, 2H), 7.60-7.69 (m, 5H), 7.79-7.89 (m, 6H), 8.05 (d, 1H), 8.10-8.11 (m, 2H), 8.18-8.23 (m, 3H), 8.53 (s, 1H), 9.16 (d, 1H), 9.32 (s, 1H).

### Reference Synthesis Example 2

A synthesis method of 4-[3-(dibenzothiophen-4-yl)phenyl]-8-(naphthalen-2-yl)-[1]benzofuro[3,2-d]pyrimidine (abbreviation: 8βN-4mDBtPBfpm), which is the organic compound that can be used for the present invention, is described. Note that the structural formula of 8βN-4mDBtPBfpm is shown below.

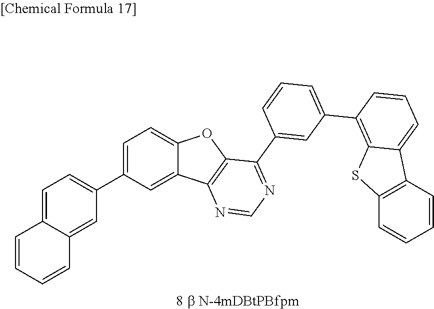 [SMILES: c1cc(-c2ncnc3c2oc2ccc(-c4ccc5ccccc5c4)cc23)cc(-c2cccc3c2sc2ccccc23)c1]

### Synthesis of 4-[3-(dibenzothiophen-4-yl)phenyl]-8-(naphthalen-2-yl)-[1]benzofuro[3,2-d]pyrimidine (abbreviation: 8PN-4mDBtPBfpm)

First, 1.5 g of 8-chloro-4-[3-(dibenzothiophen-4-yl)phenyl]-[1]benzofuro[3,2-d]pyrimidine, 0.73 g of 2-naphthaleneboronic acid, 1.5 g of cesium fluoride, and 32 mL of mesitylene were added, the air in a 100 mL three-neck flask was replaced with nitrogen, and 70 mg of 2′-(dicyclohexylphosphino)acetophenone ethylene ketal and 89 mg of tris(dibenzylideneacetone)dipalladium(0) (abbreviation: Pd₂(dba)₃) were added, followed by heating at 120° C. for 5 hours under a nitrogen stream. Water was added to the obtained reaction product, filtration was performed, and the residue was washed with water and ethanol in this order.

This residue was dissolved in toluene, followed by filtration using a filter aid filled with Celite, alumina, and Celite in this order. The solvent of the obtained solution was concentrated and recrystallized to give 1.5 g of a target pale yellow solid in a yield of 64%. The synthesis scheme is shown in Formula (b-1) below.

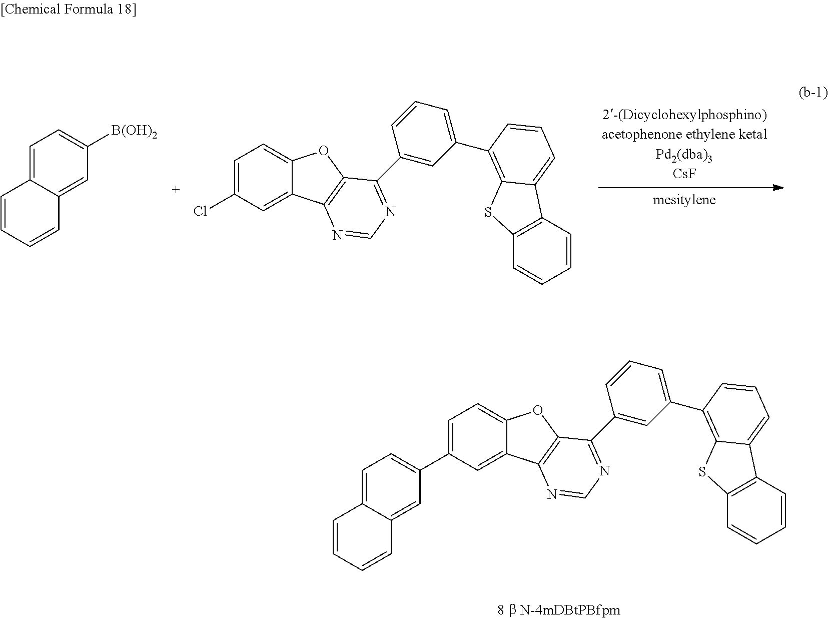 [SMILES: OB(O)c1ccc2ccccc2c1 ; Clc1ccc2oc3c(-c4cccc(-c5cccc6c5sc5ccccc56)c4)ncnc3c2c1 ; c1cc(-c2ncnc3c2oc2ccc(-c4ccc5ccccc5c4)cc23)cc(-c2cccc3c2sc2ccccc23)c1]

By a train sublimation method, 1.5 g of the obtained pale yellow solid was purified by sublimation. The conditions of the purification by sublimation were such that the solid was heated under a pressure of 2.0 Pa at 290° C. while the argon gas flowed at a flow rate of 10 mL/min. After the purification by sublimation, 0.60 g of a target yellow solid was obtained at a collection rate of 39%.

Analysis results by nuclear magnetic resonance spectroscopy (¹H-NMR) of the obtained yellow solid are shown below.

¹H-NMR. δ (TCE-d₂): 7.45-7.50 (m, 4H), 7.57-7.62 (m, 2H), 7.72-7.93 (m, 8H), 8.03 (d, 1H), 8.10 (s, 1H), 8.17 (d, 2H), 8.60 (s, 1H), 8.66 (d, 1H), 8.98 (s, 1H), 9.28 (s, 1H).

### Reference Synthesis Example 3

A synthesis method of 10-[(3′-dibenzothiophen-4-yl)biphenyl-3-yl]naphtho[1′,2′:4,5]furo[2,3-b]pyrazine (abbreviation: 10mDBtBPNfpr), which is the organic compound that can be used for the present invention, is described. Note that the structure of 10mDBtBPNfpr is shown below.

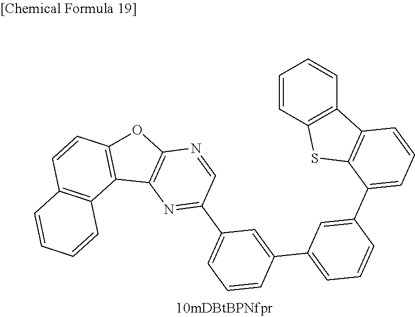 [SMILES: c1cc(-c2cccc(-c3cccc4c3sc3ccccc34)c2)cc(-c2cnc3oc4ccc5ccccc5c4c3n2)c1]

### Step 1; Synthesis of 5-chloro-3-(2-methoxynaphthalen-1-yl)pyrazin-2-amine

First, into a three-neck flask equipped with a reflux pipe were put 5.01 g of 3-bromo-5-chloropyrazin-2-amine, 6.04 g of 2-methoxynaphthalene-1-boronic acid, 5.32 g of potassium fluoride, and 86 mL of dehydrated tetrahydrofuran, and the air in the flask was replaced with nitrogen. The mixture in the flask was degassed by being stirred under reduced pressure, 0.44 g of tris(dibenzylideneacetone)dipalladium(0) (abbreviation: Pd₂(dba)₃) and 3.4 mL of tri-tert-butylphosphine (abbreviation: P(tBu)₃) were added thereto, and then stirring was performed at 80° C. for 22 hours for reaction.

After a predetermined time elapsed, the obtained mixture was subjected to suction filtration and the filtrate was concentrated. Then, purification by silica gel column chromatography using a developing solvent of toluene:ethyl acetate=10:1 was performed, whereby a target pyrazine derivative was obtained (yellowish white powder, 5.69 g, in a yield of 83%). The synthesis scheme of Step 1 is shown in Formula (c-1) below.

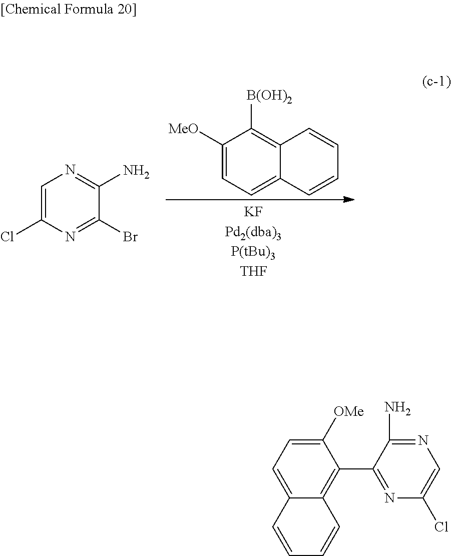 [SMILES: Nc1ncc(Cl)nc1Br ; COc1ccc2ccccc2c1B(O)O ; COc1ccc2ccccc2c1-c1nc(Cl)cnc1N]

### Step 2; Synthesis of 10-chloro-naphtho[1′,2′:4,5]furo[2,3-b]pyrazine

Next, into a three-neck flask were put 5.69 g of 5-chloro-3-(2-methoxynaphthalen-1-yl)pyrazin-2-amine obtained in Step 1, 150 mL of dehydrated tetrahydrofuran, and 150 mL of a glacial acetic acid, and the air in the flask was replaced with nitrogen. After the flask was cooled down to −10° C., 7.1 mL of tert-butyl nitrite was dripped, and stirring was performed at −10° C. for 1 hour and at 0° C. for 3.5 hours. After a predetermined time elapsed, 1 L of water was added to the obtained suspension and suction filtration was performed, whereby a target pyrazine derivative was obtained (yellowish white powder, 4.06 g, in a yield of 81%). The synthesis scheme of Step 2 is shown in Formula (c-2) below.

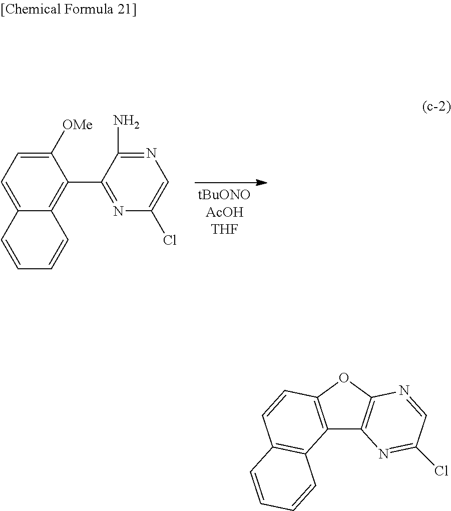 [SMILES: COc1ccc2ccccc2c1-c1nc(Cl)cnc1N ; Clc1cnc2oc3ccc4ccccc4c3c2n1]

### Step 3; Synthesis of 10mDBtBPNfpr

Into a three-neck flask were put 1.18 g of 10-chloronaphtho[1′,2′:4,5]furo[2,3-b]pyrazine obtained in Step 2, 2.75 g of 3′-(4-dibenzothiophene)-1,1′-biphenyl-3-boronic acid, 7.5 mL of a 2M aqueous solution of potassium carbonate, 60 mL of toluene, and 6 mL of ethanol, and the air in the flask was replaced with nitrogen. The mixture in the flask was degassed by being stirred under reduced pressure, 0.66 g of bis(triphenylphosphine)palladium(II) dichloride (abbreviation: Pd(PPh₃)₂Cl₂) was added thereto, and then stirring was performed at 90° C. for 22.5 hours for reaction.

After a predetermined time elapsed, the obtained suspension was subjected to suction filtration, followed by washing with water and ethanol. The obtained solid was dissolved in toluene, and the mixture was filtered through a filter aid in which Celite, alumina, and Celite were stacked in this order and was recrystallized with a mixed solvent of toluene and hexane, whereby a target substance was obtained (a white solid, 2.27 g, in a yield of 87%).

By a train sublimation method, 2.24 g of the obtained white solid was purified by sublimation. The conditions of the purification by sublimation were such that the solid was heated under a pressure of 2.3 Pa at 310° C. while the argon gas flowed at a flow rate of 16 mL/min. After the purification by sublimation, 1.69 g of a target white solid was obtained in a yield of 75%. The synthesis scheme of Step 3 is shown in Formula (c-3) below.

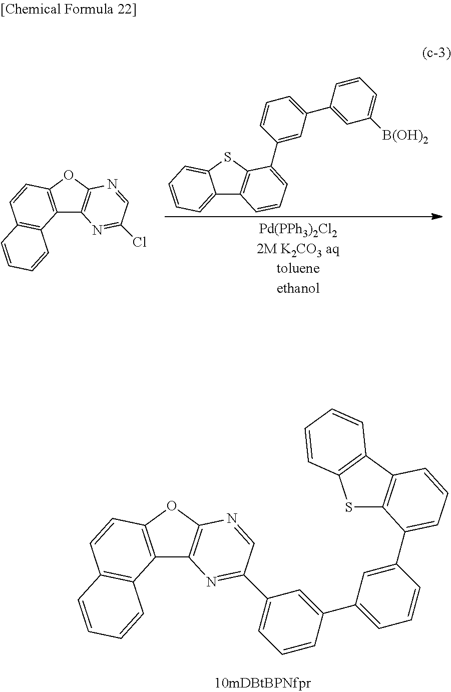 [SMILES: Clc1cnc2oc3ccc4ccccc4c3c2n1 ; OB(O)c1cccc(-c2cccc(-c3cccc4c3sc3ccccc34)c2)c1 ; c1cc(-c2cccc(-c3cccc4c3sc3ccccc34)c2)cc(-c2cnc3oc4ccc5ccccc5c4c3n2)c1]

Results of analysis by nuclear magnetic resonance spectroscopy (¹H-NMR) of the white solid obtained in Step 3 are shown below. The results revealed that 10mDBtBPNfpr, the organic compound represented by the above structural formula, was obtained.

¹H-NMR. δ (CDCl₃): 7.43 (t, 1H), 7.48 (t, 1H), 7.59-7.62 (m, 3H), 7.68-7.86 (m, 8H), 8.05 (d, 1H), 8.12 (d, 1H), 8.18 (s, 1H), 8.20-8.24 (m, 3H), 8.55 (s, 1H), 8.92 (s, 1H), 9.31 (d, 1H).

### Reference Synthesis Example 4

A synthesis method of 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), which is the organic compound used in Example 1, is described. Note that the structure of 8BP-4mDBtPBfpm is shown below.

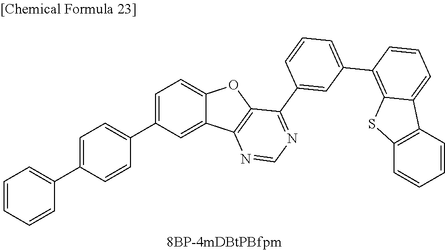 [SMILES: c1ccc(-c2ccc(-c3ccc4oc5c(-c6cccc(-c7cccc8c7sc7ccccc78)c6)ncnc5c4c3)cc2)cc1]

### Synthesis of 8-(1,1′-biphenyl-4-yl)-4-[3-(dibenzothiophen-4-yl)phenyl]-[1]benzofuro[3,2-d]pyrimidine

Into a three-neck flask, 1.37 g of 8-chloro-4-[3-(dibenzothiophen-4-yl)phenyl]-[1]benzofuro[3,2-d]pyrimidine, 0.657 g of 4-biphenylboronic acid, 1.91 g of tripotassium phosphate, 30 mL of diglyme, and 0.662 g of t-butanol were put, they were degassed by being stirred under reduced pressure, and the air in the flask was replaced with nitrogen.

This mixture was heated to 60° C. and 23.3 mg of palladium(II) acetate and 66.4 mg of di(1-adamantyl)-n-butylphosphine were added, followed by stirring at 120° C. for 27 hours. Water was added to this reaction liquid, suction filtration was performed, and the obtained residue was washed with water, ethanol, and toluene. This residue was dissolved in heated toluene, followed by filtration through a filter aid filled with Celite, alumina, and Celite in this order. The obtained solution was concentrated and dried, and then recrystallized with toluene to give 1.28 g of a target white solid in a yield of 74%.

By a train sublimation method, 1.26 g of the white solid was purified by sublimation. The conditions of the purification by sublimation were such that the solid was heated under a pressure of 2.56 Pa at 310° C. while the argon gas flowed at a flow rate of 10 mL/min. After the purification by sublimation, 1.01 g of a target pale yellow solid was obtained at a collection rate of 80%. The synthesis scheme is shown in Formula (d-1) below.

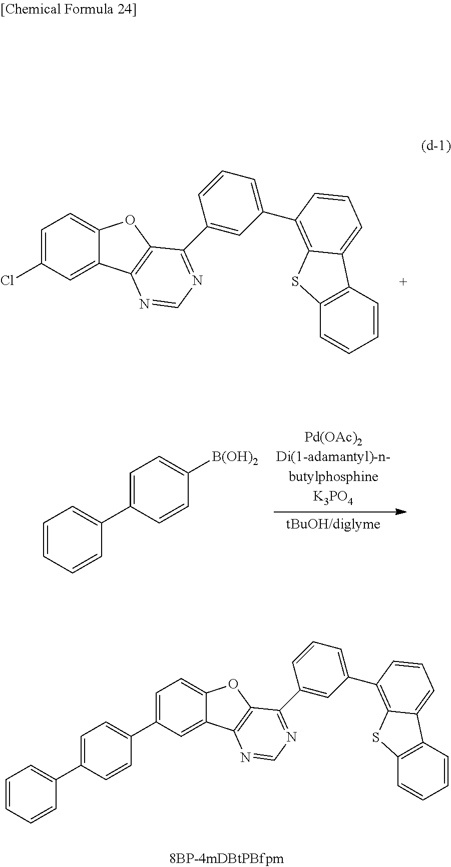 [SMILES: Clc1ccc2oc3c(-c4cccc(-c5cccc6c5sc5ccccc56)c4)ncnc3c2c1 ; OB(O)c1ccc(-c2ccccc2)cc1 ; c1ccc(-c2ccc(-c3ccc4oc5c(-c6cccc(-c7cccc8c7sc7ccccc78)c6)ncnc5c4c3)cc2)cc1]

Analysis results by nuclear magnetic resonance spectroscopy (¹H-NMR) of the pale yellow solid obtained in the above reaction are shown below. The results revealed that 8BP-4mDBtPBfpm, the organic compound represented by the above structural formula, was obtained.

¹H-NMR. δ (CDCl₃): 7.39 (t, 1H), 7.47-7.53 (m, 4H), 7.63-7.67 (m, 2H), 7.68 (d, 2H), 7.75 (d, 2H), 7.79-7.83 (m, 4H), 7.87 (d, 1H), 7.98 (d, 1H), 8.02 (d, 1H), 8.23-8.26 (m, 2H), 8.57 (s, 1H), 8.73 (d, 1H), 9.05 (s, 1H), 9.34 (s, 1H).

### REFERENCE NUMERALS

101: first electrode, 102: second electrode, 103: EL layer, 103a, 103b: EL layer, 104: charge-generation layer, 111, 111a, 111b: hole-injection layer, 112, 112a, 112b: hole-transport layer, 113, 113a, 113b: light-emitting layer, 114, 114a, 114b: electron-transport layer, 115, 115a, 115b: electron-injection layer, 200R, 200G, 200B: optical path length, 201: first substrate, 202: transistor (FET), 203R, 203G, 203B, 203W: light-emitting device, 204: EL layer, 205: second substrate, 206R, 206G, 206B: color filter, 206R′, 206G′, 206B′: color filter, 207: first electrode, 208: second electrode, 209: black layer (black matrix), 210R, 210G: conductive layer, 301: first substrate, 302: pixel portion, 303: driver circuit portion (source line driver circuit), 304a, 304b: driver circuit portion (gate line driver circuit), 305: sealant, 306: second substrate, 307: lead wiring, 308: FPC, 309: FET, 310: FET, 311: FET, 312: FET, 313: first electrode, 314: insulator, 315: EL layer, 316: second electrode, 317: light-emitting device, 318: space, 400: substrate, 401: first organic compound, 402: second organic compound, 403: light-emitting substance, 404: composition for a light-emitting device, 405: light-emitting substance, 900: substrate, 901: first electrode, 902: EL layer, 903: second electrode, 911: hole-injection layer, 912: hole-transport layer, 913: light-emitting layer, 914: electron-transport layer, 915: electron-injection layer, 4000: lighting device, 4001: substrate, 4002: light-emitting device, 4003: substrate, 4004: first electrode, 4005: EL layer, 4006: second electrode, 4007: electrode, 4008: electrode, 4009: auxiliary wiring, 4010: insulating layer, 4011: sealing substrate, 4012: sealant, 4013: desiccant, 4200: lighting device, 4201: substrate, 4202: light-emitting device, 4204: first electrode, 4205: EL layer, 4206: second electrode, 4207: electrode, 4208: electrode, 4209: auxiliary wiring, 4210: insulating layer, 4211: sealing substrate, 4212: sealant, 4213: barrier film, 4214: planarization film, 5101: light, 5102: wheel, 5103: door, 5104: display portion, 5105: steering wheel, 5106: shifter, 5107: seat, 5108: inner rearview mirror, 5109: windshield, 7000: housing, 7001: display portion, 7002: second display portion, 7003: speaker, 7004: LED lamp, 7005: operation key, 7006: connection terminal, 7007: sensor, 7008: microphone, 7009: switch, 7010: infrared port, 7011: recording medium reading portion, 7014: antenna, 7015: shutter button, 7016: image receiving portion, 7018: stand, 7022, 7023: operation button, 7024: connection terminal, 7025: band, 7026: microphone, 7029: sensor, 7030: speaker, 7052, 7053, 7054: information, 9310: portable information terminal, 9311: display portion, 9312: display region, 9313: hinge, and 9315: housing.

This application is based on Japanese Patent Application Serial No. 2018-225002 filed on Nov. 30, 2018, the entire contents of which are hereby incorporated herein by reference.

1. (canceled)

2. A composition for evaporation comprising:
a first organic compound that is represented by General Formula (G2-1) or General Formula (G3-1); and
a second organic compound comprising at least one of a triarylamine skeleton and a carbazole skeleton, 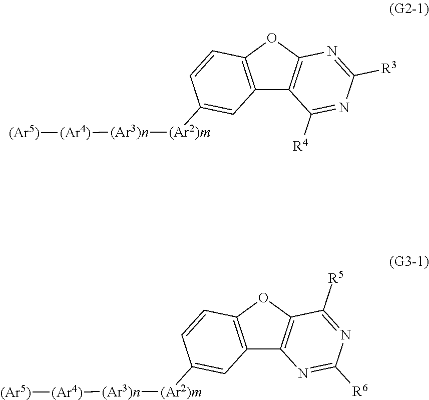
wherein each of Ar², Ar³, Ar⁴, and Ar⁵ independently represents a substituted or unsubstituted aromatic hydrocarbon ring, a substituent of the aromatic hydrocarbon ring being any one of an alkyl group having 1 to 6 carbon atoms, an alkoxy group having 1 to 6 carbon atoms, a monocyclic saturated hydrocarbon group having 5 to 7 carbon atoms, a polycyclic saturated hydrocarbon group having 7 to 10 carbon atoms, and a cyano group,
wherein the number of carbon atoms included in the aromatic hydrocarbon ring is 6 to 25,
wherein m and n independently represent 0 or 1,
wherein each of R³ to R⁶ independently represents hydrogen or a group having 1 to 100 total carbon atoms,
wherein at least one of R³ and R⁴ or at least one of R⁵ and R⁶ is bonded to any one of a pyrrole ring structure, a furan ring structure, and a thiophene ring structure through a substituted or unsubstituted phenylene group or a substituted or unsubstituted biphenylene group, and
wherein the first organic compound and the second organic compound are mixed in the composition before evaporation.

3. A composition for evaporation comprising:
a first organic compound that is represented by General Formula (G2-1) or General Formula (G3-1); and
a second organic compound comprising at least one of a triarylamine skeleton and a carbazole skeleton, 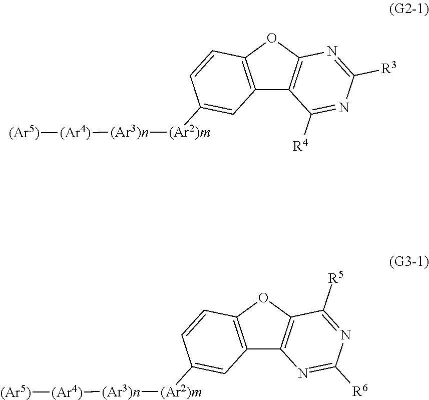
wherein each of Ar², Ar³, Ar⁴, and Ar⁵ independently represents a substituted or unsubstituted aromatic hydrocarbon ring, a substituent of the aromatic hydrocarbon ring being any one of an alkyl group having 1 to 6 carbon atoms, an alkoxy group having 1 to 6 carbon atoms, a monocyclic saturated hydrocarbon group having 5 to 7 carbon atoms, a polycyclic saturated hydrocarbon group having 7 to 10 carbon atoms, and a cyano group,
wherein the number of carbon atoms included in the aromatic hydrocarbon ring is 6 to 25,
wherein m and n independently represent 0 or 1,
wherein each of R³ to R⁶ independently represents hydrogen or a group having 1 to 100 total carbon atoms,
wherein at least one of R³ and R⁴ or at least one of R⁵ and R⁶ is bonded to any one of a pyrrole ring structure, a furan ring structure, and a thiophene ring structure through a substituted or unsubstituted phenylene group or a substituted or unsubstituted biphenylene group,
wherein the first organic compound and the second organic compound are mixed in the composition before evaporation, and
wherein a molecular mass of the first organic compound is smaller than a molecular mass of the second organic compound, and a difference in molecular mass between the first organic compound and the second organic compound is less than or equal to 200.

4. The composition for evaporation according to claim 2, wherein each of Ar², Ar³, Ar⁴, and Ar⁵ independently represents a substituted or unsubstituted benzene ring or a substituted or unsubstituted naphthalene ring.

5. The composition for evaporation according to claim 4, wherein Ar², Ar³, Ar⁴, and Ar⁵ are the same.

6. The composition for evaporation according to claim 2, wherein the at least one of R³ and R⁴ or the at least one of R⁵ and R⁶ is bonded to any one of General Formulae (Ht-1) to (Ht-26) through the substituted or unsubstituted phenylene group or the substituted or unsubstituted biphenylene group, 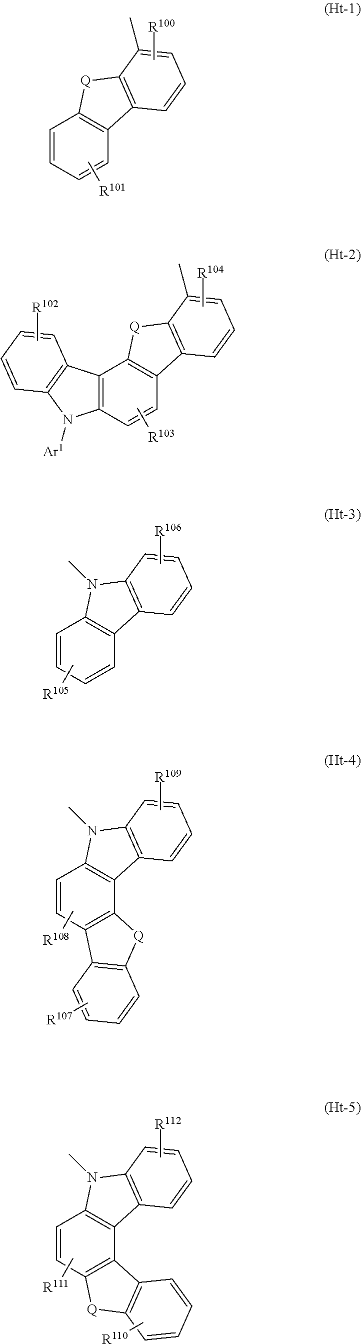 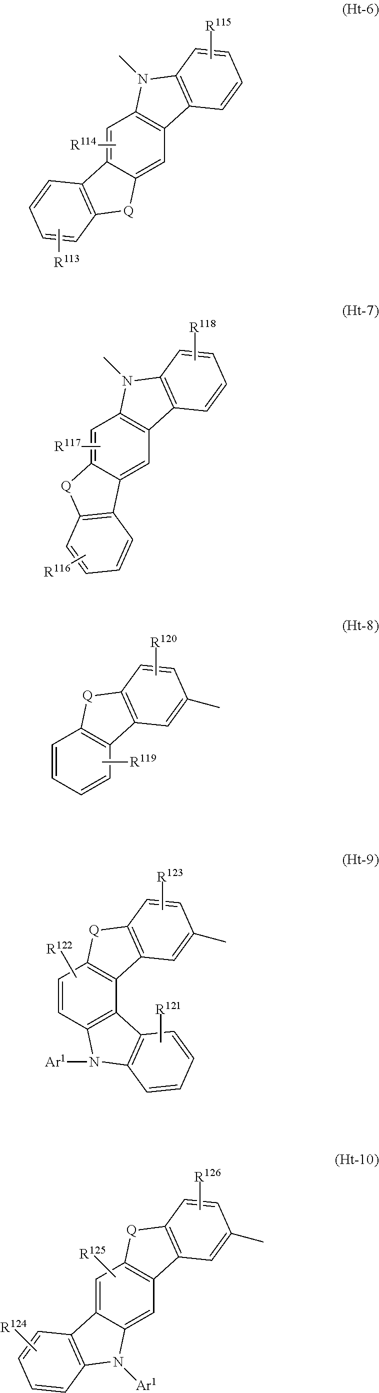 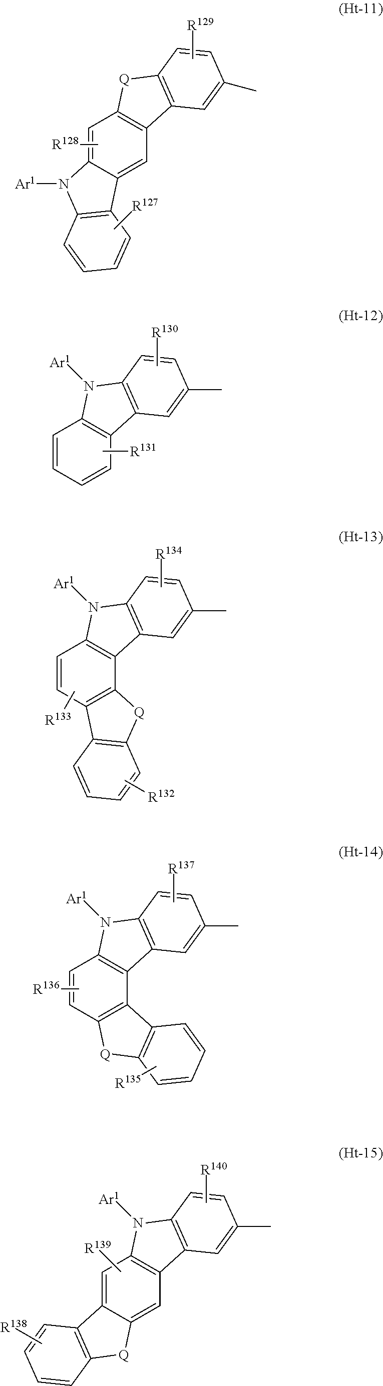 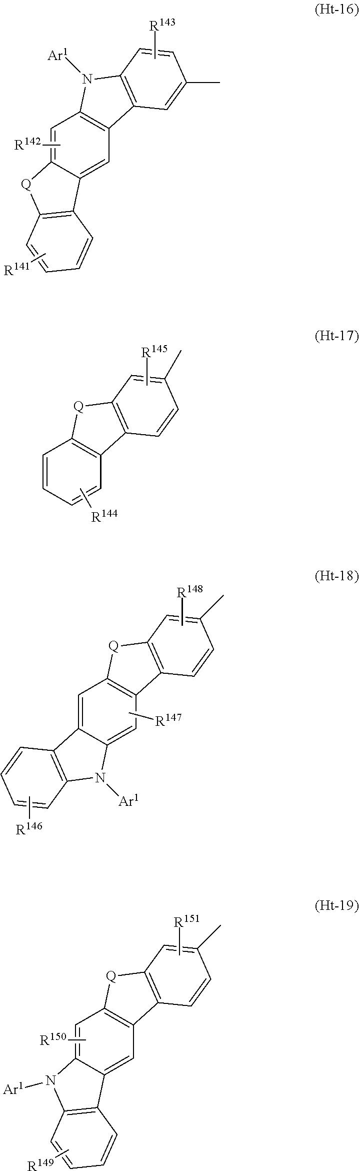 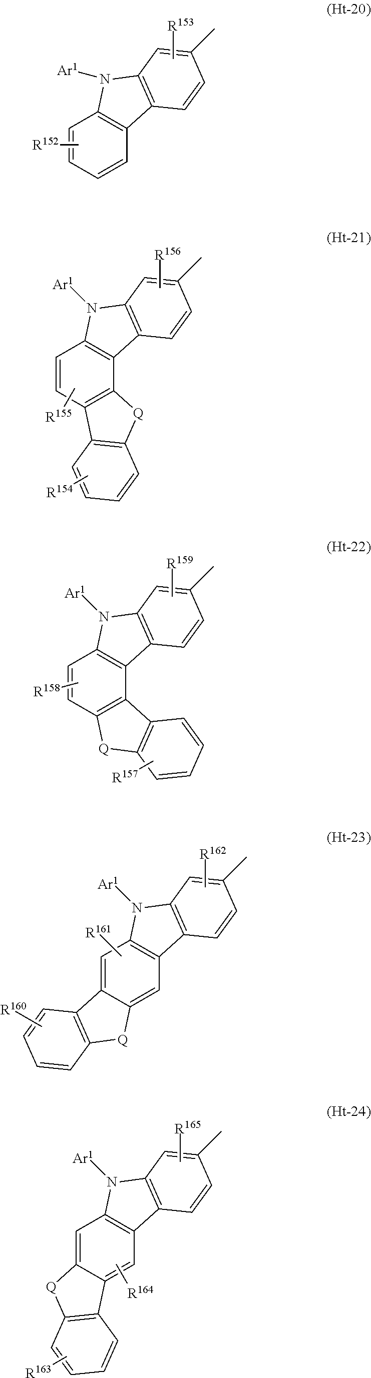 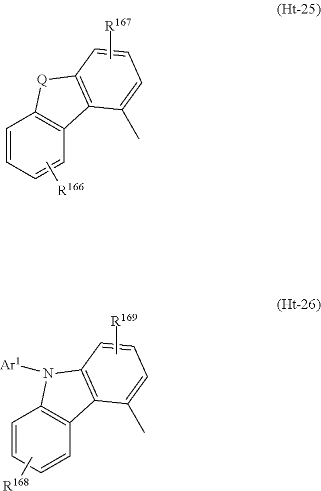
wherein Q represents oxygen or sulfur,
wherein each of R¹⁰⁰ to R¹⁶⁹ independently represents 1 to 4 substituents and independently represents any one of hydrogen, an alkyl group having 1 to 6 carbon atoms, and a substituted or unsubstituted aromatic hydrocarbon group having 6 to 13 carbon atoms, and
wherein Ar¹ represents a substituted or unsubstituted benzene ring or a substituted or unsubstituted naphthalene ring.

7. The composition for evaporation according to claim 2, wherein the second organic compound comprises the triarylamine skeleton.

8. The composition for evaporation according to claim 2, wherein the second organic compound comprises the carbazole skeleton.

9. The composition for evaporation according to claim 2, wherein the second organic compound comprises the triarylamine skeleton and the carbazole skeleton.

10. The composition for evaporation according to claim 8, wherein the second organic compound is a bicarbazole derivative.

11. The composition for evaporation according to claim 2, wherein a combination of the first organic compound and the second organic compound can form an exciplex.

12. The composition for evaporation according to claim 2, wherein the first organic compound is mixed in a larger proportion than the second organic compound.

13. The composition for evaporation according to claim 3, wherein each of Ar², Ar³, Ar⁴, and Ar⁵ independently represents a substituted or unsubstituted benzene ring or a substituted or unsubstituted naphthalene ring.

14. The composition for evaporation according to claim 13, wherein Ar², Ar³, Ar⁴, and Ar⁵ are the same.

15. The composition for evaporation according to claim 3, wherein the at least one of R³ and R⁴ or the at least one of R⁵ and R⁶ is bonded to any one of General Formulae (Ht-1) to (Ht-26) through the substituted or unsubstituted phenylene group or the substituted or unsubstituted biphenylene group, 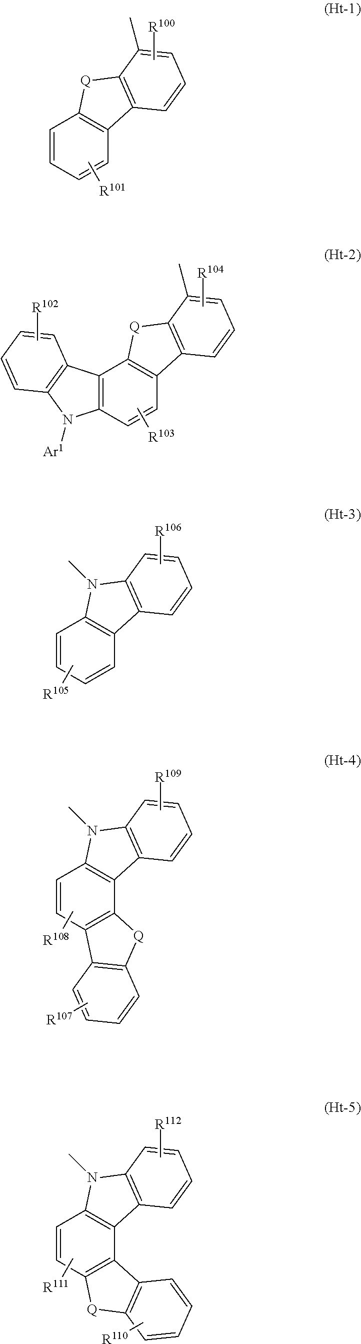 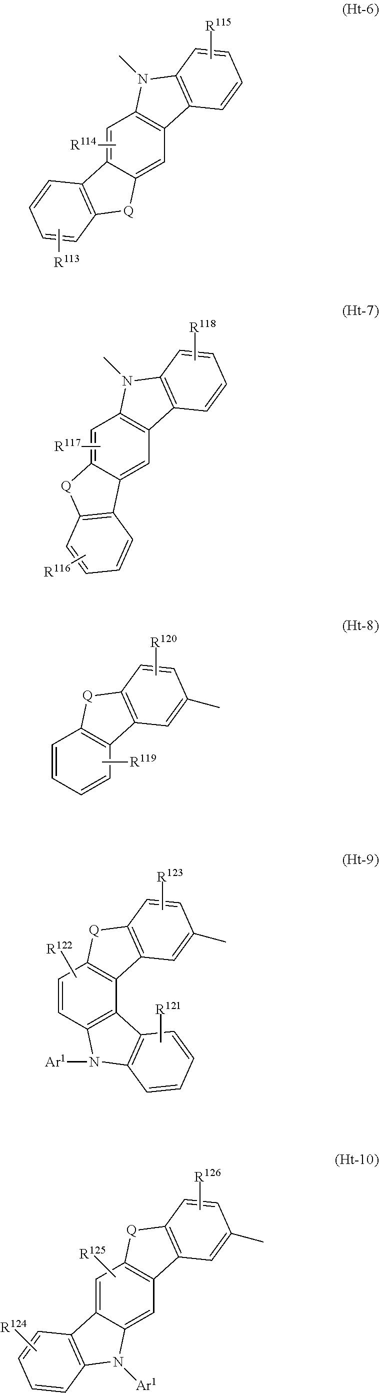 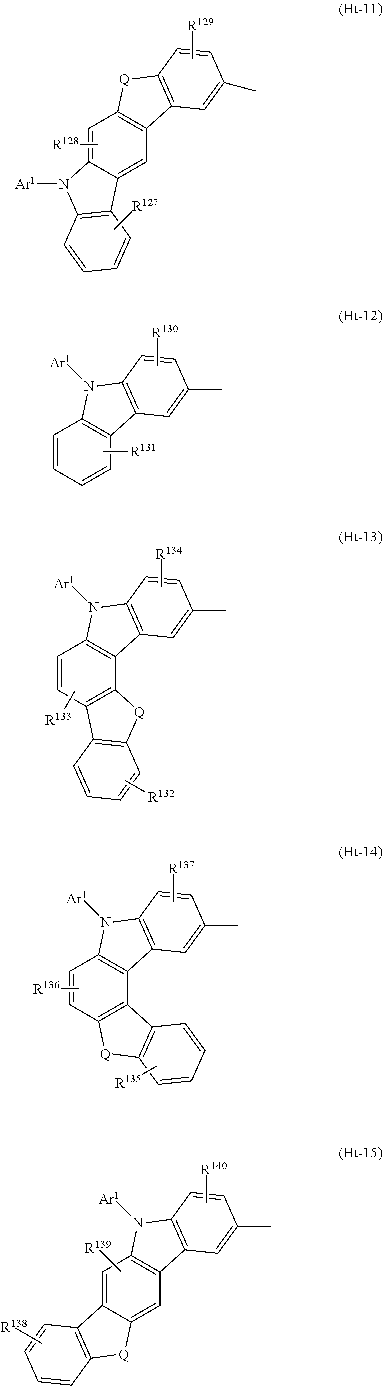 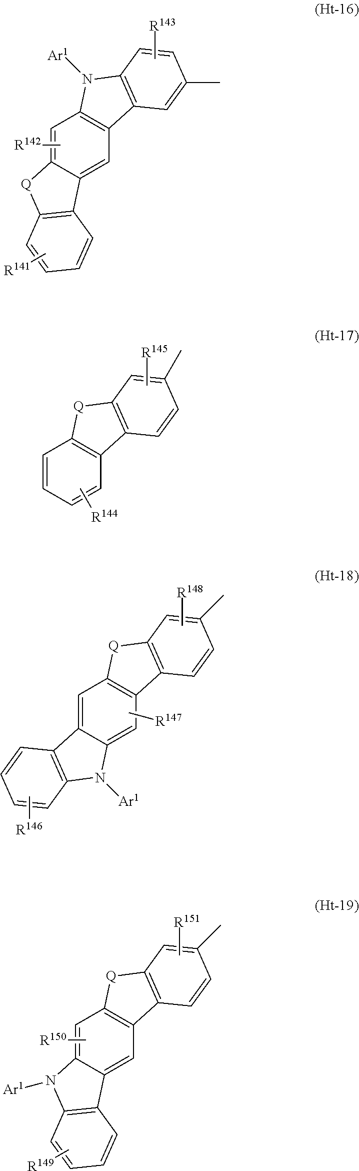 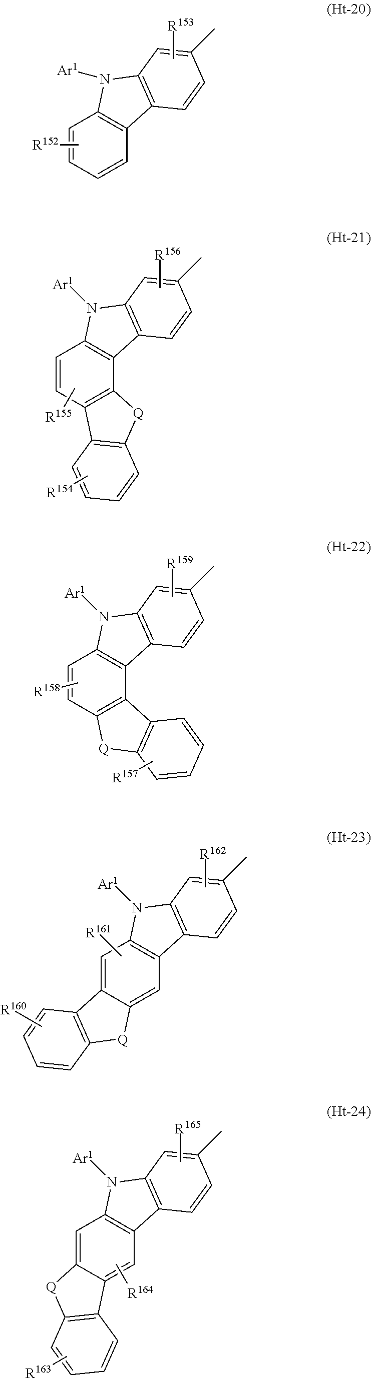 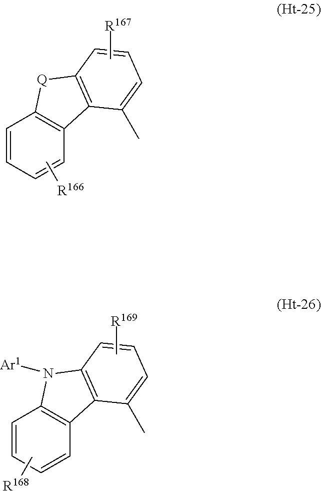
wherein Q represents oxygen or sulfur,
wherein each of R¹⁰⁰ to R¹⁶⁹ independently represents 1 to 4 substituents and independently represents any one of hydrogen, an alkyl group having 1 to 6 carbon atoms, and a substituted or unsubstituted aromatic hydrocarbon group having 6 to 13 carbon atoms, and
wherein Ar¹ represents a substituted or unsubstituted benzene ring or a substituted or unsubstituted naphthalene ring.

16. The composition for evaporation according to claim 3, wherein the second organic compound comprises the triarylamine skeleton.

17. The composition for evaporation according to claim 3, wherein the second organic compound comprises the carbazole skeleton.

18. The composition for evaporation according to claim 3, wherein the second organic compound comprises the triarylamine skeleton and the carbazole skeleton.

19. The composition for evaporation according to claim 17, wherein the second organic compound is a bicarbazole derivative.

20. The composition for evaporation according to claim 2, wherein a combination of the first organic compound and the second organic compound can form an exciplex.

21. The composition for evaporation according to claim 2, wherein the first organic compound is mixed in a larger proportion than the second organic compound.
